(19) United States
(12) Patent Application Publication
(10) Pub. No.: US 2026/0262202 A1
(43) Pub. Date: Sep. 3, 2026

(54) MODULARIZED HOT AISLE CONTAINMENT SYSTEM, AND METHODS RELATED TO THE SAME

(71) Applicant: ThermalWorks, LLC, Darien, CT (US)

(72) Inventors: John M. Costakis, Saugerties, NY (US); Doron Shapiro, St. Louis, MO (US); Paul Tarangelo, Lagrangeville, NY (US); Ming Zhang, Naples, FL (US)

(73) Assignee: ThermalWorks, LLC, Darien, CT (US)

(21) Appl. No.: 19/553,061

(22) Filed: Feb. 27, 2026

Related U.S. Application Data
(60) Provisional application No. 63/765,444, filed on Feb. 28, 2025.

(51) Int. Cl. H05K 7/20; H05K 7/14

(52) U.S. Cl. CPC H05K 7/2079; H05K 7/1491; H05K 7/1492

(57) ABSTRACT

A Hot Aisle Containment (HAC) System includes one or more pods. Each pod includes one or more modules. Each module includes one or more components. The HAC system may additionally include system-wide modules. The components, modules, pods, and/or the HAC system may be designed based on customer specifications, and then manufactured and at least partially assembled at a factory or other manufacturing facility. Following transportation of the pre-assembled components, the HAC system may be installed in as at least partially pre-assembled pods or modules at a project site. Diagnostics may be performed on the HAC system. Operational parameters may be monitored and/or adjusted for the HAC system.

### CROSS-REFERENCE TO RELATED APPLICATIONS

The present application claims the benefit of priority under 35 U.S.C. § 119(e) to U.S. Provisional Patent Application No. 63/765,444, filed on Feb. 28, 2025, the entirety of which is incorporated herein by reference.

### FIELD OF THE INVENTION

The present invention is related generally to cooling systems and more specifically to systems and related methods for modular hot aisle containment (HAC) operable to provide air cooling, liquid cooling, power, and communication to server racks in data centers.

### BACKGROUND

The background description includes information that may be useful in understanding the present inventive subject matter. It is not an admission that any of the information provided herein is prior art or relevant to the presently claimed disclosure, or that any publication specifically or implicitly referenced is prior art.

Hot Aisle Containment (HAC) is one technique used in data centers for cooling server towers by regulating heat generated by the server racks. HAC includes the use of a physical barrier that guides hot exhaust airflow to a return for a cooling system, including by directing exhaust airflow from a space around the server racks to the return. In some embodiments, server racks are lined up in two rows, with exhaust ventilation for the server racks in each row pointed inward toward a space defined between the two rows (e.g., in an “aisle” configuration). At least a portion of each row of server racks is enclosed by walls, floors, and/or ceilings, preventing the escape of the exhaust from between the two rows other than through pre-determined exits or returns within the HAC system.

For example, the space between the two rows may be enclosed by walls positioned proximate to (e.g., abutting against, or spaced a pre-determined distance from) exterior sides of the end server racks in the respective rows of server racks. By way of another example, the space between the two rows may be enclosed by ceiling panels positioned proximate to (e.g., abutting against, or spaced a pre-determined distance from) upper surfaces of the server racks in the respective rows of server racks. Further, the rows of server racks may be set on a floor surface, either an existing floor within a building or a raised platform installed with the rows of server racks on the existing floor of the building.

Access to the space may optionally be provided by one or more doors at one or more ends of the space. The doors may be within the walls that are proximate to the sides of the end server racks in the respective rows of server racks (e.g., at the end of the aisle formed from the rows of server racks). Similarly, access to the space may optionally be provided by one or more access openings within the ceiling panels, and/or within a raised platform.

Existing HAC systems are typically installed on-site. As such, although HAC system component companies may sell nationally (or internationally) including optionally sending installers to the project site, often a customer installing the HAC system at a project site instead relies on locally-hired contactors for the actual installation. This can increase installation time at the project site, and can increase the possibility of incorrect installation, including where the locally-hired contractors are not familiar with the HAC system to be installed.

### SUMMARY

As such, there exists a long-felt but unmet need for improved HAC systems, and methods of manufacturing, assembly, and installation of the same. The modularity of the HAC system should allow for manufacturing and assembly at a first site and installation at a second, different site, promoting increased efficiency, increased scalability, and reduced operational complexity in the designing, manufacturing, assembling, and installing of the HAC system.

In particular, the HAC system should be modular, allowing for flexibility in the design, manufacturing, and assembly to address particular requests by a customer. The modularity of the HAC system should promote adaptability during installation, including increasing the ease of modification to address real-time issues that arise during the installation process. The modularity of the HAC system (e.g., with the inclusion of different modules and/or pods) should also promote scalability, as more (or fewer) server racks are desired by a customer.

In addition, essential infrastructure, including liquid cooling, power, and communication trays, may be integrated into modules and/or pods during manufacturing and assembly at the factory or other manufacturing facility and prior to installation at a project site. This is beneficial as it may reduce on-site installation time and boost overall efficiency during assembly and installation.

It is contemplated that handling both manufacturing and assembly of the modules and/or pods of the HAC system at the factory or other manufacturing facility should increase quality control and consistency in manufactured and assembled products. In addition, handling manufacturing and assembly at the factory or other manufacturing facility should facilitate quicker turnaround from commissioning of the project to delivery of the completed modules and/or pods, decreasing the amount of downtime for customers.

It is contemplated that handling manufacturing and assembly at the factory or other manufacturing facility should also reduce installation time on the project site, potentially addressing labor shortages in the local contractor workforce. In particular, technicians may be utilized to install select infrastructure during manufacturing and assembly at the factory or other manufacturing facility, streamlining a process that typically requires multiple disciplines, instead of having to rely on local contractors to have the necessary technical qualifications. With the handling of select infrastructure during manufacturing and assembly, local contractors (or factory-sent technicians) only need to perform the necessary steps for on-site installations and connection of the modules and/or pods of the HAC system, providing a comprehensive purchasing experience for the customer.

Embodiments of the present disclosure are directed to an HAC system including one or more pods (e.g., sections of modules). Each pod includes one or more modules of the HAC system. For example, the pod may include a frame module. By way of another example, the pod may include a power module operable to route primary power (and optionally secondary or redundant power), that is positionable on the frame module. By way of another example, the pod may include a fluid cooling module (e.g., using a liquid or a gas), that is positionable on the frame module. By way of another example, the pod may include a tray module that is positionable on the frame module. By way of another example, the pod may include a panel module that is positionable on the frame module.

In embodiments, the pod may include a plurality of server racks set in one or more rows, where exhaust from the plurality of server racks is directed to a space defined proximate to the rows of server racks. For example, the space may be defined between two rows. It is noted that a particular pod of the HAC system may include the server racks, or the pod of the HAC system may be coupled to and/or otherwise installed with the server racks, without departing from the scope of the present disclosure.

In embodiments, the HAC system may include one or more pods, where each pod is separately installable and includes respective modules. Where the HAC system includes a plurality of pods, the full HAC system may include a set of shared components. For example, the shared components may include a power end module installed proximate to an end of the HAC system on a particular end pod of the plurality of pods. By way of another example, the shared components may include, but are not limited to, a set of one or more fluid cooling pipes that run throughout the HAC system (e.g., between and/or across the plurality of pods). By way of another example, the shared components may include an end tray module installed proximate to an end of the HAC system on a particular end pod of the plurality of pods.

In embodiments, the shared components of the HAC system may include walls, doors, windows, ceilings, flooring platforms, and/or access hatches, for access to the space between rows of server racks by a user. Optionally, the doors and/or access hatches may have components that promote automatic closure, to improve efficiency of the HAC system. It is noted that these components may additionally be used on a single pod.

In embodiments, ceiling components may be separate components installed along with modules, similar to walls, doors, and/or windows. Alternatively, the ceiling components may be installed with a particular module (e.g., the fluid cooling module), without departing from the scope of the present disclosure. For example, a ceiling for a pod may include panels on a subframe. The panels may be affixed to, or removably coupled to, the subframe, depending on whether access to components in the same module or in other-tier modules is desirable through the panels. By way of another example, the ceiling for a pod may include grating or other catwalk features to support a user's weight while also providing access to components in the same module or in other-tier modules.

In some embodiments, the HAC system may be set on a non-raised (e.g., optionally pre-existing) floor, with dual hinged doors and fixed or retractable/removable ceiling elements. In other embodiments, the HAC system may be on a raised platform, with dual hinged doors and fixed or retractable/removable ceiling elements. In other embodiments, the HAC system may be on a raised platform, with walls (e.g., fabricated from lightweight frames and vinyl sheeting with desired insulation properties) where the rows of server racks have gaps. In other embodiments, the HAC system may be on a raised platform, with dual sliding doors and rigid wall panels (and optional ceiling elements). It is noted that the HAC system may include some combination of elements from the above embodiments, without departing from the scope of the present disclosure.

In embodiments, the shared components of a HAC system may include an end cover module. The cover may protect module components, including optionally assisting in the directing of heat. The cover may also provide an increased aesthetic appearance to the HAC system, including with the covering of module components and allowing for the application of visual branding. It is noted that these covers may additionally be used on a single pod, including where the single pod forms the HAC system.

In embodiments, the HAC system includes sensors, controllers, user interfaces including displays and/or user input devices, and the like necessary to provide a readout and ability to control operating points of the HAC system to a user. The information may be presented at a location for each respective module and/or pod of the HAC system, and/or may be routed to a single location (e.g., located proximate to an end of the rows of server racks on an end pod).

In embodiments, the HAC system includes containment and leak protection subsystems. The containment and leak protection subsystems may, for example, ensure operational safety and ensure that pre-determined thresholds are maintained for cooling properties of the HAC system. Optionally, the HAC system may include installed safety high air pressure reliefs for increased protection in select situations (e.g., with pre-determined thresholds related to temperature and/or pressure are exceeded).

Aspects of the present disclosure are directed to a hot aisle containment (HAC) solution focused on supporting different systems for air-cooled and/or liquid cooled information technology (IT) equipment deployment. The HAC system of the present disclosure provides pathways that are coordinated within the layout for all major subsystems to be installed including, but not limited to, electrical systems (e.g., for power infrastructure), mechanical systems (e.g., for heating, ventilation, and air conditioning (HVAC) of the aisle and/or cooling of the server racks), telecommunications (e.g., networking), and the like. The various subsystems are installable as modules within a pod, where one or more pods are combined to form the HAC system, at a factory. The HAC system (and pods therein) can be modified or customized to user specifications during the manufacturing and assembly process, including air-cooled only configurations without integrated fluid cooling modules and fluid-cooling configurations with the integrated fluid cooling modules. The modules and/or pods can delivered partially-or fully-assembled to a project site, to be installed more efficiently and faster, and with fewer risks for error during installation, due to the coordination of the subsystems within the layout of the HAC system.

In embodiments, the HAC system includes one or more pods formed of one or more modules, including optionally system-level modules that are coupled to the one or more pods to complete the HAC system after the pods are installed at the project site. The HAC system at least partially encompasses one or more rows of server racks, where adjacent rows define an aisle therebetween. The aisle may be closed off with one or more of a door or other mechanical corridor transition, and optionally ceiling panels installed on the various pods. The exterior of the various pods includes modules for cable management, and the interior of the various pods optionally includes modules for fluid-cooling features. Optionally, a ceiling plenum transition is provided in an uppermost region of the HAC system, including optionally for coolers.

In embodiments, a width of the pods/the HAC system is adjustable during manufacturing to customer specifications. In embodiments, a total height of the pods/the HAC system is adjustable during manufacturing to customer specifications. As part of the total height being adjustable, components of the cable management modules are adjustable including, but not limited to, total shelving or tray storage capacity, depth of shelving or tray (e.g., as defined by support arm length), and height of the cable management modules as a whole.

In embodiments, a total length of the HAC system is adjustable during manufacturing to customer specifications. For example, the length of the HAC system may be adjusted by increasing or decreasing a number of pods installed to form the HAC system. By way of another example, the length of the HAC system may be adjusted by increasing or decreasing a length of a particular pod.

In embodiments where the fluid-cooled system is ordered by the customer, the fluid cooling module may be adjustable during manufacturing to customer specifications. For example, a pipe size diameter for the supply and return pipes may be adjustable to customer specifications. By way of another example, the supply and return pipes may be made redundant within the HAC system to meet required code. In some configurations, an HAC system with fluid cooling may be larger in one or more dimensions (e.g., width) as compared to an air-cooled only configuration, including to be able to accommodate the sizing of the fluid cooling piping within the pods that form the HAC system.

In embodiments, the HAC system is adjustable in one or more of height and width in approximately 2-inch increments in line with customer specifications to be more closely customizable to fit within a particular data center configuration. It is noted that the adjustability and customizability of the HAC system to the particular dimensions of a data center may improve overall air management efficiency for air-cooling operations.

In embodiments, the HAC system includes adjustable hanger arm assemblies including support arms for an adjustable number and/or spacing of cable trays. It is noted that the adjustable support arms improve the overall organization and accessibility of electrical and network cabling, including optionally reducing potential interference by assisting in maintaining an organized environment.

In embodiments, the various pods and/or modules of the HAC system are pre-manufactured for quick ship deployment from manufacturing facilities to project sites, to reduce lead times and accelerate project timelines. In embodiments, the modularity of the HAC system reduces downtime and labor costs when installing at a project site and transitioning from setup to daily operation. In embodiments, in-house installation crews are available for dispatch alongside the quick ship deployment to the project site, to increase the swiftness and efficiency of installation and reducing disruption to operations.

In embodiments, the HAC system improves cooling effectiveness by containing hotter air and reducing a mixing with cooler air, resulting in increase energy savings and a reduced carbon footprint. In embodiments, the HAC system is customizable based on customer specifications and prior to installation, and/or modifiable after installation, to utilize liquid cooling in addition to air-cooling, including optionally while trending toward optimization of air-cooled infrastructures.

In embodiments, the modularity of the HAC system allows for flexibility in scaling and/or reconfiguration during or after initial installation, as needed to meet evolving requirements and maintain long-term viability and cost-effectiveness for customers.

A first aspect of the present disclosure is to provide a pod for a modularized HAC system. The pod includes a frame module including a plurality of posts. Spacing between adjacent posts of the plurality of posts is dimensioned to receive adjacent rows of server racks and at least partially surround an aisle defined between the adjacent rows of server racks when the adjacent rows of server racks are installed with the pod. The pod includes a power module couplable to the frame module, the power module configured to route power cables to the adjacent rows of server racks when the adjacent rows of server racks are installed with the pod. The pod includes a tray module couplable to the frame module, the tray module configured to route networking or data cables to the adjacent rows of server racks when the adjacent rows of server racks are installed with the pod. The pod includes a panel module couplable to the frame module. The panel module is configured to at least partially enclose the defined aisle between adjacent rows of server racks to at least one of contain and direct hot air exhausted from the adjacent rows of server racks through the defined aisle when the adjacent rows of server racks are installed with the pod. The frame module, the power module, the tray module, and the panel module are assembled to form the pod at a first location, and are deliverable pre-assembled for installation with the adjacent rows of server racks to a second location.

The pod of the first aspect may include, optionally, that at least some posts of the plurality of posts are couplable to a floor surface during installation via anchor plates. The frame module comprises at least one crossmember coupled to adjacent posts of the plurality of posts.

The pod of the first aspect may include one or more of the previous embodiments and, optionally, that the power module includes a frame couplable to adjacent posts of the plurality of posts. The power module includes at least one hanger arm assembly coupled to the frame, the at least one hanger arm assembly including a plurality of arms that are adjustable within the hanger arm assembly and relative to the frame. The power module includes at least one power conduit coupled to one or more arms of the plurality of arms. The at least one power conduit is configured to route power cables to the adjacent rows of server racks when the adjacent rows of server racks are installed with the pod.

The pod of the first aspect may include one or more of the previous embodiments and, optionally, that the tray module includes a frame couplable to adjacent posts of the plurality of posts. The tray module includes at least one hanger arm assembly coupled to the frame, the at least one hanger arm assembly including a plurality of arms that are adjustable within the hanger arm assembly and relative to the frame. The tray module includes at least one cable tray coupled to one or more arms of the plurality of arms. The at least one cable tray is configured to route networking or data cables to the adjacent rows of server racks.

The pod of the first aspect may include one or more of the previous embodiments and, optionally, that the tray module includes at least one shelf coupled to one or more arms of the plurality of arms.

The pod of the first aspect may include one or more of the previous embodiments and, optionally, that the panel module includes a frame couplable to adjacent posts of the plurality of posts. The panel module includes at least one window that extends from the frame, The at least one window is configured to at least partially enclose the defined aisle between adjacent rows of server racks to at least one of contain and direct the hot air exhausted from the adjacent rows of server racks through the defined aisle when the adjacent rows of server racks are installed with the pod.

The pod of the first aspect may include one or more of the previous embodiments and, optionally, that the panel module includes at least one divider that extends from the frame in a direction opposite a direction of extension of the at least one window. The at least one divider is configured to at least partially enclose the defined aisle between adjacent rows of server racks to at least one of contain and direct the hot air exhausted from the adjacent rows of server racks through the defined aisle when the adjacent rows of server racks are installed with the pod.

The pod of the first aspect may include one or more of the previous embodiments and, optionally, at least one ceiling panel. The at least one ceiling panel is configured to at least partially enclose the defined aisle between adjacent rows of server racks to at least one of contain and direct the hot air exhausted from the adjacent rows of server racks through the defined aisle when the adjacent rows of server racks are installed with the pod.

The pod of the first aspect may include one or more of the previous embodiments and, optionally, at least one catwalk panel. The at least one catwalk panel is configured to support a pre-determined amount of weight.

The pod of the first aspect may include one or more of the previous embodiments and, optionally, that the at least one catwalk panel is installed on a fluid cooling module of the pod.

The pod of the first aspect may include one or more of the previous embodiments and, optionally, a fluid cooling module, the fluid cooling module configured to provide fluid to the adjacent rows of server racks for fluid cooling when the adjacent rows of server racks are installed with the pod.

The pod of the first aspect may include one or more of the previous embodiments and, optionally, that the fluid cooling module is a liquid cooling module which supplies a liquid coolant at a first lower temperature to, and receives liquid coolant at a second higher temperature from, the adjacent rows of server racks when the adjacent rows of server racks are installed with the pod.

The pod of the first aspect may include one or more of the previous embodiments and, optionally, the fluid cooling module includes a frame couplable to adjacent posts of the plurality of posts. The fluid cooling module includes at least one supply pipe insertable in the frame and for a fluid at a first lower temperature. The fluid cooling module includes at least one supply line fluidically coupled with the supply pipe and the adjacent rows of server racks when the adjacent rows of server racks are installed with the pod. The fluid cooling module includes at least one return pipe insertable in the frame and for a fluid at a second higher temperature. The fluid cooling module includes at least one return line fluidically coupled with the return pipe and the adjacent rows of server racks when the adjacent rows of server racks are installed with the pod.

The pod of the first aspect may include one or more of the previous embodiments and, optionally, that the at least one supply pipe includes two supply pipes that are fluidically coupled via a supply pipe joint to circulate supply fluid between supply ports located at one end of the pod. The at least one return pipe includes two return pipes that are fluidically coupled via a return pipe joint to circulate return fluid between return ports located at one end of the pod.

The pod of the first aspect may include one or more of the previous embodiments and, optionally, that the frame module is configured to receive a door module. The door module is configured to at least partially enclose the defined aisle between adjacent rows of server racks to at least one of contain and direct hot air exhausted from the adjacent rows of server racks through the defined aisle when the adjacent rows of server racks are installed with the HAC system.

A second of the present disclosure is to provide a modularized HAC system. The HAC system includes at least one pod and a door module. The at least one pod includes a frame module including a plurality of posts. Spacing between adjacent posts of the plurality of posts is dimensioned to receive adjacent rows of server racks and at least partially surround an aisle defined between the adjacent rows of server racks when the adjacent rows of server racks are installed with the HAC system. The at least one pod includes a power module couplable to the frame module, the power module configured to route power cables to the adjacent rows of server racks when the adjacent rows of server racks are installed with the HAC system. The at least one pod includes a tray module couplable to the frame module, the tray module configured to route networking or data cables to the adjacent rows of server racks when the adjacent rows of server racks are installed with the HAC system. The at least one pod includes a panel module couplable to the frame module. The panel module is configured to at least partially enclose the defined aisle between adjacent rows of server racks to at least one of contain and direct hot air exhausted from the adjacent rows of server racks through the defined aisle when the adjacent rows of server racks are installed with the pod. The frame module, the power module, the tray module, and the panel module are assembled to form the at least one pod at a first location, and are deliverable pre-assembled as the at least one pod for installation with the adjacent rows of server racks to a second location. The door module is couplable to the frame module of a particular pod of the at least one pod. The door module is configured to at least partially enclose the defined aisle between adjacent rows of server racks to at least one of contain and direct hot air exhausted from the adjacent rows of server racks through the defined aisle when the adjacent rows of server racks are installed with the HAC system.

The HAC system of the second aspect may include, optionally, a fluid cooling module, the fluid cooling module configured to provide fluid to the adjacent rows of server racks for fluid cooling when the adjacent rows of server racks are installed with the HAC system.

A third aspect of the present disclosure is to provide a method. The method may include, but is not limited to, designing one or more modules for at least one pod of a modularized hot aisle containment (HAC) system. The one or more modules include a frame module with a plurality of posts. Spacing between adjacent posts of the plurality of posts is dimensioned to receive adjacent rows of server racks and at least partially surround an aisle defined between the adjacent rows of server racks when the adjacent rows of server racks are installed with the HAC system. The method may include, but is not limited to, a power module couplable to the frame module, the power module configured to route power cables to the adjacent rows of server racks when the adjacent rows of server racks are installed with the HAC system. The method may include, but is not limited to, a tray module couplable to the frame module, the tray module configured to route networking or data cables to the adjacent rows of server racks when the adjacent rows of server racks are installed with the HAC system. The method may include, but is not limited to, a panel module couplable to the frame module. The panel module is configured to at least partially enclose the defined aisle between adjacent rows of server racks to at least one of contain and direct hot air exhausted from the adjacent rows of server racks through the defined aisle when the adjacent rows of server racks are installed with the HAC system. The method may include, but is not limited to, manufacturing the one or more modules for at least one pod of the system. The method may include, but is not limited to, assembling the at least one pod of the HAC system. The frame module, the power module, the tray module, and the panel module are assembled to form the at least one pod at a first location, and the at least one pod is deliverable pre-assembled for installation with the adjacent rows of server racks to a second location.

The method of the third aspect may include, optionally, that designing one or more modules for at least one pod of a modularized hot aisle containment system includes designing a fluid cooling module, the fluid cooling module configured to provide fluid to the adjacent rows of server racks for fluid cooling when the adjacent rows of server racks are installed with the HAC system.

A fourth of the present disclosure is to provide a modularized HAC system. The HAC system includes at least one pod. The at least one pod includes a frame module with a plurality of posts. Spacing between adjacent posts of the plurality of posts is dimensioned to receive adjacent rows of server racks and at least partially surround an aisle defined between the adjacent rows of server racks when the adjacent rows of server racks are installed with the HAC system. The at least one pod includes a module including at least one hanger arm assembly couplable to the frame module, the at least one hanger arm assembly including a plurality of arms that are adjustable within the hanger arm assembly and relative to the frame module. The HAC system includes a plurality of windows couplable to the frame module of the at least one pod. The HAC system includes a plurality of ceiling panels couplable to the frame module of the at least one pod. The HAC system includes a door module couplable to the frame module of a particular pod of the at least one pod at an end of the HAC system. The frame module, the module including the at least one hanger arm assembly, the plurality of windows, the plurality of ceiling panels, and the door module are assembled to form the at least one pod at a first location, and are deliverable pre-assembled as the at least one pod for installation with the adjacent rows of server racks to a second location. The plurality of windows, the plurality of ceiling panels, and the door module are configured to at least partially enclose the defined aisle between adjacent rows of server racks to at least one of contain and direct hot air exhausted from the adjacent rows of server racks through the defined aisle when the adjacent rows of server racks are installed with the HAC system.

The HAC system of the fourth aspect may include, optionally, that at least some posts of the plurality of posts of the frame module of the at least one pod are couplable to a floor surface during installation via anchor plates. The frame module includes at least one crossmember coupled to adjacent posts of the plurality of posts.

The HAC system of the fourth aspect may include one or more of the previous embodiments and, optionally, that the at least one pod includes at least one power conduit coupled to one or more arms of the plurality of arms of the at least one hanger arm assembly. The at least one power conduit is configured to route power cables to the adjacent rows of server racks when the adjacent rows of server racks are installed with the HAC system.

The HAC system of the fourth aspect may include one or more of the previous embodiments and, optionally, that the module including the at least one hanger arm assembly is a power conduit module. The at least one hanger arm assembly is coupled to a frame of the power conduit module. The frame is couplable to adjacent posts of the plurality of posts of the at least one pod.

The HAC system of the fourth aspect may include one or more of the previous embodiments and, optionally, that the at least one pod includes at least one cable tray coupled to one or more arms of the plurality of arms of the at least one hanger arm assembly. The at least one cable tray is configured to route networking or data cables to the adjacent rows of server racks when the adjacent rows of server racks are installed with the system.

The HAC system of the fourth aspect may include one or more of the previous embodiments and, optionally, that the module including the at least one hanger arm assembly is a tray module. The at least one hanger arm assembly is coupled to a frame of the tray module. The frame is couplable to adjacent posts of the plurality of posts of each pod of the at least one pod.

The HAC system of the fourth aspect may include one or more of the previous embodiments and, optionally, that the at least one pod includes at least one shelf coupled to one or more arms of the plurality of arms of the at least one hanger arm assembly. The at least one shelf is configured to route networking or data cables to the adjacent rows of server racks when the adjacent rows of server racks are installed with the system.

The HAC system of the fourth aspect may include one or more of the previous embodiments and, optionally, that the module including the at least one hanger arm assembly is a tray module. The at least one hanger arm assembly is coupled to a frame of the tray module. The frame is couplable to adjacent posts of the plurality of posts of the at least one pod.

The HAC system of the fourth aspect may include one or more of the previous embodiments and, optionally, that at least some windows of the plurality of windows are coupled to a frame of a panel module. The frame is couplable to adjacent posts of the plurality of posts of the at least one pod.

The HAC system of the fourth aspect may include one or more of the previous embodiments and, optionally, that the at least one pod includes a fluid cooling module, the fluid cooling module configured to provide fluid to the adjacent rows of server racks for fluid cooling when the adjacent rows of server racks are installed with the system.

The HAC system of the fourth aspect may include one or more of the previous embodiments and, optionally, that the fluid cooling module is a liquid cooling module that supplies a liquid coolant at a first lower temperature to, and receives liquid coolant at a second higher temperature from, the adjacent rows of server racks when the adjacent rows of server racks are installed with the system.

The HAC system of the fourth aspect may include one or more of the previous embodiments and, optionally, that the fluid cooling module includes a frame couplable to a particular frame module of the at least one pod. The fluid cooling module includes at least one supply pipe insertable in the frame and for a fluid at a first lower temperature. The fluid cooling module includes at least one supply line fluidically coupled with the supply pipe and the adjacent rows of server racks when the adjacent rows of server racks are installed with the HAC system. The fluid cooling module includes at least one return pipe insertable in the frame and for a fluid at a second higher temperature. The fluid cooling module includes at least one return line fluidically coupled with the return pipe and the adjacent rows of server racks when the adjacent rows of server racks are installed with the HAC system.

The HAC system of the fourth aspect may include one or more of the previous embodiments and, optionally, that the at least one supply pipe includes two supply pipes that are fluidically coupled via a supply pipe joint to circulate supply fluid between supply ports located at one end of the pod. The at least one return pipe include two return pipes that are fluidically coupled via a return pipe joint to circulate return fluid between return ports located at one end of the pod.

The HAC system of the fourth aspect may include one or more of the previous embodiments and, optionally, that at least some ceiling panels of the plurality of ceiling panels are installed in the fluid cooling module and couplable to the frame module of the at least one pod.

The HAC system of the fourth aspect may include one or more of the previous embodiments and, optionally, a transition corridor module couplable to the frame module of a particular pod of the at least one pod at an end of the HAC system opposite the end of the HAC system to which the door module is couplable. The transition corridor module is configured to at least one of contain and direct hot air exhausted from the adjacent rows of server racks when the adjacent rows of server racks are installed with the HAC system.

A fifth aspect of the present disclosure is to provide a pod for a modularized HAC system. The pod includes a frame module including a plurality of posts. Spacing between adjacent posts of the plurality of posts is dimensioned to receive adjacent rows of server racks and at least partially surround an aisle defined between the adjacent rows of server racks when the adjacent rows of server racks are installed with the pod. The pod includes a module including at least one hanger arm assembly couplable to the frame module, the at least one hanger arm assembly including a plurality of arms that are adjustable within the hanger arm assembly and relative to the frame module. The frame module and the module including the at least one hanger arm assembly are assembled to form at least one pod at a first location, and are deliverable pre-assembled as the at least one pod for installation with the adjacent rows of server racks to a second location.

The pod of the fifth aspect may include, optionally, that the frame module is couplable to a plurality of windows, a plurality of ceiling panels, and a door module. The frame module, the module including the at least one hanger arm assembly, the plurality of windows, the plurality of ceiling panels, and the door module are assembled to form the at least one pod at a first location, and are deliverable pre-assembled as the at least one pod for installation with the adjacent rows of server racks to a second location. The plurality of windows, the plurality of ceiling panels, and the door module are configured to at least partially enclose the defined aisle between adjacent rows of server racks to at least one of contain and direct hot air exhausted from the adjacent rows of server racks through the defined aisle when the adjacent rows of server racks are installed with the pod.

The pod of the fifth aspect may include one or more of the previous embodiments and, optionally, a fluid cooling module, the fluid cooling module configured to provide fluid to the adjacent rows of server racks for fluid cooling when the adjacent rows of server racks are installed with the pod.

A sixth aspect of the present disclosure is to provide a method. The method may include, but is not limited to, designing one or more modules for at least one pod of a modularized hot aisle containment system. The one or more modules include a frame module including a plurality of posts. Spacing between adjacent posts of the plurality of posts is dimensioned to receive adjacent rows of server racks and at least partially surround an aisle defined between the adjacent rows of server racks when the adjacent rows of server racks are installed with the HAC system. The one or more modules include a module including at least one hanger arm assembly couplable to the frame module, the at least one hanger arm assembly including a plurality of arms that are adjustable within the hanger arm assembly and relative to the frame module.

The method of the sixth aspect may include, but is not limited to, manufacturing the one or more modules for at least one pod of the HAC system,

The method of the sixth aspect may include, but is not limited to, assembling the at least one pod of the HAC system. The frame module and the module including the at least one hanger arm assembly are assembled to form the at least one pod at a first location, and the at least one pod is deliverable pre-assembled for installation with the adjacent rows of server racks to a second location.

The method of the sixth aspect may include, but is not limited to, that designing one or more modules for at least one pod of a modularized hot aisle containment system includes designing a fluid cooling module, the fluid cooling module configured to provide fluid to the adjacent rows of server racks for fluid cooling when the adjacent rows of server racks are installed with the HAC system.

A seventh aspect of the present disclosure is to provide a data center. The data center includes adjacent rows of server racks that define an aisle therebetween. The data center includes a modularized HAC system dimensioned to at least partially enclose the adjacent rows of server racks. The HAC system includes at least one pod. The at least one pod includes a frame module including a plurality of posts. Spacing between adjacent posts of the plurality of posts is dimensioned to receive the adjacent rows of server racks and at least partially surround the aisle defined between the adjacent rows of server racks. The at least one pod includes a module with at least one hanger arm assembly couplable to the frame module. The at least one hanger arm assembly includes a plurality of arms that are adjustable within the hanger arm assembly and relative to the frame module. The HAC system includes a plurality of windows couplable to the frame module of the at least one pod. The HAC system includes a plurality of ceiling panels couplable to the frame module of the at least one pod. The HAC system includes a door module couplable to the frame module of a particular pod of the at least one pod at an end of the system. The plurality of windows, the plurality of ceiling panels, and the door module are configured to at least partially enclose the defined aisle between adjacent rows of server racks to at least one of contain and direct hot air exhausted from the adjacent rows of server racks through the defined aisle when the adjacent rows of server racks are installed with the system.

The data center of the seventh aspect may include, optionally, that the at least one pod of the system is installed in the data center in a pre-assembled configuration including the frame module, the module including the at least one hanger arm assembly, the plurality of windows, the plurality of ceiling panels, and the door module.

The data center of the seventh aspect may include one or more of the previous embodiments and, optionally, a mechanical corridor proximate to a wall surface.

The data center of the seventh aspect may include one or more of the previous embodiments and, optionally, that the HAC system comprises a transition corridor module couplable to the frame module of a particular pod of the at least one pod at an end of the HAC system opposite the end of the HAC system to which the door module is couplable. The wall surface includes an opening that connects the transition corridor module of the HAC system and the mechanical corridor.

The data center of the seventh aspect may include one or more of the previous embodiments and, optionally, that the transition corridor module is configured to at least one of contain and direct hot air exhausted from the adjacent rows of server racks through the opening into the mechanical corridor.

The data center of the seventh aspect may include one or more of the previous embodiments and, optionally, that a security screen is installed within the opening that connects the transition corridor module of the HAC system and the mechanical corridor.

The data center of the seventh aspect may include one or more of the previous embodiments and, optionally, a ceiling-mounted cooling unit within the mechanical corridor and proximate to the HAC system and configured to provide cool air over the HAC system.

The data center of the seventh aspect may include one or more of the previous embodiments and, optionally, stacked cooling units within the mechanical corridor and proximate to the HAC system and configured to provide cool air over the HAC system.

The data center of the seventh aspect may include one or more of the previous embodiments and, optionally, that the HAC system includes a fluid cooling module, the fluid cooling module configured to provide fluid to the adjacent rows of server racks for fluid cooling.

The data center of the seventh aspect may include one or more of the previous embodiments and, optionally, that the fluid cooling module includes a frame couplable to a particular frame module of the at least one pod. The fluid cooling module includes at least one supply pipe insertable in the frame and for a fluid at a first lower temperature. The fluid cooling module includes at least one supply line in fluid communication with the supply pipe and the adjacent rows of server racks. The fluid cooling module includes at least one return pipe insertable in the frame and for a fluid at a second higher temperature. The fluid cooling module includes at least one return line in fluid communication with the return pipe and the adjacent rows of server racks.

The data center of the seventh aspect may include one or more of the previous embodiments and, optionally, that the at least one supply pipe is fluidically coupled to at least one supply port through a wall surface to a mechanical corridor. The at least one return pipe is fluidically coupled to at least one return port through the wall surface to the mechanical corridor.

The data center of the seventh aspect may include one or more of the previous embodiments and, optionally, the at least one supply port includes two supply ports. The at least one return port includes two return ports. The at least one supply pipe includes two supply pipes that are fluidically coupled via a supply pipe joint to circulate supply fluid between the two supply ports. The at least one return pipe include two return pipes that are fluidically coupled via a return pipe joint to circulate return fluid between the two return ports.

The data center of the seventh aspect may include one or more of the previous embodiments and, optionally, a control system. The control system includes a control unit in communication including one or more processors and memory. The one or more processors are configured to execute program instructions stored in memory. The program instructions are configured to cause the one or more processors to perform diagnostics on one or more components of the server racks and at least one pod of the HAC system. The program instructions are configured to cause the one or more processors to monitor operational parameters of one or more components of the server racks and at least one pod of the HAC system. The program instructions are configured to cause the one or more processors to adjust the operational parameters of the one or more components of the server racks and at least one pod of the HAC system.

The data center of the seventh aspect may include one or more of the previous embodiments and, optionally, that one or more of fluid-cooling temperature, air exhaust air temperature, per-pod average power density, and per-server rack operation status is at least one of monitored and adjusted by the control unit.

The data center of the seventh aspect may include one or more of the previous embodiments and, optionally, that the control system includes a user interface configured to display information about the operational parameters of the HAC system.

The data center of the seventh aspect may include one or more of the previous embodiments and, optionally, that the user interface is mounted on the HAC system.

An eighth aspect of the present disclosure is to provide a control system for a data center including a modularized hot aisle containment (HAC) system with one or more rows of server racks and an aisle defined therebetween. The control system includes a control unit in communication including one or more processors and memory. The one or more processors are configured to execute program instructions stored in memory. The program instructions are configured to cause the one or more processors to perform diagnostics on one or more components of the server racks and at least one pod of the HAC system. The program instructions are configured to cause the one or more processors to monitor operational parameters of one or more components of the server racks and at least one pod of the HAC system. The program instructions are configured to cause the one or more processors to adjust the operational parameters of the one or more components of the server racks and at least one pod of the HAC system.

The control system of the eighth aspect may include, optionally, a user interface configured to display information about the operational parameters of the HAC system.

A ninth aspect of the present disclosure is to provide a method. The method may include, but is not limited to, performing diagnostics on one or more components of server racks and at least one pod of a modularized hot aisle containment (HAC) system installed within a data center. The method may include, but is not limited to, monitoring operational parameters of one or more components of the server racks and at least one pod of the HAC system. The method may include, but is not limited to, adjusting the operational parameters of the one or more components of the server racks and at least one pod of the HAC system.

The method of the ninth aspect may include, but is not limited to, that at least one of the performing diagnostics, the monitoring operational parameters, and the adjusting the operational parameters is via a control system of the data center.

Another aspect of the present disclosure is to provide a HAC system as substantially described herein.

Another aspect of the present disclosure is to provide a pod for a HAC system as substantially described herein.

Another aspect of the present disclosure is to provide a module for a pod of a HAC system as substantially described herein.

Another aspect of the present disclosure is to provide a module for a HAC system as substantially described herein.

Another aspect of the present disclosure is to provide a method of designing a modularized HAC system and/or at least one of a component, a module, and a pod of the modularized HAC system, as substantially described herein.

Another aspect of the present disclosure is to provide a method of manufacturing a modularized HAC system and/or at least one of a component, a module, and a pod of the modularized HAC system, as substantially described herein.

Another aspect of the present disclosure is to provide a method of assembling a modularized HAC system and/or at least one of a component, a module, and a pod of the modularized HAC system, as substantially described herein.

Another aspect of the present disclosure is to provide a method of installing a modularized HAC system and/or at least one of a component, a module, and a pod of the modularized HAC system, as substantially described herein.

Another aspect of the present disclosure is to provide a method of performing diagnostics on a modularized HAC system and/or at least one of a component, a module, and a pod of the modularized HAC system, as substantially described herein.

Another aspect of the present disclosure is to provide a method of monitoring operational parameters of a modularized HAC system and/or at least one of a component, a module, and a pod of the modularized HAC system, as substantially described herein.

Another aspect of the present disclosure is to provide a method of adjusting operational parameters of a modularized HAC system and/or at least one of a component, a module, and a pod of the modularized HAC system, as substantially described herein.

The phrases “at least one”, “one or more”, and “and/or”, as used herein, are open-ended expressions that are both conjunctive and disjunctive in operation. For example, each of the expressions “at least one of A, B and C,” “at least one of A, B, or C,” “one or more of A, B, and C,” “one or more of A, B, or C,” and “A, B, and/or C” means A alone, B alone, C alone, A and B together, A and C together, B and C together, or A, B and C together.

Unless otherwise indicated, all numbers expressing quantities, dimensions, conditions, and so forth used in the specification and claims are to be understood as being modified in all instances by the term “about” or “approximately”. As used herein, unless otherwise specified, the terms “about,” “approximately,” etc., when used in relation to numerical limitations or ranges, mean that the recited limitation or range may vary by up to 10%. By way of non-limiting example, “about 750” can mean as little as 675 or as much as 825, or any value therebetween. When used in relation to ratios or relationships between two or more numerical limitations or ranges, the terms “about,” “approximately,” etc. mean that each of the limitations or ranges may vary by up to 10%; by way of non-limiting example, a statement that two quantities are “approximately equal” can mean that a ratio between the two quantities is as little as 0.9:1.1 or as much as 1.1:0.9 (or any value therebetween), and a statement that a four-way ratio is “about 5:3:1:1” can mean that the first number in the ratio can be any value of at least 4.5 and no more than 5.5, the second number in the ratio can be any value of at least 2.7 and no more than 3.3, and so on.

The use of “substantially” in the present disclosure, when referring to a measurable quantity (e.g., a diameter or other distance) and used for purposes of comparison, is intended to mean within 5% of the comparative quantity. The terms “substantially similar to,” “substantially the same as,” and “substantially equal to,” as used herein, should be interpreted as if explicitly reciting and encompassing the special case in which the items of comparison are “similar to,” “the same as” and “equal to,” respectively.

The term “a” or “an” entity, as used herein, refers to one or more of that entity. As such, the terms “a” (or “an”), “one or more” and “at least one” can be used interchangeably herein.

The use of “including,” “comprising,” or “having” and variations thereof herein is meant to encompass the items listed thereafter and equivalents thereof as well as additional items. Accordingly, the terms “including,” “comprising,” or “having” and variations thereof can be used interchangeably herein. The use of “engaged with” and variations thereof herein is meant to encompass any direct or indirect connections between components.

It shall be understood that the term “means” as used herein shall be given its broadest possible interpretation in accordance with 35 U.S.C. § 112(f). Accordingly, a claim incorporating the term “means” shall cover all structures, materials, or acts set forth herein, and all of the equivalents thereof. Further, the structures, materials, or acts and the equivalents thereof shall include all those described in the Summary, Brief Description of the Drawings, Detailed Description, Abstract, and claims themselves.

These and other advantages will be apparent from the disclosure of the invention(s) contained herein. The above-described embodiments, objectives, and configurations are neither complete nor exhaustive. The Summary is neither intended nor should it be construed as being representative of the full extent and scope of the present disclosure. Moreover, references made herein to “the present disclosure” or aspects thereof should be understood to mean certain embodiments of the present disclosure and should not necessarily be construed as limiting all embodiments to a particular description. The present disclosure is set forth in various levels of detail in the Summary as well as in the attached drawings and the Detailed Description and no limitation as to the scope of the present disclosure is intended by either the inclusion or non-inclusion of elements, components, etc. in this Summary. Additional aspects of the present disclosure will become more readily apparent from the Detailed Description, particularly when taken together with the drawings.

It is to be appreciated that any feature or aspect described herein can be claimed in combination with any other feature(s) or aspect(s) as described herein, regardless of whether the features or aspects come from the same described embodiment.

Any one or more aspects described herein can be combined with any other one or more aspects described herein. Any one or more features described herein can be combined with any other one or more features described herein. Any one or more embodiments described herein can be combined with any other one or more embodiments described herein.

### BRIEF DESCRIPTION OF THE DRAWINGS

Those of skill in the art will recognize that the following description is merely illustrative of the principles of the disclosure, which may be applied in various ways to provide many different alternative embodiments. This description is made for illustrating the general principles of the teachings of this disclosure and is not meant to limit the inventive concepts disclosed herein.

The accompanying drawings illustrate embodiments of the disclosure and together with the general description of the disclosure given above and the detailed description of the drawings given below, serve to explain the principles of the disclosure.

FIG. 1A is a perspective view of a pod for a Hot Aisle Containment (HAC) system, in accordance with one or more embodiments of the present disclosure;

FIG. 1B is a side elevation view of the pod of FIG. 1A;

FIG. 1C is an end view of the pod of FIG. 1A;

FIG. 2 is a perspective view of a frame module for the pod of FIG. 1A;

FIG. 3 is a perspective view of a power module for the pod of FIG. 1A;

FIG. 4A is a perspective view of a fluid cooling module for the pod of FIG. 1A;

FIG. 4B is a perspective view of a supply line of the fluid cooling module of FIG. 4A;

FIG. 4C is a perspective view of a variation of the supply line of FIG. 4B;

FIG. 4D is a perspective view of a return line of the fluid cooling module of FIG. 4A;

FIG. 4E is a perspective view of a variation of the return line of FIG. 4D;

FIG. 4F is a perspective view of a variation of the supply line of FIG. 4B or the return line of FIG. 4D;

FIG. 5 is a partial perspective view of a ceiling portion of the fluid cooling module of FIG. 4A;

FIG. 6 is a partial perspective view of a variation of a ceiling portion of the fluid cooling module of FIG. 4A;

FIG. 7 is a perspective view of a tray module for the pod of FIG. 1A;

FIG. 8 is a perspective view of a panel module for the pod of FIG. 1A;

FIG. 9A is a perspective view of an HAC system including a plurality of pods of FIG. 1A, in accordance with one or more embodiments of the present disclosure;

FIG. 9B is a perspective view of a particular end pod of the HAC system of FIG. 9A;

FIG. 10 is a perspective view of a power end module of the HAC system of FIG. 9A;

FIG. 11A is a perspective view of a set of fluid cooling pipes of the HAC system of FIG. 9A;

FIG. 11B is a perspective view of the fluid cooling pipes of the HAC system of FIG. 9A;

FIG. 12 is a perspective view of an end tray module of the HAC system of FIG. 9A;

FIG. 13 is a perspective view of a door module of the HAC system of FIG. 9A;

FIG. 14 is a perspective view of a module cover of the HAC system of FIG. 9A;

FIG. 15 is a front view of the HAC system of FIG. 9A;

FIG. 16A is a perspective view of a variation of the HAC system of FIG. 9A, the variation of the HAC system including a plurality of a variation of the pods of FIG. 1A;

FIG. 16B is a side elevation view of the HAC system and pods in FIG. 16A;

FIG. 16C is a top plan view of the HAC system and pods in FIG. 16A;

FIG. 16D is an end view of the HAC system and pods in FIG. 16A;

FIG. 16E is a hanger arm assembly of the HAC system and pods in FIG. 16A;

FIG. 16F is a perspective view of a portion of the HAC system and pods in FIG. 16A;

FIG. 16G is a truss shown in the portion of the HAC system and pods in FIG. 16F;

FIG. 16H is a perspective view of a second portion of the HAC system and pods in FIG. 16A;

FIG. 16I is a fluid conduit plate shown in the portion of the HAC system and pods in FIG. 16H;

FIG. 16J is a perspective view of a variation of the HAC system and pods in FIG. 16A;

FIG. 17 is a comparison of the HAC system and pods of FIG. 16A configured for air-cooling versus configured for fluid-cooling;

FIG. 18A is a perspective view of the HAC system and pods of FIG. 16A with server racks, where the HAC system and pods are configured with fluid-cooling capabilities;

FIG. 18B is a perspective view of the fluid-cooling capabilities of the system and pods of FIG. 18A;

FIG. 18C is a perspective view of a pipe hanger assembly of the HAC system and pods of FIG. 18A;

FIG. 18D is a perspective view of the HAC system and pods of FIG. 18A with power conduits and shelves;

FIG. 18E is a perspective view of the HAC system and pods of FIG. 18A with cable trays;

FIG. 19A is a side elevation view of the HAC system and pods of FIG. 18A with ceiling-mounted air-cooling capabilities;

FIG. 19B is a side elevation view of the HAC system and pods of FIG. 18A with floor-or wall-mounted air-cooling capabilities; and

FIG. 20A is a control system for the HAC system of FIG. 9A;

FIG. 20B is a graphical user interface of FIG. 20A including information related to the HAC system of FIG. 9A; and

FIG. 21 is a process flow diagram for the design, manufacturing, assembly, installation, and operation of the HAC system of FIG. 9A including the pod of FIG. 1A and/or the HAC system with pods of FIG. 16A, in accordance with one or more embodiments of the present disclosure.

It should be understood that the drawings are not necessarily to scale, and various dimensions may be altered. In certain instances, details that are not necessary for an understanding of the disclosure or that render other details difficult to perceive may have been omitted. It should be understood, of course, that the disclosure is not necessarily limited to the particular embodiments illustrated herein. It is noted that any line in the drawings may be illustrated as solid or broken lines, including any section or length of each individual line, without departing from the scope of the present disclosure.

It will be appreciated that recitation of, for example, reference character 117, 117A, 117B, etc. may apply to any combination of reference characters 117, 117A, 117B, etc. In addition, it will be appreciated any reference characters “xx01”, “01”, and “1”, etc. within the figures and the description are referring to the same component within a system or operation of a method.

In the figures:

| Reference | |
|---|---|
| Number | Component |
| 100, 100A | Pod |
| 100B, 100C | Pod |
| 102 | Row |
| 104 | Server Rack |
| 106 | Aisle |
| 200 | Frame Module |
| 202 | Rigging Post |
| 204 | Anchor Plates |
| 206 | Crossmember |
| 208 | Coupling Element |
| 210 | Brace |
| 212 | Coupling Element |
| 300 | Power Module |
| 301 | Frame |
| 302 | Sleeve |
| 304 | Coupler Element |
| 306 | Bracket Mount |
| 308 | Bracket |
| 310 | Hanger Arm Assembly |
| 312 | Bar |
| 314 | Coupler Element |
| 316 | Arm |
| 318 | Coupler Element |
| 320 | Power Conduit |
| 322 | Row |
| 400 | Fluid Cooling Module |
| 401 | Frame |
| 402 | Sleeves |
| 404 | Coupler Element |
| 406 | Crossmember |
| 408 | Posts |
| 410 | Braces |
| 412 | Supply Pipe |
| 414 | Return Pipe |
| 416 | Pipe Set |
| 418, 418A | Supply Line |
| 418B, 418C | Supply Line |
| 420, 420A | Return Line |
| 420B, 420C | Return Line |
| 422 | Manual Valve |
| 424 | Solenoid Valve |
| 426 | Sensor |
| 428 | Flow Meter |
| 430 | Line Joint |
| 500 | Ceiling Panel |
| 600 | Catwalk Panel |
| 00 | Tray Module |
| 701 | Frame |
| 702 | Sleeves |
| 704 | Coupler Element |
| 706 | Bracket |
| 708 | Bracket Mount |
| 710 | Hanger Arm Assembly |
| 712 | Bar |
| 714 | Coupler Element |
| 716 | Arm |
| 718 | Coupler Element |
| 720 | Cable Tray |
| 722 | Row |
| 724 | Shelf |
| 726 | Row |
| 800 | Panel Module |
| 801 | Frame |
| 802 | Sleeve |
| 804 | Coupler Element |
| 806 | Window |
| 808 | Pane |
| 810 | Barrier |
| 900 | Hot Aisle Containment (HAC) System |
| 902 | Floor Surface |
| 904 | Wall Surface |
| 1000 | Power End Module |
| 1002 | Bracket Mount |
| 1004 | Coupler Element |
| 1006 | Hanger Arm Assembly |
| 1008 | Bracket |
| 1010 | Arm |
| 1012 | Coupler Element |
| 1014 | Power Conduit Joint |
| 1016 | Row |
| 1018 | End Stop |
| 1100 | Fluid End Module |
| 1102 | Supply Port |
| 1104 | Return Port |
| 1106 | Supply Pipe Joint |
| 1108 | Return Pipe Joint |
| 1200 | End Tray Module |
| 1202 | Sleeve |
| 1204 | Coupler Element |
| 1206 | Bracket Mounts |
| 1208 | Bracket |
| 1210 | Hanger Arm Assembly |
| 1212 | Bar |
| 1214 | Coupler Element |
| 1216 | Arm |
| 1218 | Coupler Element |
| 1220 | Cable Trays |
| 1222 | Row |
| 1224 | Shelf |
| 1226 | Row |
| 1300 | Door Module |
| 1302 | Door Assembly |
| 1304 | Frame |
| 1306 | Fixed Portion of Frame |
| 1308 | Door |
| 1310 | Pane |
| 1312 | Divider Assembly |
| 1314 | Frame |
| 1316 | Window |
| 1318 | Pane |
| 1400 | End Cover Module |
| 1402 | Cover |
| 1404 | Indicia |
| 1500 | Accessory Module |
| 1502 | Cooler Platform |
| 1504 | User Interface |
| 1600, 1600A | HAC System |
| 1600B | HAC System |
| 1602, 1602A | Pod |
| 1602B, 1602C | Pod |
| 1604 | Frame Module |
| 1606 | Post |
| 1608 | Anchor Plate |
| 1610 | Crossmember |
| 1612 | Brace |
| 1614 | Hanger Arm Assembly |
| 1616 | Bar |
| 1618 | Arm |
| 1620 | Window |
| 1622 | Pane |
| 1624 | Ceiling Panel |
| 1626 | Pane |
| 1628 | Door Module |
| 1630 | Door Assembly |
| 1632 | Frame |
| 1634 | Fixed Portion |
| 1636 | Door |
| 1638 | Pane |
| 1640 | Transition Corridor Module |
| 1642 | Frame |
| 1644 | Post |
| 1646 | Anchor Plate |
| 1648 | Fixed Portion |
| 1650 | Door |
| 1652 | Opening |
| 1654 | Pane |
| 1656 | Ceiling Panel |
| 1658 | Pane |
| 1660 | Truss Plate |
| 1662 | Frame |
| 1664 | Window |
| 1666 | Pane |
| 1668 | Fluid Conduit Plate |
| 1670 | Frame |
| 1672 | Window |
| 1674 | Pane |
| 1676 | Aperture |
| 1800 | Fluid Cooling Module |
| 1802 | Supply Pipe |
| 1804 | Return Pipe |
| 1806 | Pipe Set |
| 1808 | Supply Line |
| 1810 | Return Line |
| 1812 | Valve |
| 1814 | Frame |
| 1816 | Crossmember |
| 1818 | Post |
| 1820 | Brace |
| 1822 | Hanger |
| 1824 | Power Conduit |
| 1826 | Shelf |
| 1828 | Power End Module |
| 1830 | Power Conduit Joint |
| 1832 | End Stop |
| 1834 | Cable Tray |
| 1900 | Ceiling-Mounted Cooling Unit |
| 1902 | Ceiling Surface |
| 1904 | Warm Air |
| 1906 | Cool Air |
| 1908 | Stacked Cooling Unit |
| 2000 | Control System |
| 2001 | Data |
| 2002 | Control Unit |
| 2003 | Instructions |
| 2004 | Processor |
| 2006 | Memory |
| 2008 | Program Instructions |
| 2010 | User Interface |
| 2012 | Display |
| 2014 | User Input Device |
| 2016 | Port Connectors |
| 2018 | Mechanical Corridor |
| 2020 | Data Center |
| 2022 | Opening |
| 2024 | Security Screen |
| 2100 | Method or Process |
| 2102 | Design Modules, Pods, and/or HAC System |
| 2104 | Manufacture Modules, Pods, and/or HAC System |
| 2106 | Assemble Modules, Pods, and/or HAC System |
| 2108 | Install Modules, Pods, and/or HAC System |
| 2110 | Perform Diagnostics of Modules, Pods, and/ |
| | or HAC System |
| 2112 | Monitor Operational Parameters of Modules, |
| | Pods, and/or HAC System |
| 2114 | Adjust Operational Parameters of Modules, |
| | Pods, and/or HAC System |

### DETAILED DESCRIPTION

Although the following text sets forth a detailed description of numerous different embodiments, it should be understood that the legal scope of the description is defined by the words of the claims set forth at the end of this disclosure. The Detailed Description is to be construed as exemplary only and does not describe every possible embodiment of the modularized Hot Aisle Containment (HAC) system since describing every possible embodiment would be impractical, if not impossible. Numerous alternative embodiments could be implemented, using either current technology or technology developed after the filing date of this patent, which would still fall within the scope of the claims. Additionally, any combination of features shown in the various figures can be used to create additional embodiments of the present disclosure. Thus, dimensions, aspects, and features of one embodiment of the modularized HAC system can be combined with dimensions, aspects, and features of another embodiment of the modularized HAC system to create the claimed embodiment.

Embodiments of the present disclosure are directed to a modularized HAC system, and methods related to the manufacturing, assembly, installation, and operation of the same. The modularized HAC system includes one or more pods, where each pod includes a series of modules that are installed proximate to one or more rows of server racks (e.g., including, optionally, two rows of server racks defining an aisle therebetween, into which exhaust is directed). The modularized HAC system includes shared modules or components installable within and/or at an end of the one or more pods. Together, the HAC system may be installed at a project site in aisles, where each aisle includes one or more pods (and shared components) that make up the HAC system with the one or more rows of server racks.

In embodiments, information about the operational parameters of the HAC system, the pods within the HAC system, the modules within the pods, the shared components or modules of the HAC system, and/or the components for the modules. The information may be provided at each respective pod, or at a single location on the HAC system, and/or at a separate location from the HAC system, including via a user interface.

In embodiments, modules of the pods (and/or full pods) and/or the shared components or modules of the HAC system may be designed, manufactured, and assembled as a factory or other manufacturing facility. The assembled modules, shared components or modules, and/or pods of modules may then be provided to a project site, streamlining the assembly process prior to installation and reducing the possibility of installation error while increasing quality control and consistency of assembly and installation across different products.

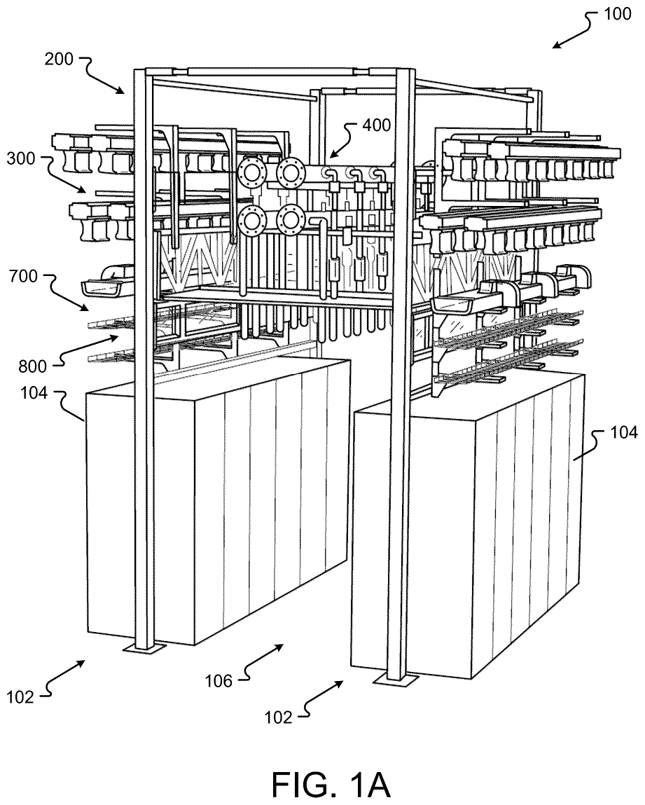

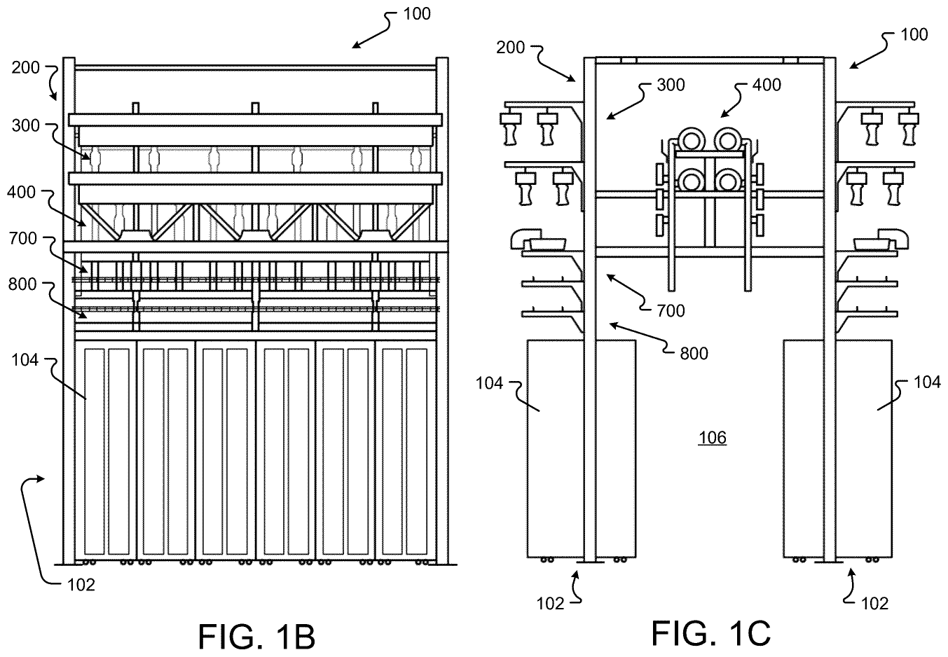

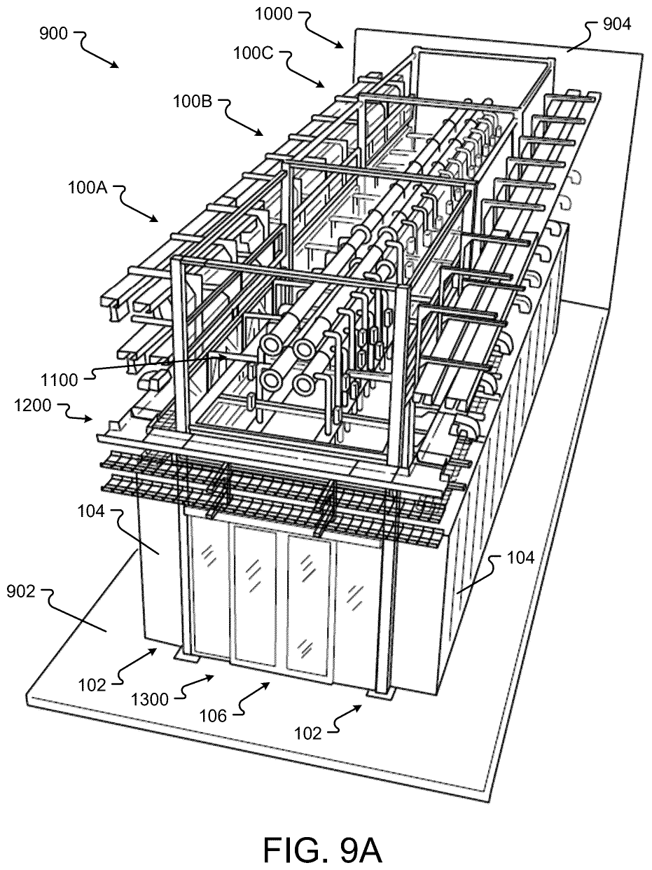

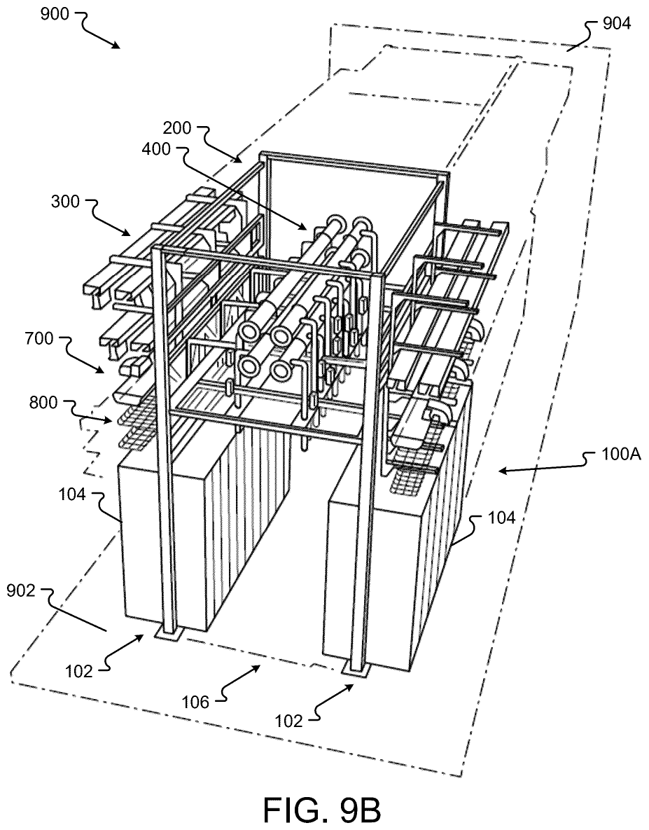

FIGS. 1A-8 generally illustrate a pod 100 of an HAC system 900 of FIGS. 9A-15, in accordance with one or more embodiments of the present disclosure. In particular, FIG. 1A is a perspective view of the pod 100, FIG. 1B is a side view of the pod 100, and FIG. 1C is an end view of the pod 100.

As illustrated in FIGS. 1A-1C, the pod 100 may include (or be installed proximate to) one or more rows 102 of server racks 104. For example, the pod 100 may include (or be installed proximate to) two rows 102 of server racks 104 that define a gap or space for exhaust therebetween. It is noted that the pod 100 and the one or more rows 102 of server racks 104 may be arranged in an aisle configuration, such that the gap or space is an aisle 106, for purposes of the present disclosure.

In embodiments, the pod 100 includes a frame module 200. For example, one or more of a power module 300, a fluid cooling module 400, a tray module 700, and a panel module 800 may be coupled to the frame module 200 in a fixed or an adjustable position, as described in detail further herein. Although the pod 100 illustrates the modules 200, 300, 400, 700, 800 in a particular order or arrangement (e.g., as stacked vertically upward from a ground surface), it is contemplated that the order or arrangement of the modules 200, 300, 400, 700, 800 may be changed without departing from the scope of the present disclosure. Rather, the present disclosure is directed to the general arrangement of modules 200, 300, 400, 700, 800 within a modular build for a pod 100, which may be fabricated and assembled efficiently while reducing possible error during fabrication and assembly processes.

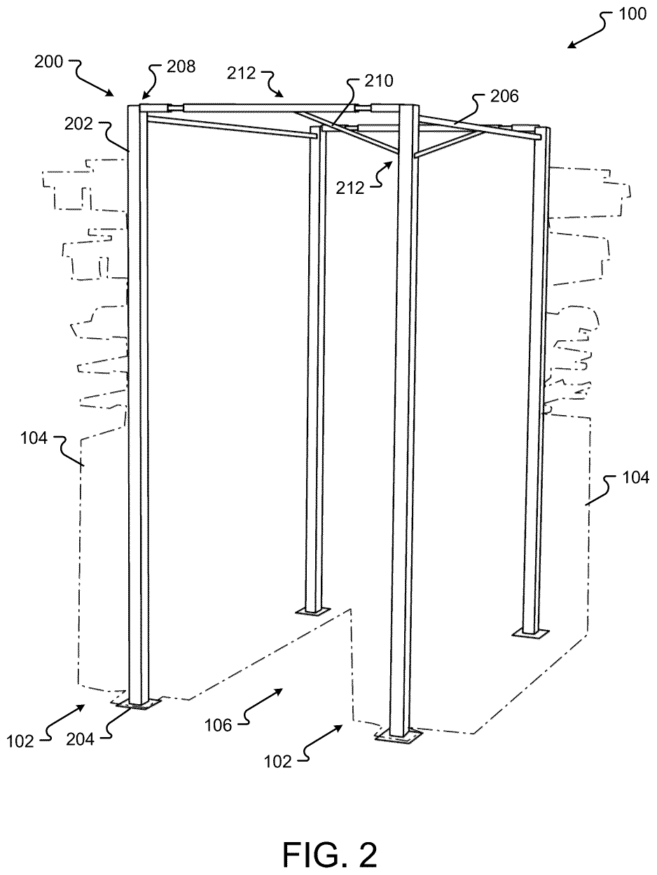

Reference will be made to the pod 100 and the modules 200, 300, 400, 700, 800 in detail further herein. It is noted that any and/or all of the subassemblies of the pod 100 may include further subassemblies as described in detail further herein, which are each considered subassemblies of the HAC system 900. In addition, it is noted that one or more of the various modules and features of the pod 100 shown in FIGS. 1A-1C are illustrated in FIG. 2-8, with select modules and features removed between the various FIGS. 2-8 for ease of review only.

Referring now to FIG. 2, a perspective view of a frame module 200 of the pod 100 is illustrated. In embodiments, the frame module 200 includes a set of rigging posts 202 in a vertical or substantially vertical orientation. For example, the rigging posts 202 may be secured with anchor plates 204 to a pre-existing floor surface and/or a raised floor located above a pre-existing floor surface. By way of another example, the rigging posts 202 may be secured with anchor plates 204 to a pre-existing ceiling surface and/or a suspended ceiling located below a pre-existing ceiling surface. By way of another example, the rigging posts 202 may be secured with anchor plates 204 to a pre-existing wall surface and/or a standoff wall located proximate to a pre-existing wall surface.

In embodiments, the frame module 200 may include a set of crossmembers 206 in a horizontal or substantially horizontal orientation, and attached to the set of rigging posts 202. For example, a crossmember 206 may be coupled to adjacent posts 202. By way of another example, a crossmember 206 may be coupled to corner posts 202. One or more of the crossmembers 206 may be coupled to respective posts 202 via coupler elements 208 including, but not limited to, interlocking assemblies, fasteners, adhesives, and the like. Alternatively, or in addition, one or more of the crossmembers 206 may be affixed to respective posts 202 via joining processes (e.g., welding, or the like).

In embodiments, the frame module may include a set of braces 210 attached to the rigging posts 202 and/or the crossmembers 206. For example, a brace 210 may be coupled to a post 202 and a crossmember 206. By way of another example, a brace 210 may be coupled between crossmembers 206. One or more of the braces 210 may be coupled to respective posts 202 and crossmembers 206 via coupler elements 212 including, but not limited to, interlocking assemblies, fasteners, adhesives, or the like. Alternatively, or in addition, one or more of the braces 210 may be affixed to respective posts 202 and crossmember 206 via joining processes (e.g., welding, or the like).

It is noted that the braces 210 may be set at an oblique angle relative to the rigging posts 202 and/or the crossmembers 206. However, in other configurations such as where there are multiple tiers of crossmembers 206, the braces 210 may additionally or alternatively be substantially perpendicular to, and attached to, crossmembers 206 within respective tiers.

It is noted that the posts 202, the crossmembers 206, and/or the braces 210 may be fabricated from the same or different stock metal material, without departing from the scope of the present disclosure. In addition, it is noted that the posts 202, the crossmembers 206, and/or the braces 210 may have the same or different cross-section, without departing from the scope of the present disclosure.

In one non-limiting example, the dimensions of the frame module 200) may range between approximately 15 feet and approximately 20 feet in height (e.g., as defined upward from a floor surface). In another non-limiting example, the dimensions of the frame module 200) may range between approximately 12 feet and approximately 13 feet in length (e.g., as defined between ends of the aisle 106 between rows 102 of server racks 104). In another non-limiting example, the dimensions of the frame module 200) may range between approximately 6 feet and 10 feet in width (e.g., as defined across the rows 102 of server racks 104). It should be understood that the above dimensions are not intended on being limiting for purposes of the present disclosure.

In addition, it should be understood that the above dimensions are adjustable, depending at least in part on the aisle 106 arrangement of the pod 100 and rows 102 of server racks 104. For example, it is noted that the posts 202, the crossmembers 206, and/or the braces 210 may have the same or different dimensions in one or more of length, width, and thickness or depth, without departing from the scope of the present disclosure. With respect to length, it is noted that the posts 202, the crossmembers 206, and/or the braces 210 may be a fixed length or may be adjustable in length, without departing from the scope of the present disclosure. In one non-limiting example as generally illustrated in FIGS. 1-10, the length of the posts 202 may be fixed in length (or height) and the crossmembers 206 may be adjustable in length to allow for different spacing between posts 202 during fabrication and assembly of the pod 100, depending at least in part on the aisle 106 arrangement of the pod 100 and rows 102 of server racks 104.

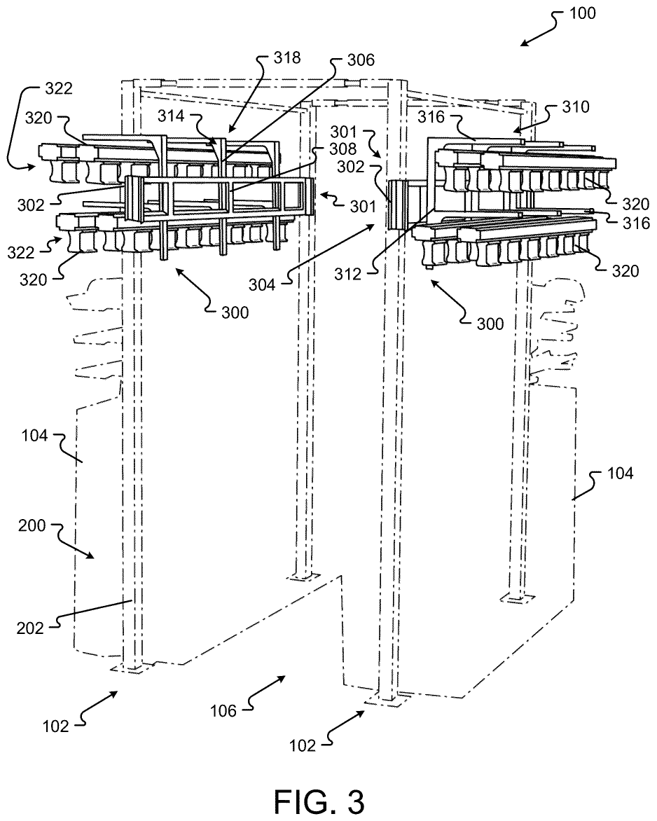

Referring now to FIG. 3, a perspective view of a power module 300 of the pod 100. In embodiments, the power module 300 may be installable on, and positionable at one or more locations on, the frame module 200. For example, the pod 100 may include one power module 300 per row 102 of server racks 104. For instance, where there are two rows 102 of server racks 104, the pod 100 includes two power modules 300. However, it should be understood that this arrangement is not intended to be limiting on the present disclosure.

In embodiments, the power module 300 may be installable on a pair of adjacent posts 202 of the frame module 200 via a frame 301 including respective sleeves 302 for each of the posts 202. The sleeves 302 may be coupled to respective posts 202 via coupler elements 304 including, but not limited to, interlocking assemblies, fasteners, adhesives, or the like. For instance, where coupler elements 304 are used to attach the sleeves 302 to the posts 202, the power module 300 may be height-adjustable on the frame module 200. Alternatively, or in addition, the sleeves 302 may be affixed to respective posts 202 via joining processes (e.g., welding, or the like).

In embodiments, the frame 301 includes one or more bracket mounts 306 that attach to and span a space between the sleeves 302. The one or more bracket mounts 306 may be coupled to the sleeves 302 via coupler elements including, but not limited to, interlocking assemblies, fasteners, adhesives, or the like. Alternatively, or in addition, one or more of the bracket mounts 306 may be affixed to respective sleeves 302 via joining processes (e.g., welding, or the like).

In embodiments, including where there are multiple bracket mounts 306, the frame 301 includes one or more brackets 308 that attach to and span a space between the bracket mounts 306. The one or more brackets 308 may be coupled to the bracket mounts 306 via coupler elements including, but not limited to, interlocking assemblies, fasteners, adhesives, or the like. Alternatively, or in addition, one or more of the brackets 308 may be affixed to respective bracket mounts 306 via joining processes (e.g., welding, or the like).

In embodiments, a hanger arm assembly 310 is attached to the frame 301. The hanger arm assembly 310 includes one or more bars 312. For example, the one or more bars 312 attach to the brackets 308 of the frame 301. The one or more bars 312 may be coupled to the frame 301 via coupler elements 314 including, but not limited to, interlocking assemblies, fasteners, adhesives, or the like. For instance, where coupler elements 314 are used to attach the bars 312 to the frame 301, the hanger arm assembly 310 may be height-adjustable relative to the frame module 200. Alternatively, or in addition, one or more of the bars 312 may be affixed to the frame 301 via joining processes (e.g., welding, or the like).

In embodiments, the hanger arm assembly 310 includes a plurality of arms 316. For example, one or more arms 316 are coupled to a respective bar 312. The one or more arms 316 may be coupled to the bar 312 via coupler elements 318 including, but not limited to, interlocking assemblies, fasteners, adhesives, or the like. For instance, where coupler elements 318 are used to attach the arms 316 to the bars 312, the arms 316 may be height-adjustable relative to the frame module 200. Alternatively, or in addition, one or more of the arms 316 may be affixed to the bars 312 via joining processes (e.g., welding, or the like).

In embodiments, one or more power conduits 320 are attached to the arms 316. For example, the one or more power conduits 320 are coupled to a plurality of arms 316 in a row 322. The one or more power conduits 320 may be coupled to the arms 316 via coupler elements including, but not limited to, interlocking assemblies, fasteners, adhesives, or the like. Alternatively, or in addition, one or more of the power conduits 320 may be affixed to the arms 316 via joining processes (e.g., welding, or the like.

Via the power conduits 320, the power module 300 may routecables or other wiring that supplies or returns primary power. For example, the provided power may be AC and/or DC power, as needed by the pod 100 and/or the modules or components of the pod 100. In some configurations, a power conduit 320 defines a channel with openings at opposite ends and/or openings at one or more locations along the length of the power conduit 320 to route cables for supplies power to the rows 102 of server racks 104. It is noted that the power conduits 320 may optionally supply secondary or redundant power, as may be required by code, without departing from the scope of the present disclosure.

It is noted that each power module 300 may include one or more rows 322 of power conduits 320. To accommodate the multiple rows 322, the hanger arm assembly 310 may include a number of arms 316 corresponding to each of the number of rows 322. For example, each bar 312 may have a number of arms 316 corresponding to each of the number of rows 322 attached. However, it is contemplated other numbers of arms 316 are usable to support the power conduits 320 per row 322 and/or per bar 312, without departing from the scope of the present disclosure.

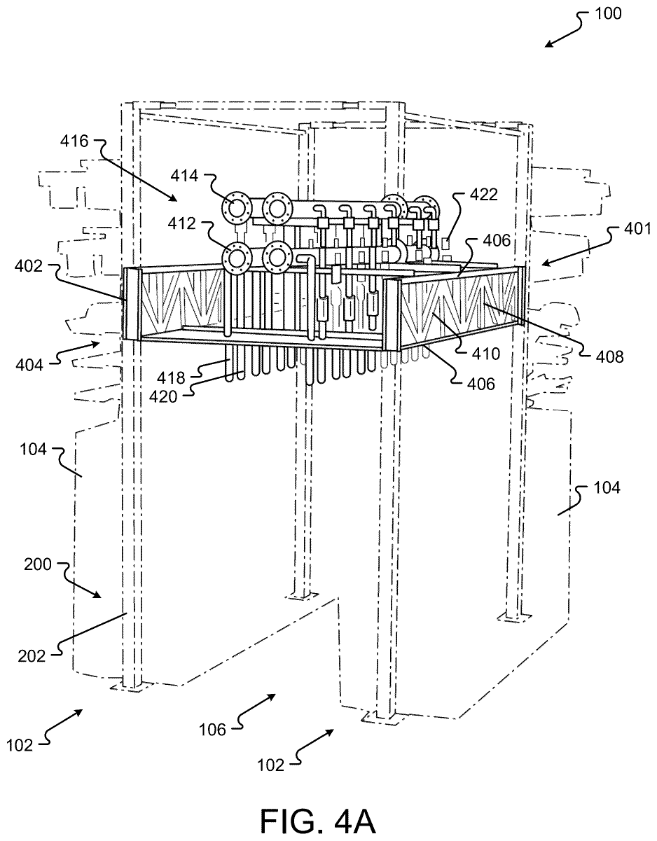

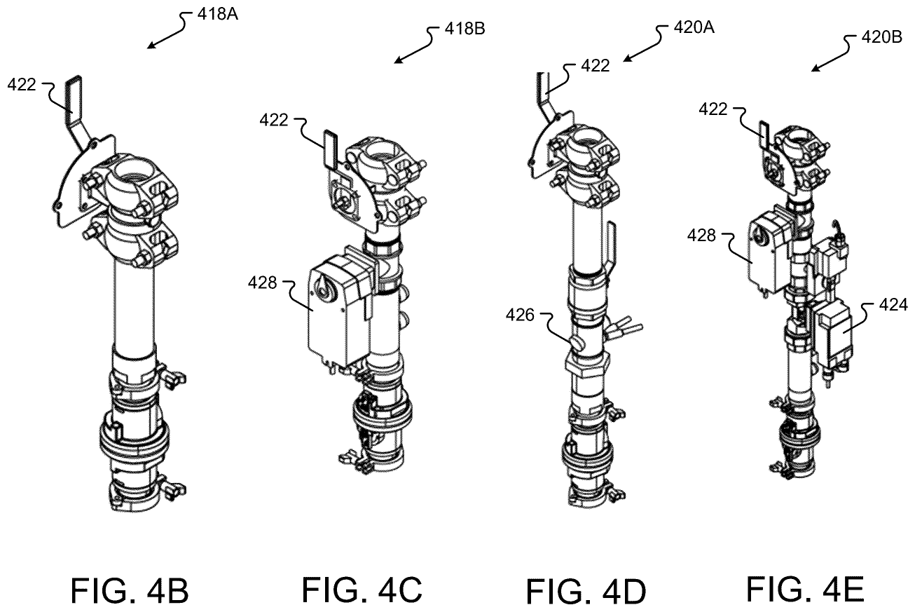

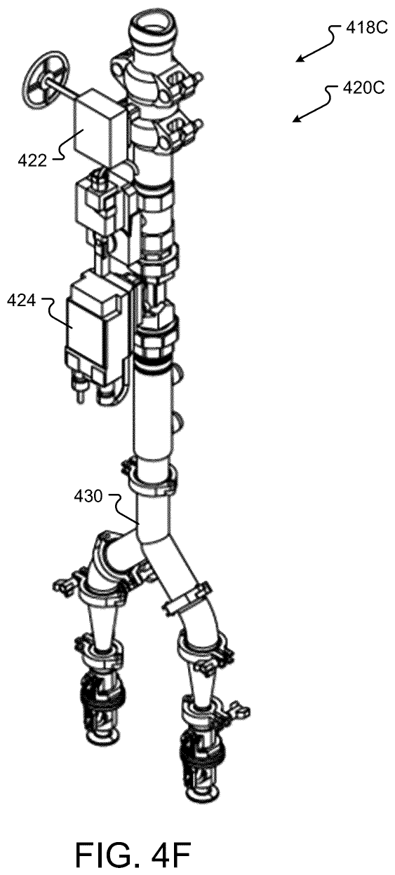

Referring now to FIGS. 4A-4F, a perspective view of a fluid cooling module 400 of the pod 100 is illustrated. In embodiments, the fluid cooling module 400 may be installable on, and positionable at one or more locations on, the frame module 200. For example, the pod 100 may include one fluid cooling module 400 that supplies adjacent rows 102 of server racks 104. For instance, where there are two rows 102 of server racks 104, the pod 100 includes one fluid cooling module 400. However, it should be understood that this arrangement is not intended to be limiting on the present disclosure.

In embodiments, the fluid cooling module 400 may be installable on at least some of the posts 202 of the frame module 200 via a frame 401 including respective sleeves 402 for each of the posts 202. The sleeves 402 may be coupled to respective posts 202 via coupler elements 404 including, but not limited to, interlocking assemblies, fasteners, adhesives, or the like. For instance, where coupler elements 404 are used to attach the sleeves 402 to the posts 202, the fluid cooling module 400 may be height-adjustable on the frame module 200. Alternatively, or in addition, the sleeves 402 may be affixed to respective posts 202 via joining processes (e.g., welding, or the like).

In embodiments, the frame 401 includes a plurality of crossmembers 406 in a horizontal or substantially horizontal orientation, and attached to the sleeves 402. One or more of the crossmembers 406 may be coupled to respective sleeves 402 via coupler elements including, but not limited to, interlocking assemblies, fasteners, adhesives, and the like. Alternatively, or in addition, one or more of the crossmembers 406 may be affixed to respective sleeves 402 via joining processes (e.g., welding, or the like).

In embodiments, the frame 401 includes a plurality of posts 408 in a vertical or substantially vertical orientation, and attached to the crossmembers 406. One or more of the posts 408 may be coupled to respective crossmember 406 via coupler elements including, but not limited to, interlocking assemblies, fasteners, adhesives, and the like. Alternatively, or in addition, one or more of the posts 408 may be affixed to respective crossmembers 406 via joining processes (e.g., welding, or the like).

In embodiments, the frame 401 includes a plurality of braces 410 set at an oblique angle relative to, and attached to, the crossmembers 406 and/or the posts 408. For example, a brace 410 may be coupled to a crossmember 406 and a post 408. One or more of the braces 410 may be coupled to respective crossmembers 406 and posts 408 via coupler elements including, but not limited to, interlocking assemblies, fasteners, adhesives, or the like. Alternatively, or in addition, one or more of the braces 410 may be affixed to respective crossmembers 406 and posts 408 via joining processes (e.g., welding, or the like).

It is noted that the crossmembers 406, the posts 408, and/or the braces 410 may be fabricated from the same or different stock metal material, without departing from the scope of the present disclosure. In addition, it is noted that the crossmembers 406, the posts 408, and/or the braces 410 may have the same or different cross-section, without departing from the scope of the present disclosure. Further, it is noted that the crossmembers 406, the posts 408, and/or the braces 410 may have the same or different dimensions in one or more of length, width, and thickness or depth, without departing from the scope of the present disclosure.

In embodiments, the fluid cooling module 400 may utilize a fluid (e.g., a coolant such as a water, a glycol, a water-glycol mixture, and the like, or more generally a liquid or a gas) in a supply pipe 412 and a return pipe 414. For example, the supply pipe 412 may provide fluid at a cooler temperature than the fluid received in the return pipe 414. Optionally, the return pipe 414 may be exterior to the pod 100, such that only a supply pipe 412 is provided within the pod 100. Alternatively, the supply pipe 412 may be exterior to the pod 100, such that only the return pipe 414 is provided within the pod 100.

In non-limiting examples illustrated in FIG. 4A, the fluid cooling module 400 includes a pipe set 416 including a supply pipe 412 and a return pipe 414 for each of the rows 102 of server racks 104. In addition, as illustrated in FIG. 4A, the fluid cooling module 400 includes a supply line 418 from the supply pipe 412 and a return line 420 to the return pipe 414 for each of the server racks 104 within a particular row 102.

In embodiments, FIGS. 4B-4E illustrate examples of the supply line 418 (labeled 418A, 418B) or the return line 420 (labeled 420A, 420B). For example, one or more of the supply lines 418A, 418B and/or the return lines 420A, 420B may include a manual valve 422 (e.g., a ball valve, gate valve, or other valve manually controllable by a technician). By way of another example, one or more of the supply lines 418A, 418B and/or the return lines 420A, 420B may Alternatively, or in addition include a solenoid valve 424 (e.g., solenoid-driven gate valves, solenoid-driven ball valves, or the like) that are electronically controlled either by a technician via a control system.

It is noted that the valve 422 may be a solenoid valve that is automatically controlled by the control system in response to acquired sensor data monitoring operational parameters within the HAC system 900. For example, one or more of the supply lines 418A, 418B and/or the return lines 420A, 420B may include sensors 426 (e.g., pressure transducers, temperature transducers, or the like) that provide data to a control system. By way of another example, one or more of the supply lines 418A, 418B and/or the return lines 420A, 420B may include a flow meter 428 that provides data to a control system.

It should be understood that the configurations of the supply lines 418 and/or return lines 420 in FIGS. 4B-4E are not intended to be limiting for the present disclosure. For example, multiple server racks 104 may share lines 418, 420, as illustrated in FIG. 4F, such that the supply lines 418 may be split at a line joint 430 prior to the multiple server racks 104 and/or the return lines 420 may join together at the line joint 430 after the multiple server racks 104. By way of another example, although not shown, it is contemplated that there may be multiple supply lines 418 and return lines 420 for multiple pipe sets 416 of supply pipes 412 and return pipes 414 for each of the rows 102 of server racks 104, such as where meeting code requires the installation of multiple supply pipes 412 and return pipes 414 to each row 102 of server racks 104.

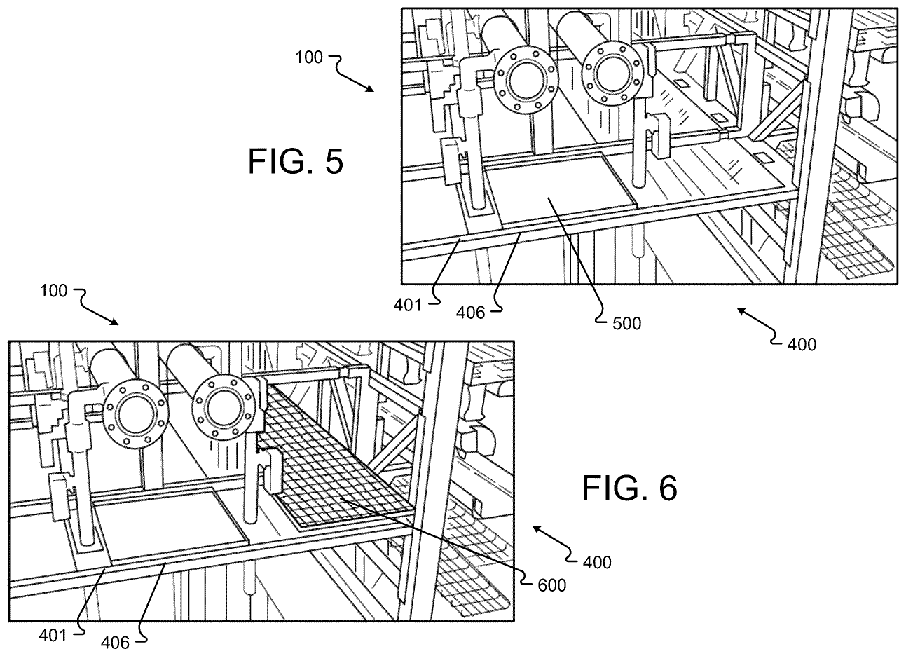

In embodiments, the fluid cooling module 400 optionally includes affixed or removable ceiling panels 500, as illustrated in FIG. 5. For example, the ceiling panels 500 may be installable on the frame 401 including, but not limited to, crossmember 406 of the frame 401. The ceiling panels 500 may be coupled to the frame 401 via coupler elements including, but not limited to, interlocking assemblies, fasteners, adhesives, or the like. Alternatively, or in addition, the ceiling panels 500 may be affixed to the frame 401 via joining processes (e.g., welding, or the like).

The ceiling panels 500 when installed on the pod 100, along with the panel module 800 and door modules 1300 as described further herein, may at least partially enclose the aisle 106 defined between the rows 102 of server racks 104. In some configurations, complete or nearly complete enclosure may be beneficial to be able to regulate the volume of the aisle 106 using air-cooling technologies (e.g., close room air conditioners, or the like) in addition to fluid cooling provided to the server racks 104, creating a hybrid cooling arrangement where fluid cooling and/or air cooling may be employed within the pod 100 (and the HAC system 900) as desired.

In general, the ceiling panels 500 may be dimensioned with any length, width, or thickness to be installable on the pod 100 (e.g., on the frame 401 of the fluid cooling module 400), including optionally abutting adjacent respective ceiling panels 500 or having a space between adjacent respective ceiling panels 500, while still being able to provide technician weight support, without departing from the scope of the present disclosure.

In embodiments, the fluid cooling module optionally includes affixed or removable catwalk panels 600 able to support a technician, as illustrated in FIG. 6. For example, the catwalk panels 600 may be installable on the frame 401 including, but not limited to, crossmember 406 of the frame 401. The catwalk panels 600 may be coupled to the frame 401 via coupler elements including, but not limited to, interlocking assemblies, fasteners, adhesives, or the like. Alternatively, or in addition, the catwalk panels 600 may be affixed to the frame 401 via joining processes (e.g., welding, or the like).

The catwalk panels 600 may provide access to elements of the fluid cooling system 400 including, but not limited to, the valves 422 (and, more generally, the pod 100 and/or the HAC system 900). For example, where the valves 422 need to be monitored and/or manually actuated, a technician may use the catwalk panels 500 to reach the valves 422 along the length of the pod 100 (and the HAC system 900).

In general, the catwalk panels 600 may be dimensioned with any length, width, or thickness to be installable on the pod 100 (e.g., on the frame 401 of the fluid cooling module 400), including optionally abutting adjacent respective catwalk panels 600 or having a space between adjacent respective catwalk panels 600, while still being able to provide technician weight support, without departing from the scope of the present disclosure.

Although embodiments are directed to the inclusion of the fluid module 400 in the pod 100, it should be understood that the pod 100 may not include the fluid module 400. For example, the pod 100 and the HAC system 900 may be configured to provide air-cooling only to the aisle 106 between the rows 102 of server racks 104, without departing from the scope of the present disclosure.

Although embodiments are directed to the ceiling panels 500 and/or the catwalk panels 600 being installed on the fluid cooling module 400, it is noted that the ceiling panels 500 may be installed on the pod 100 separately from the fluid cooling module 400, without departing from the scope of the present disclosure. For example, the ceiling panels 500 and/or the catwalk panels 600 may be installed on one or more of the frame module 200, including optionally as components of the power module 300, the tray module 700, and/or the panel module 800, without departing from the scope of the present disclosure.

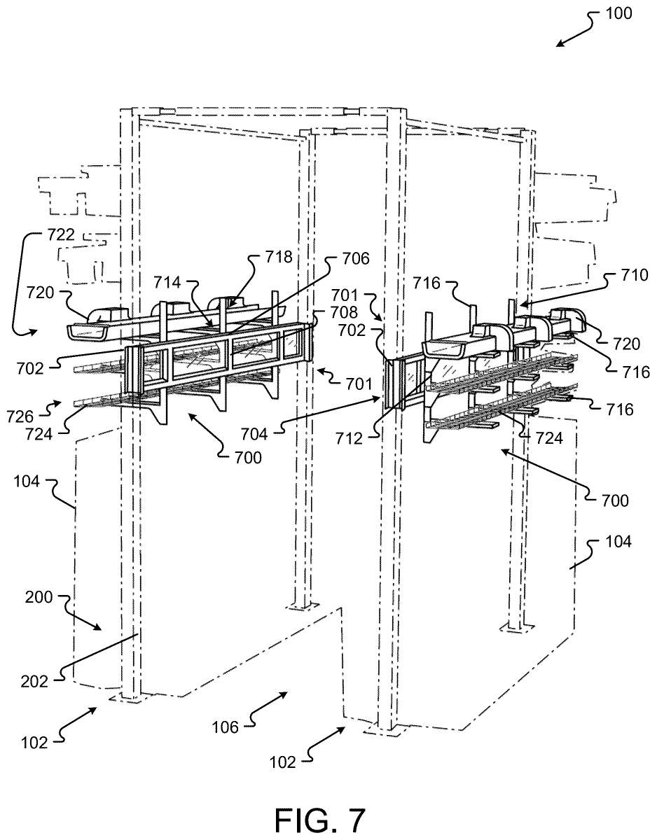

In embodiments, FIG. 7 is a perspective view of a tray module 700 of the pod 100. In embodiments, the tray module 700 may be installable on, and positionable at one or more locations on, the frame module 200. For instance, where there are two rows 102 of server racks 104, the pod 100 includes two tray modules 700. However, it should be understood that this arrangement is not intended to be limiting on the present disclosure.

In embodiments, the tray module 700 may be installable on a pair of adjacent posts 202 of the frame module 200 via a frame 701 including respective sleeves 702 for each of the posts 202. The sleeves 702 may be coupled to respective posts 202 via coupler elements 704 including, but not limited to, interlocking assemblies, fasteners, adhesives, or the like. For instance, where coupler elements 704 are used to attach the sleeves 702 to the posts 202, the tray module 700 may be height-adjustable on the frame module 200. Alternatively, or in addition, the sleeves 702 may be affixed to respective posts 202 via joining processes (e.g., welding, or the like).

In embodiments, the frame 701 includes one or more bracket mounts 706 that attach to and span a space between the sleeves 702. The one or more bracket mounts 706 may be coupled to the sleeves 702 via coupler elements including, but not limited to, interlocking assemblies, fasteners, adhesives, or the like. Alternatively, or in addition, one or more of the bracket mounts 706 may be affixed to respective sleeves 702 via joining processes (e.g., welding, or the like).

In embodiments, including where there are multiple bracket mounts 706, the frame 701 includes one or more brackets 708 that attach to and span a space between the bracket mounts 706. The one or more brackets 708 may be coupled to the bracket mounts 706 via coupler elements including, but not limited to, interlocking assemblies, fasteners, adhesives, or the like. Alternatively, or in addition, one or more of the brackets 708 may be affixed to respective bracket mounts 706 via joining processes (e.g., welding, or the like).

In embodiments, a hanger arm assembly 710 is attached to the frame 701. The hanger arm assembly 710 includes one or more bars 712. For example, the one or more bars 712 attach to the brackets 708 of the frame 701. The one or more bars 712 may be coupled to the frame 701 via coupler elements 714 including, but not limited to, interlocking assemblies, fasteners, adhesives, or the like. For instance, where coupler elements 714 are used to attach the bars 712 to the frame 701, the hanger arm assembly 710 may be height-adjustable relative to the frame module 200. Alternatively, or in addition, one or more of the bars 712 may be affixed to the frame 701 via joining processes (e.g., welding, or the like).

In embodiments, the hanger arm assembly 710 includes a plurality of arms 716. For example, one or more arms 716 are coupled to a respective bar 712. The one or more arms 716 may be coupled to the bar 712 via coupler elements 718 including, but not limited to, interlocking assemblies, fasteners, adhesives, or the like. For instance, where coupler elements 718 are used to attach the arms 716 to the bars 712, the arms 716 may be height-adjustable relative to the frame module 200. Alternatively, or in addition, one or more of the arms 716 may be affixed to the bars 712 via joining processes (e.g., welding, or the like).

In embodiments, one or more cable trays 720 or other storage elements are attached to the arms 716. For example, the one or more cable trays 720 may be open, may be closed with an actuatable lid or cover, or may be at least temporarily sealed from being able to open. The one or more cable trays 720 may be coupled to the arms 716 via coupler elements including, but not limited to, interlocking assemblies, fasteners, adhesives, or the like. Alternatively, or in addition, one or more of the cable trays 720 may be affixed to the arms 716 via joining processes (e.g., welding, or the like.

Via the cable trays 720, the tray module 700 may route networking or data cables, or other wiring that supplies or returns data from the rows 102 of server racks 104. In some configurations, a cable tray 720 defines a channel with openings at opposite ends and/or openings at one or more locations along the length of the cable tray 720 to route cables for networking or data to the rows 102 of server racks 104. It is noted that the cable trays 720 may optionally include redundant networking or data cables, as may be required by code, without departing from the scope of the present disclosure.

In some configurations, the cable trays 720 are plastic trays. Generally, however, the cable trays 720 may be fabricated from a sufficiently rigid metal or plastic (e.g., with an optional plastic or rubber coating), where a base of the cable trays 720 is solid or includes openings, and where the cable trays 720 support objects placed on the cable trays 720 to a pre-determined weight rating, for purposes of the present disclosure.

It is noted that each tray module 700 may include one or more rows 722 of cable trays 720. To accommodate the multiple rows 722, the hanger arm assembly 710 may include a number of arms 716 corresponding to each of the number of rows 722. For example, each bar 712 may have a number of arms 716 corresponding to each of the number of rows 722 attached. However, it is contemplated other numbers of arms 716 are usable to support the cable trays 720 per row 722 and/or per bar 712, without departing from the scope of the present disclosure.

Although embodiments of the present disclosure are directed to the power conduits 320 of FIG. 3 for power cable management and cable trays 720 for networking or data cable management, it should be understood that this is not limiting on the present disclosure. For example, the power conduits 320 may be conduits for routing networking or data cables, and/or the cable trays 720 may be conduits for routing power cables, without departing from the scope of the present disclosure.

In embodiments, one or more shelves 724 are attached to the arms 716. For example, the one or more shelves 724 may be installed as separate sections that are spaced or abut together, may be separately fabricated and installed in pre-assembled lengths, or may be fabricated and installed as a single continuous length. The one or more shelves 724 may be coupled to the arms 716 via coupler elements including, but not limited to, interlocking assemblies, fasteners, adhesives, or the like. Alternatively, or in addition, one or more of the shelves 724 may be affixed to the arms 716 via joining processes (e.g., welding, or the like.

In some configurations, the shelves 724 are wire-rack shelving units. Generally, however, the shelves 724 may be fabricated from a sufficiently rigid metal or plastic (e.g., with an optional plastic or rubber coating), where a base of the shelves 724 is solid or includes openings, and where the shelves 724 support objects placed on the shelves 724 to a pre-determined weight rating, for purposes of the present disclosure.

It is noted that each tray module 700 may include one or more rows 726 of shelves 724. To accommodate the multiple rows 726, the hanger arm assembly 710 may include a number of arms 716 corresponding to each of the number of rows 726. For example, each bar 712 may have a number of arms 716 corresponding to each of the number of rows 726 attached. However, it is contemplated other numbers of arms 716 are usable to support the shelves 724 per row 726 and/or per bar 712, without departing from the scope of the present disclosure.

In some configurations, the tray module 700 may include one or more rows 722 of cable trays 720 and/or one or more rows 726 of shelves 724, which are adjustable in terms of height and/or spacing on the frame module 700. For example, the tray module 700 is capable of supporting up a combination of up to five rows 722 of cable trays 720 and rows 726 of shelves 724, though this configuration should be understood as being non-limiting on the present disclosure. In addition, it is noted that, including where the arms 716 are adjustably coupled to the bars 712 via the coupler elements 714, the spacing between rows 722, 726 may be adjusted to add or remove rows 722, 726.

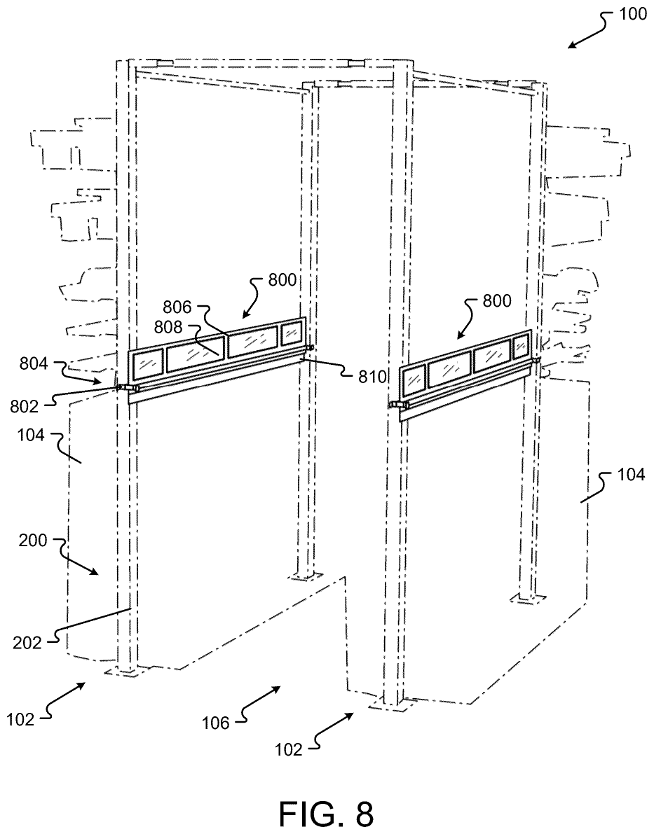

Referring now to FIG. 8, a perspective view of a panel module 800 of the pod 100 is illustrated. In embodiments, the panel module 800 may be installable on, and positionable at one or more locations on, the frame module 200. For example, the pod 100 may include one panel module 800 per row 102 of server racks 104. For instance, where there are two rows 102 of server racks 104, the pod 100 includes two panel modules 800. However, it should be understood that this arrangement is not intended to be limiting on the present disclosure.

In embodiments, the panel module 800 may be installable on a pair of adjacent posts 202 of the frame module 200 via a frame 801 including respective sleeves 802 for each of the posts 202. The sleeves 802 may be coupled to respective posts 202 via coupler elements 804 including, but not limited to, interlocking assemblies, fasteners, adhesives, or the like. For instance, where coupler elements 804 are used to attach the sleeves 802 to the posts 202, the panel module 800 may be height-adjustable on the frame module 200. Alternatively, or in addition, the sleeves 802 may be affixed to respective posts 202 via joining processes (e.g., welding, or the like).

In embodiments, the frame 801 includes one or more windows 806 that attach to and span a space between the sleeves 802. The one or more windows 806 may be coupled to the frame 801 via coupler elements including, but not limited to, interlocking assemblies, fasteners, adhesives, or the like. Alternatively, or in addition, one or more of the windows 806 may be affixed to the frame 801 via joining processes (e.g., welding, or the like).

In some configurations, the windows 806 may be installed as separate sections that are spaced or abut together, may be separately fabricated and installed in pre-assembled lengths, or may be fabricated and installed as a single continuous length. It is noted that abutting separate windows 806 or sections of windows 806 may serve to better enclose the aisle 106 between adjacent rows 102 of server racks 104, as compared to spaced windows 806.

In embodiments, the windows 806 may include a pane 808 fabricated from an opaque, translucent, or transparent material. For example, the material may be a plastic, a glass, or a metal. By way of another example, the material may be of a thickness to be flexible (e.g., similar to a vinyl panel or other lightweight fabric material) or may be of a thickness to be at least semi-rigid, without departing from the scope of the present disclosure. However, it is also contemplated that windows 806 may be fabricated from a single piece of material, such that the pane 808 may not be included, without departing from the scope of the present disclosure.

In embodiments, the frame 801 includes one or more dividers 810 that attach to and span a space between the sleeves 802. The one or more dividers 810 may be coupled to the frame 801 via coupler elements including, but not limited to, interlocking assemblies, fasteners, adhesives, or the like. Alternatively, or in addition, one or more of the dividers 810 may be affixed to the frame 801 via joining processes (e.g., welding, or the like).

In some configurations, the dividers 810 may be installed as separate sections that are spaced or abut together, may be separately fabricated and installed in pre-assembled lengths, or may be fabricated and installed as a single continuous length. It is noted that abutting separate dividers 810 or sections of dividers 810 may serve to better enclose the aisle 106 between adjacent rows 102 of server racks 104, as compared to spaced dividers 810.

In embodiments, the dividers 810 may be fabricated from an opaque, translucent, or transparent material. For example, the material may be a plastic, a glass, or a metal. By way of another example, the material may be of a thickness to be flexible (e.g., similar to a vinyl panel or other lightweight fabric material) or may be of a thickness to be at least semi-rigid, without departing from the scope of the present disclosure. However, it is also contemplated that dividers 810 may be fabricated with a separate or additional pane 808, without departing from the scope of the present disclosure.

In one non-limiting example, the windows 806 extend in a first direction from the frame 801 (e.g., toward a higher module), and the dividers 810 extend in a second direction from the frame 801 (e.g., toward the server racks 104). However, it is contemplated that dividers 810 may be used in place of windows, and/or that windows 806 may be used in place of dividers 810. As such, it should be understood that the windows 806 and the dividers 810 are interchangeable and/or optional, for purposes of the present disclosure.

It is noted that the panel module 800 may include one or more sets of windows 806 and/or dividers 810 to partially or fully-enclose the pod 100, including optionally along the length of the sides and/or the ceiling the pod 100, across the width of the ends of the pod 100, without departing from the scope of the present disclosure. For purposes of the present disclosure it should be understood that the panel module 800 may be installable to contain and/or direct a predetermined amount of hot air (e.g., that is exhausted from the server racks 104 into the aisle 106) within/through the pod 100 (and the HAC system 900, as a whole.

In embodiments, the panel module 800, along with the optional ceiling panels 500 (and door module 1300, as described further herein) may at least partially enclose the aisle 106 defined between the rows 102 of server racks 104 (and above, within the modules 300, 400, 700 of the pod 100/the HAC system 900). In some configurations, complete or nearly complete enclosure may be beneficial to be able to regulate the volume of the aisle 106 using air-cooling technologies (e.g., close room air conditioners, or the like) in addition to fluid cooling provided to the server racks 104, creating a hybrid cooling arrangement where fluid cooling and/or air cooling may be employed within the pod 100 (and the HAC system 900) as desired.

It is noted that the windows 806 and/or dividers 810 (and/or sections of windows 806 and/or sections of dividers 810) may have different heights and be interchangeable within the panel module 800, such that the panel module 800 is height-adaptable. For example, adjustment of components of a higher module (e.g., shelves 724 in the tray module 700) may increase or decrease a spacing between the higher module and the server racks 104. To maintain a desired level of enclosure of the aisle 106 between the adjacent rows 102 of server racks 104, windows 806 and/or dividers 810 of different heights may be interchanged into the panel module 800.

Where only a single pod 100 is necessary, the single pod 100 may be considered an HAC system 900, without departing from the scope of the present disclosure. However, as illustrated in FIGS. 9A-15, an HAC system 900 may include multiple pods 100.

FIGS. 9A-15 generally illustrate an HAC system 900, in accordance with one or more embodiments of the present disclosure. In particular, FIG. 9A is a perspective view of the HAC system 900 including multiple pods 100, 100B, 100C of FIGS. 1A-8. In addition, FIG. 9B is a perspective view of a particular pod 100A (e.g., an end pod 100) of the HAC system 900 of FIG. 9A. It should be understood that any embodiments directed to the pod 100 in FIGS. 1A-8 may be interchangeable with embodiments directed to the pod 100A, 100B, 100C in FIGS. 9A-15, and vice versa, without departing from the scope of the present disclosure.

It is noted that the HAC system 900 is not limited to pods 100A, 100B, 100C, but may include more or fewer pods 100 as is desirable and/or installable within a data center. As such, the inclusion of pods 100A, 100B, 100C in the HAC system 900 should not be interpreted as limiting on the present disclosure.

In embodiments, the HAC system 900 is located on a floor surface 902 to which anchor plates 204 of frame modules 200 of respective pods 100A, 100B, 100C couple. For example, the floor surface 902 may be a pre-existing floor surface and/or a raised floor located above a pre-existing floor surface.

In embodiments, the HAC system 900 is located proximate to a wall surface 904. For example, the wall surface 904 may be a pre-existing wall surface and/or a standoff wall located proximate to a pre-existing wall surface. Although not shown, it is noted that anchor plates 204 of frame modules 200 of respective pods 100A, 100B, 100C may couple to the wall surface 904.

Although not shown, it is noted that anchor plates 204 of frame modules 200 of respective pods 100A, 100B, 100C may couple to a ceiling surface, without departing from the scope of the present disclosure. For example, the ceiling surface may be a pre-existing ceiling surface and/or a suspended ceiling located below a pre-existing ceiling surface.

In embodiments, one or more of a power end module 1000, a fluid end module 1100, an end tray module 1200, a door module 1300, an end cover module 1400, an accessory module 1500 in a fixed or an adjustable position, as described in detail further herein. In general, the order or arrangement of the modules 1000, 1100, 1200, 1300, 1400, 1500 within a modular build for the HAC system 900 is to allow for efficient fabrication and assembly while reducing possible error during fabrication and assembly processes.

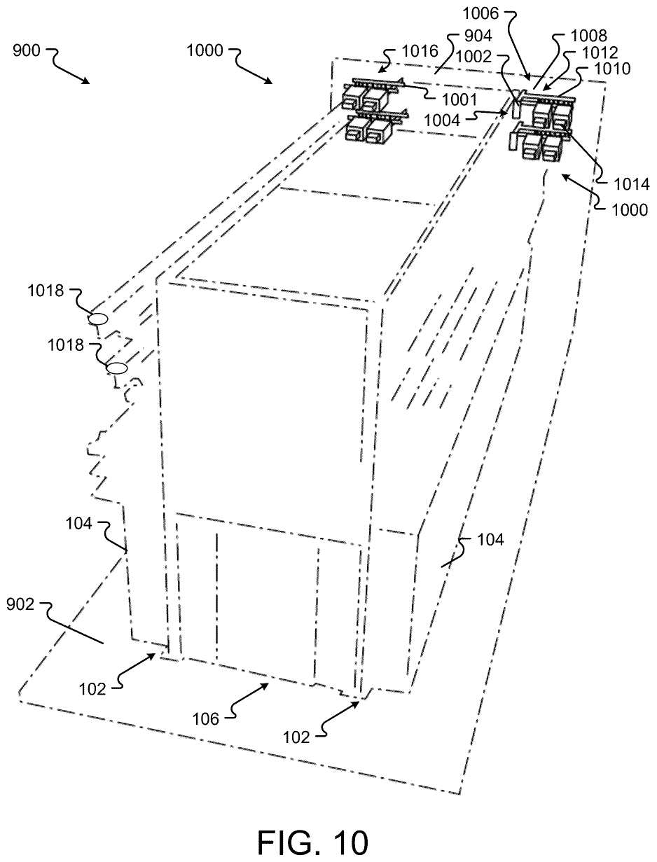

Reference will be made to the HAC system 900 including the pods 100A, 100B, 100C (including the modules of the pods 100A, 100B, 100C) and the modules 1000, 1100, 1200, 1300, 1400, 1500 in detail further herein. It is noted that any and/or all of the subassemblies of the HAC system 900 may include further subassemblies as described in detail further herein, which are each considered subassemblies of the HAC system 900. In addition, it is noted that one or more of the various modules and features of the HAC system 900 shown in FIGS. 9A and 9B are illustrated in FIG. 10-15, with select modules and features removed between the various FIGS. 10-106B for ease of review only.

Referring now to FIG. 10, a perspective view of a power end module 1000 of the HAC system 900 is illustrated. The power end module 1000 may be installed one or more of the pods 100A, 100B, 100C (e.g., as illustrated in FIG. 9A). Where the power end module is installed on the HAC system 900 in addition to the power module 300 of the various pods 100, the power end module 1000 may be the electrical source for the power modules 300 of the various pods 100, and/or may be a supplementary electrical source for the power modules 300 of the various pods 100.

In some configurations, the power end module 1000 may be installable on, and positionable at one or more locations on, a frame module 200 of a particular end pod 100 (e.g., pod 100A and/or 100C, as illustrated in FIG. 9A). Alternatively, a separate frame module 200 may be installed for the HAC system 900, to which the power end module 1000 may be coupled. In one non-limiting example, the HAC system 900 may include one power end module 1000 per row 102 of server racks 104. For instance, where there are two rows 102 of server racks 104, the HAC system 900 includes two power end modules 1000, whether entirely separated or joined together at one or more ends of the HAC system 900. However, it should be understood that this arrangement is not intended to be limiting on the present disclosure.

In embodiments, the power end module 1000 may be installable on at least one post 202 of the frame module 200 of a particular pod 100 via at least one bracket mount 1002 for the at least one post 202. The at least one bracket mount 1002 may be coupled to the at least one post 202 via coupler elements 1004 including, but not limited to, interlocking assemblies, fasteners, adhesives, or the like. For instance, where coupler elements 1004 are used to attach the at least one bracket mount 1002 to the at least one post 202, the power end module 1000 may be height-adjustable on the frame module 200. Alternatively, or in addition, the at least one bracket mount 1002 may be affixed to the at least one post 202 via joining processes (e.g., welding, or the like).

It is noted that the at least one bracket mount 1002 may make contact with one or more surfaces of the at least one post 202. For example, where the at least one bracket mount 1002 at least partially surrounds the at least one post 202, the at least one bracket mount 1002 may operate similar to a sleeve.

In embodiments, a hanger arm assembly 1006 is attached to the at least one bracket mount 1002. The hanger arm assembly 1006 includes one or more brackets 1008. The one or more brackets 1008 may be coupled to the at least one bracket mount 1002 via coupler elements including, but not limited to, interlocking assemblies, fasteners, adhesives, or the like. Alternatively, or in addition, one or more of the brackets 1008 may be affixed to the at least one bracket mount 1002 via joining processes (e.g., welding, or the like).

In embodiments, the hanger arm assembly 1006 includes a plurality of arms 1010. For example, one or more arms 1010 are coupled to the brackets 1008. The one or more arms 1010 may be coupled to the brackets 1008 via coupler elements 1012 including, but not limited to, interlocking assemblies, fasteners, adhesives, or the like. For instance, where coupler elements 1012 are used to attach the arms 1010 to the brackets 1008, the arms 1010 may be height-adjustable relative to the frame module 200. Alternatively, or in addition, one or more of the arms 1010 may be affixed to the brackets 1008 via joining processes (e.g., welding, or the like).

In embodiments, one or more power conduit joints 1014 are attached to the arms 1010. For example, the one or more power conduit joints 1014 are coupled to a plurality of arms 1010 in a row 1016. The one or more power conduit joints 1014 may be coupled to the arms 1010 via coupler elements including, but not limited to, interlocking assemblies, fasteners, adhesives, or the like. Alternatively, or in addition, one or more of the power conduit joints 1014 may be affixed to the arms 1010 via joining processes (e.g., welding, or the like.

Via the power conduit joints 1014, the power end module 1000 may route cables or other wiring that supplies or returns primary power to the power conduits 320 of a power module 300 of a particular pod 100 (e.g., the pod 100C, as illustrated in FIG. 9A). For example, the provided power may be AC and/or DC power, as needed by the HAC system 900 and/or the modules or components of the pod 100. It is noted that the power conduit joints 1014 may be proximate to a wall surface 904, such that the power conduit joints 1014 couple to corresponding conduits that extend from the wall surface 904 (or, alternatively, are insertable into the wall surface 904 to couple to wall-inset power conduit components), without departing from the scope of the present disclosure.

In some configurations, a power conduit joint 1014 defines an interior cavity, such that the power conduit joint 1014 is installed over the corresponding power conduit 320 when the power end module 1000 is mounted to the HAC system 900. In other configurations, a power conduit joint 1014 has an exterior surface that is insertable into a channel of the corresponding power conduit 320 when the power end module 1000 is mounted to the HAC system 900. It is noted that the power conduit joints 1014 may optionally supply secondary or redundant power, as may be required by code, without departing from the scope of the present disclosure.

It is noted that each power end module 1000 may include one or more rows 1016 of power conduit joints 1014. To accommodate the multiple rows 1016, the hanger arm assembly 1006 may include a number of arms 1010 corresponding to each of the number of rows 1016. For example, each bracket 1008 may have a number of arms 1010 corresponding to each of the number of rows 1016 attached. However, it is contemplated other numbers of arms 1010 are usable to support the power conduit joints 1014 per row 1016 and/or per bracket 1008, without departing from the scope of the present disclosure.

In embodiments, the power end module 1000 includes one or more end stops 1018. In some configurations, an end stop 1018 has an exterior surface that is insertable into a channel of the corresponding power conduit 320 (e.g., of the pod 100A, as illustrated in FIG. 9A) when the power end module 1000 is mounted to the HAC system 900. In other configurations, an end stop 1018 defines an interior cavity, such that the end stop 1018 is installed over the corresponding power conduit 320 when the power end module 1000 is mounted to the HAC system 900. It is noted that where there are multiple end stops 1018, that the end stops 1018 may be coded (e.g., with colors, labels, patterns, or the like) to indicate to which power conduit 320 the end stop 1018 is attached.

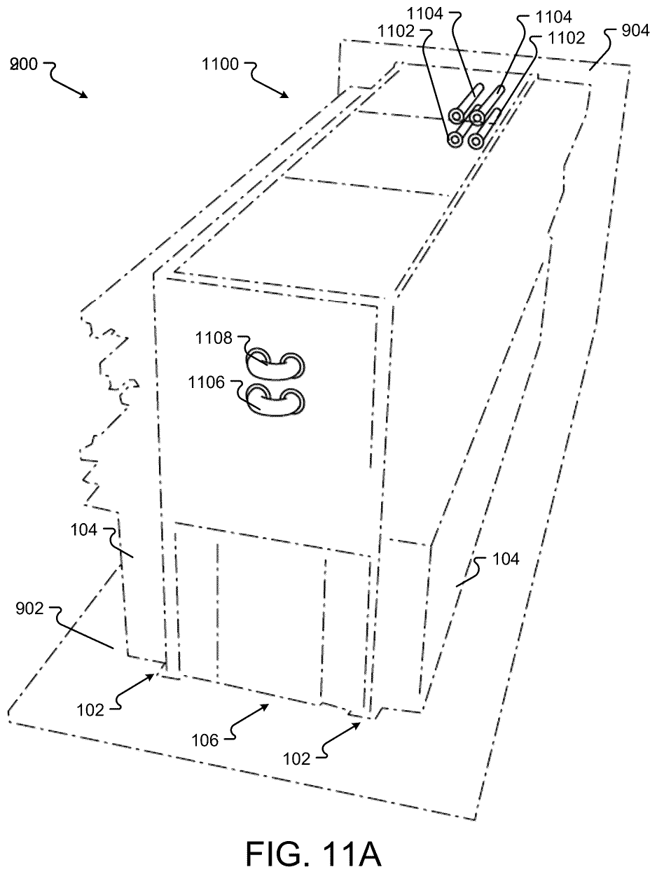

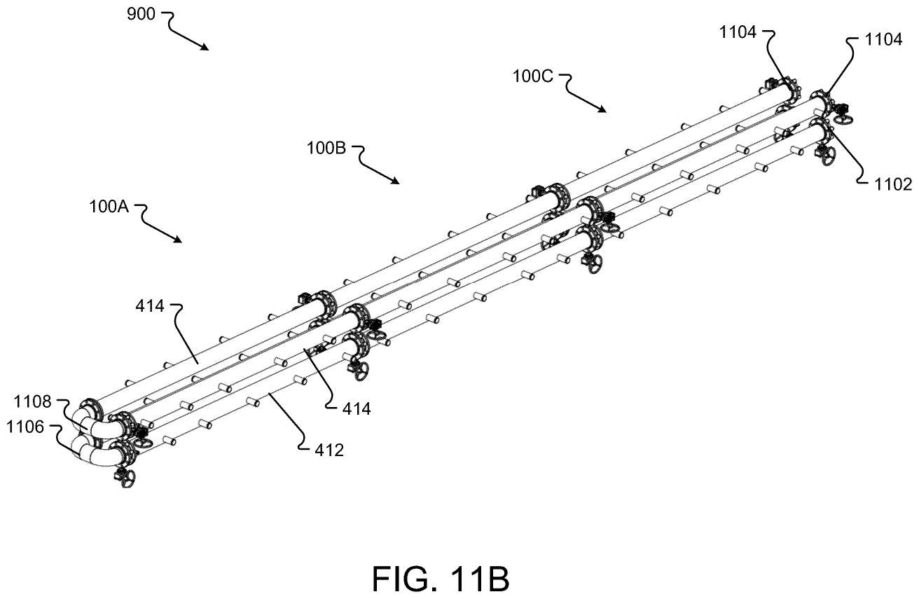

Referring now to FIGS. 11A and 11B, a perspective view of a fluid end module 1100 of the HAC system 900 is illustrated. In embodiments, the fluid end module 1100 may be installable on, and positionable at one or more locations on, the HAC system 900. For example, the HAC system 900 may include one fluid end module 1100 that supplies adjacent rows 102 of server racks 104. For instance, where there are two rows 102 of server racks 104, the HAC system 900 includes one fluid end module 1100. However, it should be understood that this arrangement is not intended to be limiting on the present disclosure.

In embodiments, the fluid end module 1100 includes supply ports 1102 for the supply pipes 412, and return ports 1104 for the return pipes 414 (e.g., as illustrated in FIG. 4A). Via the ports 1102, 1104, the fluid end module 1100 may provide a fluid (e.g., a coolant such as a water, a glycol, a water-glycol mixture, and the like, or more generally a liquid or a gas) to the supply pipe 412 and receive the fluid from the return pipe 414 to the HAC system 900. It is noted that the ports 1102, 1104 may be proximate to a wall surface 904, such that the ports 1102, 1104 couple to corresponding fluidic elements that extend from the wall surface 904 (or, alternatively, are insertable into the wall surface 904 to couple to wall-inset fluidic elements), without departing from the scope of the present disclosure.

In some configurations, the ports 1102, 1104 and the corresponding pipes 412, 414 each have flanges that are coupled together with surface-mounted interfaces. In other configurations, ports 1102, 1104 defines an interior cavity, such that the ports 1102, 1104 are installed over the corresponding pipes 412, 414 when the fluid end module 1100 is mounted to the HAC system 900. In other configurations, ports 1102, 1104 each have an exterior surface that is insertable into a respective channel of the corresponding pipes 412, 414 when the fluid end module 1100 is mounted to the HAC system 900. It is noted that the ports 1102, 1104 may optionally supply secondary or redundant fluid, as may be required by code, without departing from the scope of the present disclosure.

In embodiments, the fluid end module includes pipe joints 1106, 1108. For example, the supply pipe joint 1106 couples sections of the fluid supply pipe 412 together within the fluid module 400, and the return pipe joint 1108 couple sections of the fluid return pipe 414 together within the fluid module 400 (e.g., as illustrated in FIG. 4A). In general, the fluidic components 1102, 1104, 1106, 1108 of the fluid end module 1100 assist in fluid flow through the fluid module 400, including directing supply fluid and/or return fluid within (or exterior to) the HAC system 900. However, it is contemplated that the fluid end module 1100 may not include the pipe joints 1106, 1108, including where the fluid passes through the fluid module 1100 in a single direction for supply and/or return.

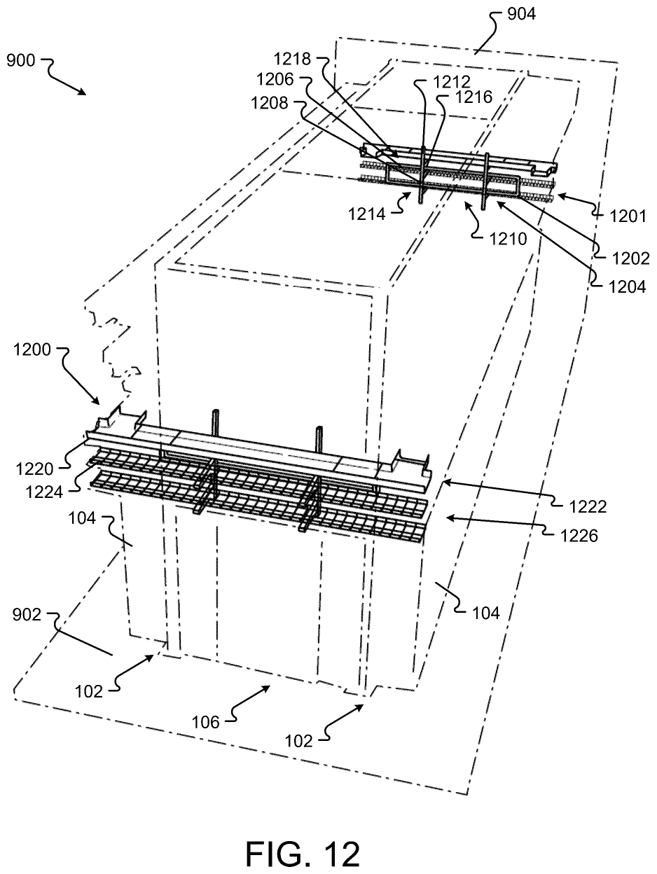

Referring now to FIG. 12, a perspective view of an end tray module 1200 of the HAC system 900 is illustrated. In embodiments, the end tray module 1200 may be installable on, and positionable at one or more locations on, a frame module of a particular end pod 100. Alternatively, a separate frame module 200 may be installed for the HAC system 900, to which the end tray module 1200 may be coupled. In one non-limiting example, the HAC system 900 may include at least one end tray module 1200 per row 102 of server racks 104. For instance, where there are two rows 102 of server racks 104 that define an aisle 106, the HAC system 900 includes at least one (and optionally two) end tray modules 1200 that connect the respective tray modules 700 of the one or more pods 100 (e.g., as illustrated in FIG. 9A). However, it should be understood that this arrangement is not intended to be limiting on the present disclosure.

In embodiments, the end tray module 1200 may be installable on a pair of adjacent posts 202 of the frame module 200 (e.g., the pods 100A, 100C, as illustrated in FIG. 9A) via a frame 1201 including respective sleeves 1202 for each of the posts 202. The sleeves 1202 may be coupled to respective posts 202 via coupler elements 1204 including, but not limited to, interlocking assemblies, fasteners, adhesives, or the like. For instance, where coupler elements 1204 are used to attach the sleeves 1202 to the posts 202, the end tray module 1200 may be height-adjustable on the frame module 200. Alternatively, or in addition, the sleeves 1202 may be affixed to respective posts 202 via joining processes (e.g., welding, or the like).

In embodiments, the frame 1201 includes one or more bracket mounts 1206 that attach to and span a space between the sleeves 1202. The one or more bracket mounts 1206 may be coupled to the sleeves 1202 via coupler elements including, but not limited to, interlocking assemblies, fasteners, adhesives, or the like. Alternatively, or in addition, one or more of the bracket mounts 1206 may be affixed to respective sleeves 1202 via joining processes (e.g., welding, or the like).

In embodiments, including where there are multiple bracket mounts 1206, the frame 1201 includes one or more brackets 1208 that attach to and span a space between the bracket mounts 1206. The one or more brackets 1208 may be coupled to the bracket mounts 1206 via coupler elements including, but not limited to, interlocking assemblies, fasteners, adhesives, or the like. Alternatively, or in addition, one or more of the brackets 1208 may be affixed to respective bracket mounts 706 via joining processes (e.g., welding, or the like).

In embodiments, a hanger arm assembly 1210 is attached to the frame 1201. The hanger arm assembly 1210 includes one or more bars 1212. For example, the one or more bars 1212 attach to the brackets 1208 of the frame 1201. The one or more bars 1212 may be coupled to the frame 1201 via coupler elements 1214 including, but not limited to, interlocking assemblies, fasteners, adhesives, or the like. For instance, where coupler elements 1214 are used to attach the bars 1212 to the frame 1201, the hanger arm assembly 1210 may be height-adjustable relative to the frame module 200. Alternatively, or in addition, one or more of the bars 1212 may be affixed to the frame 1201 via joining processes (e.g., welding, or the like).

In embodiments, the hanger arm assembly 1210 includes a plurality of arms 1216. For example, one or more arms 1216 are coupled to a respective bar 1212. The one or more arms 1216 may be coupled to the bar 1212 via coupler elements 1218 including, but not limited to, interlocking assemblies, fasteners, adhesives, or the like. For instance, where coupler elements 1218 are used to attach the arms 1216 to the bars 1212, the arms 1216 may be height-adjustable relative to the frame module 200. Alternatively, or in addition, one or more of the arms 1216 may be affixed to the bars 1212 via joining processes (e.g., welding, or the like).

In embodiments, one or more cable trays 1220 or other storage elements are attached to the arms 1216. For example, the one or more cable trays 1220 may be open, may be closed with an actuatable lid or cover, or may be at least temporarily sealed from being able to open. The one or more cable trays 1220 may be coupled to the arms 1216 via coupler elements including, but not limited to, interlocking assemblies, fasteners, adhesives, or the like. Alternatively, or in addition, one or more of the cable trays 1220 may be affixed to the arms 1216 via joining processes (e.g., welding, or the like).

Via the cable trays 1220, the end tray module 1200 may route networking or data cables, or other wiring that supplies or returns data from the rows 102 of server racks 104. In some configurations, a cable tray 1220 defines a channel with openings at opposite ends and/or openings at one or more locations along the length of the cable tray 1220 to route cables for networking or data to the rows 102 of server racks 104. It is noted that the cable trays 1220 may optionally include redundant networking or data cables, as may be required by code, without departing from the scope of the present disclosure.

In some configurations, the cable trays 1220 are plastic trays. Generally, however, the cable trays 1220 may be fabricated from a sufficiently rigid metal or plastic (e.g., with an optional plastic or rubber coating), where a base of the cable trays 1220 is solid or includes openings, and where the cable trays 1220 support objects placed on the cable trays 1220 to a pre-determined weight rating, for purposes of the present disclosure.

It is noted that each end tray module 1200 may include one or more rows 1222 of cable trays 1220. To accommodate the multiple rows 1222, the hanger arm assembly 1210 may include a number of arms 1216 corresponding to each of the number of rows 1222. For example, each bar 1212 may have a number of arms 1216 corresponding to each of the number of rows 1222 attached. However, it is contemplated other numbers of arms 1216 are usable to support the cable trays 1220 per row 1222 and/or per bar 1212, without departing from the scope of the present disclosure.

In embodiments, one or more shelves 1224 are attached to the arms 1216. For example, the one or more shelves 1224 may be installed as separate sections that are spaced or abut together, may be separately fabricated and installed in pre-assembled lengths, or may be fabricated and installed as a single continuous length. The one or more shelves 1224 may be coupled to the arms 1216 via coupler elements including, but not limited to, interlocking assemblies, fasteners, adhesives, or the like. Alternatively, or in addition, one or more of the shelves 1224 may be affixed to the arms 1216 via joining processes (e.g., welding, or the like.

In some configurations, the shelves 1224 are wire-rack shelving units. Generally, however, the shelves 1224 may be fabricated from a sufficiently rigid metal or plastic (e.g., with an optional plastic or rubber coating), where a base of the shelves 1224 is solid or includes openings, and where the shelves 1224 support objects placed on the shelves 1224 to a pre-determined weight rating, for purposes of the present disclosure.

It is noted that each end tray module 1200 may include one or more rows 1226 of shelves 1224. To accommodate the multiple rows 1226, the hanger arm assembly 1210 may include a number of arms 1216 corresponding to each of the number of rows 1226. For example, each bar 1212 may have a number of arms 1216 corresponding to each of the number of rows 1226 attached. However, it is contemplated other numbers of arms 1216 are usable to support the shelves 1224 per row 1226 and/or per bar 1212, without departing from the scope of the present disclosure.

In some configurations, the end tray module 1200 may include one or more rows 1222 of cable trays 1220 and/or one or more rows 1226 of shelves 1224, which are adjustable in terms of height and/or spacing on the frame module 1200. For example, the end tray module 1200 is capable of supporting up a combination of up to five rows 1222 of cable trays 1220 and rows 1226 of shelves 1224, though this configuration should be understood as being non-limiting on the present disclosure. In addition, it is noted that, including where the arms 1216 are adjustably coupled to the bars 1212 via the coupler elements 1214, the spacing between rows 1222, 1226 may be adjusted to add or remove rows 1222, 1226.

Although embodiments of the present disclosure are directed to the power conduit joints 1014 of FIG. 10 for power cable management and cable trays 1220 for networking or data cable management, it should be understood that this is not limiting on the present disclosure. For example, the power conduit joints 1014 may be conduits for routing networking or data cables, and/or the cable trays 1220 may be conduits for routing power cables, without departing from the scope of the present disclosure.

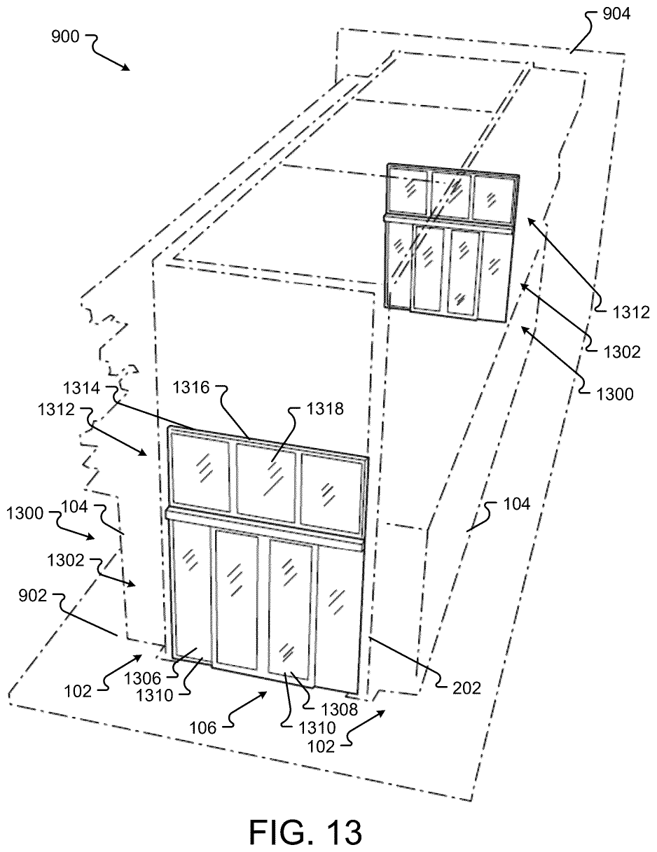

Referring now to FIG. 13, a perspective view of a door module 1300 of the HAC system 900 is illustrated. In embodiments, the door module 1300 may be installable on, and positionable at one or more locations on, the HAC system 900. For example, the HAC system 900 may include at least one door module 1300. For instance, where there are two rows 102 of server racks 104 that define an aisle 106 therebetween, the HAC system 900 includes at least one (and optionally two) door modules 1300 located at a respective end of the aisle 106. However, it should be understood that this arrangement is not intended to be limiting on the present disclosure.

In embodiments, the door module 1300, along with the panel module 800 and optional ceiling panels 500 as described previously herein, may at least partially enclose the aisle 106 defined between the rows 102 of server racks 104 (and above, within the modules of the pods 100/the HAC system 900 including the pods 100). In some configurations, complete or nearly complete enclosure may be beneficial to be able to regulate the volume of the aisle 106 using air-cooling technologies (e.g., close room air conditioners, or the like) in addition to fluid cooling provided to the server racks 104, creating a hybrid cooling arrangement where fluid cooling and/or air cooling may be employed within the pod 100 (and the HAC system 900) as desired.

In embodiments, the door module 1300 includes a door assembly 1302 that is installable on a pair of adjacent posts 202 of the frame module 200. For example, the door assembly 1302 may include a frame 1304 that is coupled to the adjacent posts 202 of a particular pod 100 (e.g. pods 100A, 100C) via coupler elements including, but not limited to, interlocking assemblies, fasteners, adhesives, or the like. Alternatively, or in addition, the frame 1304 may be affixed to adjacent posts 202 via joining processes (e.g., welding, or the like).

In some configurations, the door assembly 1302 includes a fixed portion 1306 within the frame 1304, and one or more doors 1308 installed within the frame 1304 that actuate relative to the fixed portion 1306. For example, the doors 1308 may slide relative to the fixed portion 1306 between an open position and a closed position. By way of another example, the doors 1308 may pivot about an axis through hinges relative to the fixed portion 1306 between an open position and a closed position. In general, it should be understood that doors 1308 may actuate relative to the frame 1304 in any of a swinging, a sliding, a pivoting, or other movement for opening and closing to allow or deny access to the aisle 106 between the adjacent rows 102 of server racks 104.

In some configurations, the fixed portion 1306 and the one or more doors 1308 may be installed as separate sections that are spaced or abut together, may be separately fabricated and installed in pre-assembled lengths, or may be fabricated and installed as a single continuous length. It is noted that abutting the fixed portion 1306 and the one or more doors 1308, or more generally including seals between the frame 1304 and the posts 202 and/or the fixed portion 1306 and the one or more doors 1308, may serve to better enclose the aisle 106 between adjacent rows 102 of server racks 104, as compared to components within the door assembly 1302 being spaced apart. It is noted that the one or more doors 1308 may fully fill the frame 1304 between the posts 202, such that the fixed portion 1306 may not be included within the door assembly 1302, without departing from the scope of the present disclosure.

In embodiments, the doors 1308 and/or the optional fixed portion 1306 of the frame 1304 may include a pane 1310 fabricated from an opaque, translucent, or transparent material. For example, the material may be a plastic, a glass, or a metal. By way of another example, the material may be of a thickness to be flexible (e.g., similar to a vinyl panel or other lightweight fabric material) or may be of a thickness to be at least semi-rigid, without departing from the scope of the present disclosure. However, it is also contemplated that the door 1308 and/or the optional fixed portion 1306 of the frame 1304 may be fabricated from a single piece of material, such that the panes 1310 may not be included within the door assembly 1302, without departing from the scope of the present disclosure.

In embodiments, the door module 1300 includes a divider assembly 1312 that is installable on a pair of adjacent posts 202 of the frame module 200. For example, the divider assembly 1312 may include a frame 1314 that is coupled to the frame 1304 of the door assembly 1302 and/or to the adjacent posts 202 of a particular pod 100 (e.g. pods 100A, 100C) via coupler elements including, but not limited to, interlocking assemblies, fasteners, adhesives, or the like. Alternatively, or in addition, the frame 1304 may be affixed to the frame 1304 of the door assembly 1302 and/or to adjacent posts 202 via joining processes (e.g., welding, or the like).

In embodiments, the frame 1314 includes one or more windows 1316 that attach to and span a space between the posts 202. The one or more windows 1316 may be coupled to the frame 1314 via coupler elements including, but not limited to, interlocking assemblies, fasteners, adhesives, or the like. Alternatively, or in addition, one or more of the windows 1316 may be affixed to the frame 1314 via joining processes (e.g., welding, or the like).

In some configurations, the windows 1316 may be installed as separate sections that are spaced or abut together, may be separately fabricated and installed in pre-assembled lengths, or may be fabricated and installed as a single continuous length. It is noted that abutting separate windows or sections of windows may serve to better enclose the aisle 106 between adjacent rows 102 of server racks 104, as compared to spaced windows 1316.

In embodiments, the windows 1316 may include a pane 1318 fabricated from an opaque, translucent, or transparent material. For example, the material may be a plastic, a glass, or a metal. By way of another example, the material may be of a thickness to be flexible (e.g., similar to a vinyl panel or other lightweight fabric material) or may be of a thickness to be at least semi-rigid, without departing from the scope of the present disclosure. However, it is also contemplated that windows 1316 may be fabricated from a single piece of material, such that the pane 1318 may not be included, without departing from the scope of the present disclosure.

In embodiments, the door module 1300, along with the optional ceiling panels 500 and the panel modules 800, may at least partially enclose the aisle 106 defined between the rows 102 of server racks 104 (and above, within the modules 300, 400, 700 of the pod 100/the HAC system 900). In some configurations, complete or nearly complete enclosure may be beneficial to be able to regulate the volume of the aisle 106 using air-cooling technologies (e.g., close room air conditioners, or the like) in addition to fluid cooling provided to the server racks 104, creating a hybrid cooling arrangement where fluid cooling and/or air cooling may be employed within the pod 100 (and the HAC system 900) as desired.

It is noted that the door assembly 1302 and/or the divider assembly 1312 (and/or sections of the door assembly 1302 and/or the divider assembly 1312) may have different heights and be interchangeable within the door module 1300, such that the door module 1300 is height-adaptable. For example, adjustment of components of a higher module (e.g., shelves 724 in the tray module 700 and/or shelves 1224 in the end tray module 1200) may increase or decrease a spacing between the higher module and the server racks 104. To maintain a desired level of enclosure of the aisle 106 between the adjacent rows 102 of server racks 104, a door assembly 1302 and/or a divider assembly 1312 of different heights may be interchanged into the panel module 800.

It is contemplated that, in embodiments, the HAC system 900 may include access hatches for access to the aisle 106 between rows 102 of server racks 104. Optionally, the doors 1308 and/or access hatches may have components that promote automatic closure, to improve efficiency of the HAC system 900. It is noted that these components may additionally be used on a single pod 100, including in non-limiting examples where the single pod 100 is a standalone or singular HAC system 900.

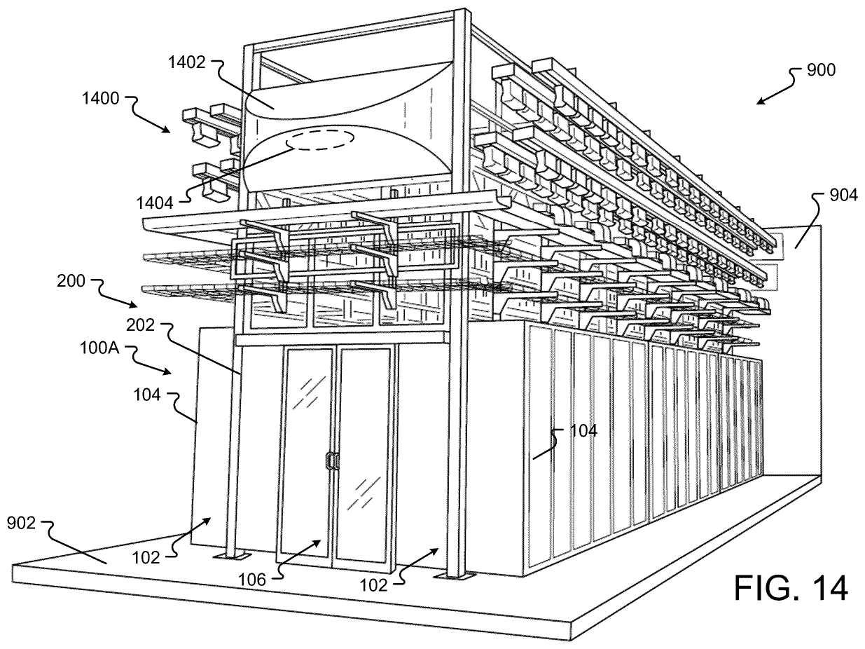

Referring now to FIG. 14, a perspective view of an end cover module 1400 of the HAC system 900 is illustrated. In embodiments, the end cover module 1400 includes a cover 1402. For example, the cover 1402 may couple directly to the adjacent posts 202 of a particular pod 100 (e.g. pod 100A) via coupler elements including, but not limited to, interlocking assemblies, fasteners, adhesives, or the like. Alternatively, or in addition, the cover 1402 may be affixed directly to adjacent posts 202 via joining processes (e.g., welding, or the like).

However, it is noted that the cover 1402 may instead be installed on a frame using the example techniques above for attaching the cover 1402 to the posts 202, and the frame is instead attached to the adjacent posts 202. For example, the frame may be coupled to the adjacent posts 202 of a particular pod 100 (e.g. pod 100A) via coupler elements including, but not limited to, interlocking assemblies, fasteners, adhesives, or the like. Alternatively, or in addition, the frame may be affixed to adjacent posts 202 via joining processes (e.g., welding, or the like).

In embodiments, the end cover module 1400 may protect module components, including optionally further assisting in the insulating or directing of heat from the rows 102 of server racks 104 and/or defined aisle 106 therebetween. For example, the cover 1402 may be a vinyl panel or other lightweight fabric material, where the vinyl has desired heat insulation properties.

It is noted that the end cover module 1400 may provide an increased aesthetic appearance to the HAC system 900, including with the covering of module components within the pods 100 and/or coupled to the pods 100 as part of the HAC system 900. For example, using the end cover module 1400 may de-emphasize the appearance of fluid pipes within the fluid module 400 and fluid end module 1100. In some configurations, indicia 1404 including, but not limited to, aisle number and/or visual branding may be included on the cover 1402, including optionally for increased aesthetic appearance.

It is noted that the end cover modules 1400 may be used on a single pod 100, including in non-limiting examples where the single pod 100 is a standalone or singular HAC system 900.

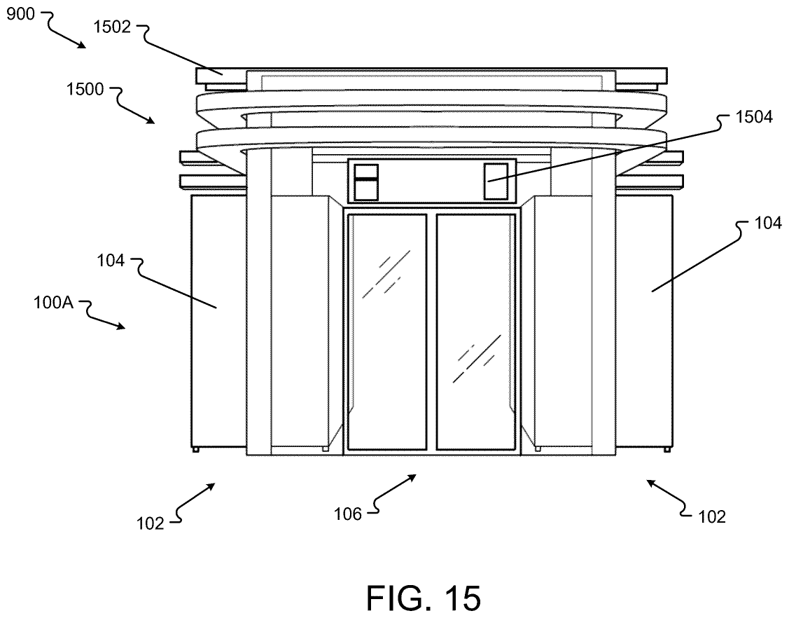

Referring now to FIG. 15, an end or front view of the HAC system 900 is illustrated. For example, the accessory module 1500 includes one or more accessories that are installable on the HAC system 900 and/or on one or more pods 100 (e.g., at least pod 100A, from FIG. 9A) to further customize the HAC system 900 (e.g., in addition to customizing height, width, and/or length of the HAC system 900 and/or the one or more pods 100 that form sections of the HAC system 900, and the like).

In embodiments, the accessory module 1500 includes a cooler platform 1502 that support coolers for circulating a fluid (e.g., a coolant such as a water, a glycol, a water-glycol mixture, and the like, or more generally a liquid or a gas). For example, the cooler platform 1502 may be configured to support liquid-based coolers that circulate a liquid through the fluid module 400 and the fluid end module 1100 to liquid-cool the server racks 104, providing supply liquid at a first lower temperature and receiving return liquid at a second higher temperature. By way of another example, the cooler platform 1502 may be configured to support liquid-based coolers that circulate a liquid through the air-cooling components (e.g., close room air conditioners, and the like) that air-cool the aisle 106 and the server racks 104, providing supply liquid at a first lower temperature and receiving return liquid at a second higher temperature.

In embodiments, the accessory module 1500 includes a user interface 1504 such as an optional data display module. For example, the user interface 1504 may provide operational information about the HAC system 900, and may be in communication with a control system 1600 as described further herein.

In embodiments, the accessory module 1500 includes an interior lighting package. For example, the interior lighting package may illuminate the aisle 106. By way of another example, the interior lighting package may illuminate the working space of the HAC system 900 (e.g., within the modules 200, 300, 400, 700, 800). In some configurations, the interior lighting package is installed on the HAC system 900 as a separate module 1500. In other configurations, the interior lighting package may be integrated into one or more of the modules 200, 300, 400, 700, 800 of one or more of the pods 100A, 100B, 100C during assembly at the factory (e.g., generally, a first location) and prior to installation at the project site (e.g., generally, a second location), without departing from the scope of the present disclosure.

In embodiments, the accessory module 1500 includes a leak detection package. For example, the leak detection package may include sensors to collect data from which it may be determined if there is an air leak from the aisle 106. By way of another example, the leak detection package may include sensors to collect data from which it may be determined there is a coolant leak, where the customer has specified the addition of the fluid cooling modules 400 and/or fluid end module 1100.

In embodiments, the configuration of the HAC system 900 is to be fabricated and assembled separately (i.e., without relying on support of) the rows 102 of the server racks 104. Rather, the HAC system 900 (e.g., including the pods 100 of the HAC system 900, and other modules 1000, 1100, 1200, 1300, 1400, 1500 that attach to the HAC system 900) are standalone from the server racks 104. In this regard, the HAC system 900 is customizable to any server rack or cabinet, while also not relying on the server racks 104 for support when assembled. This non-reliance for support allows for a hot-swapping or interchanging of server racks 104 with reduced or no disassembly of the HAC system 900 and thus reduced or no data center downtime.

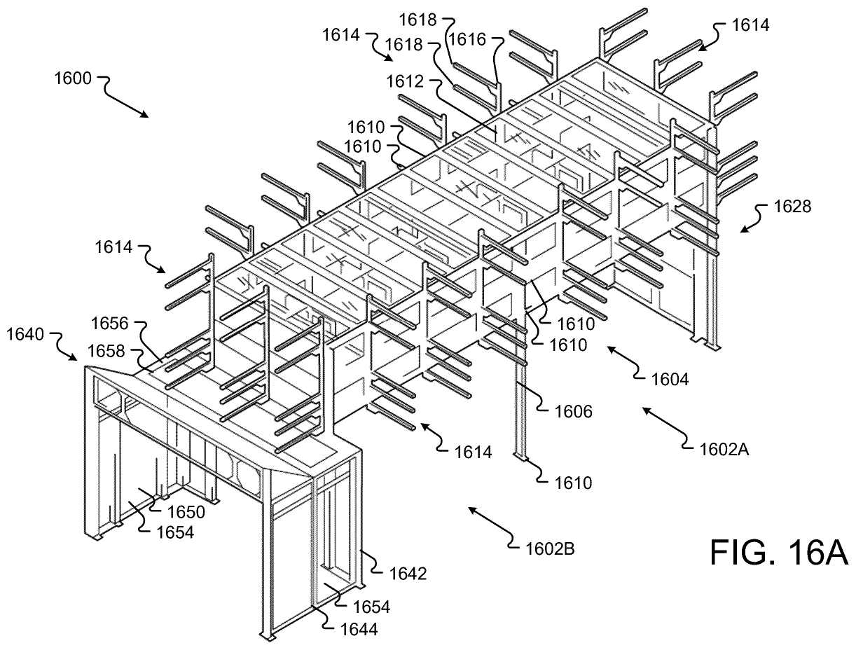

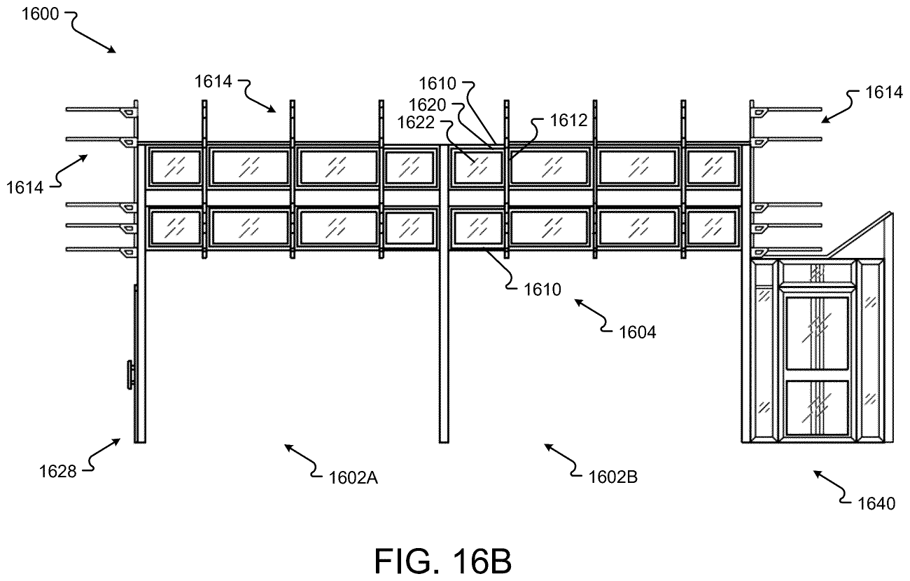

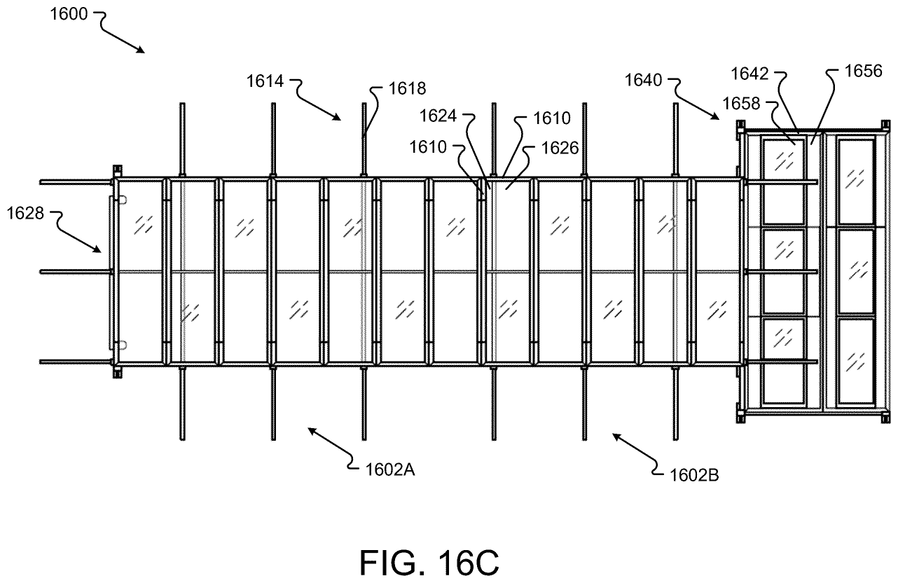

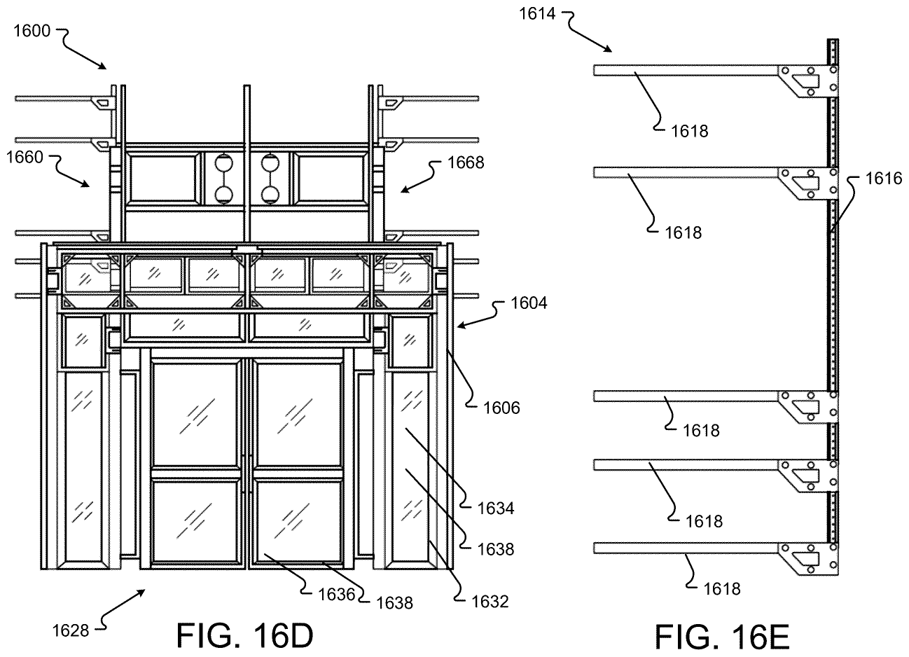

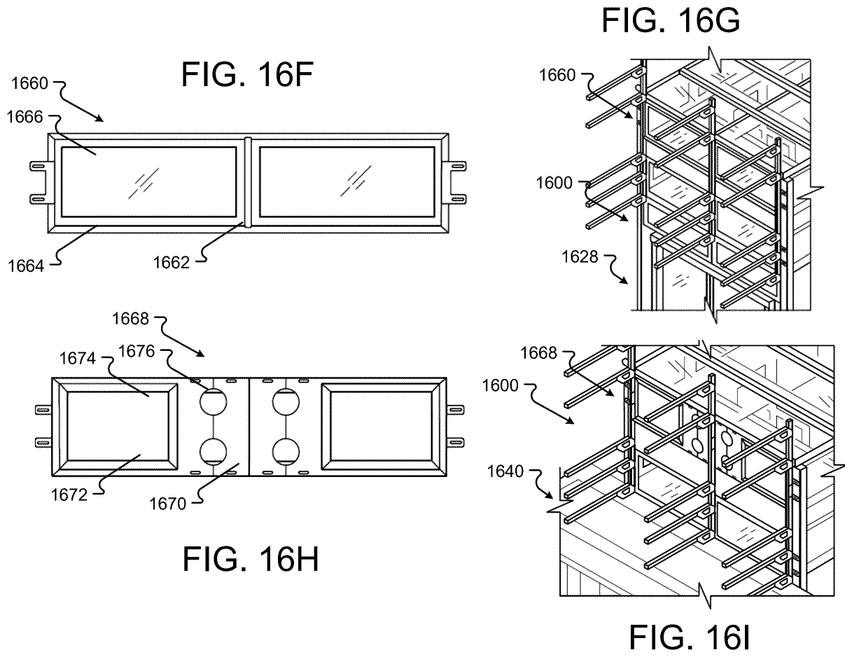

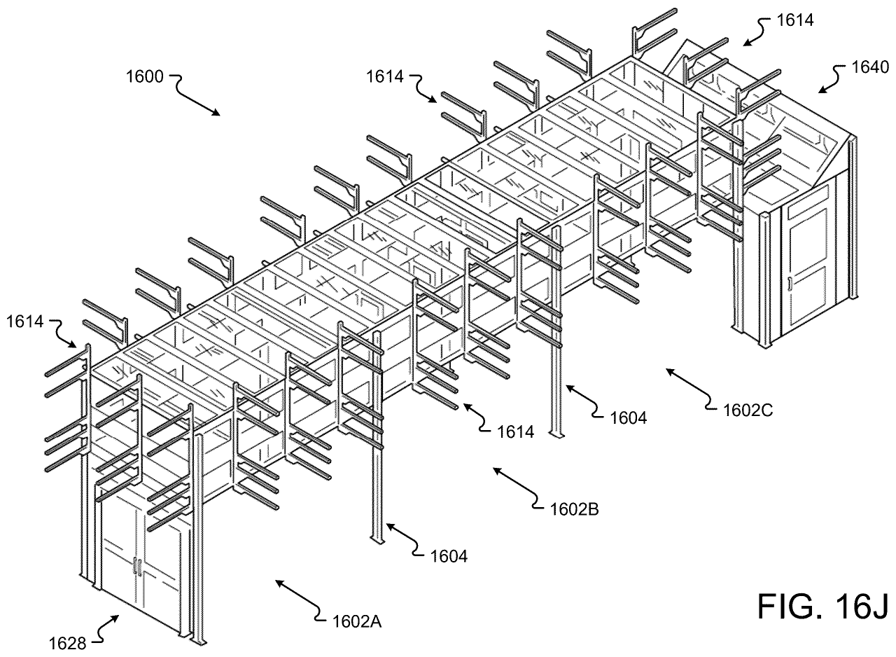

FIGS. 16A-16J generally illustrate a variation of the HAC system 900 with pods 100, labelled HAC system 1600 with pods 1602, in accordance with one or more embodiments of the present disclosure. It should be understood that embodiments directed to the HAC system 900 with pods 100 may be directed to the HAC system 1600 with pods 1602, and vice versa, without departing from the scope of the present disclosure.

In embodiments, the HAC system 1600 includes one or more pods 1602. For example, as illustrated in FIGS. 16A-16I the HAC system 1600 includes a first pod 1602A and a second pod 1602B. By way of another example, as illustrated in FIG. 16J, the HAC system 1600 includes an additional third pod 1602C. In general, however, it should be understood that the HAC system 1600 may include any number of pods 1602, which are added to the HAC system 1600 (e.g., in response to customer specifications).

In embodiments, each pod 1602 includes a frame module 1604. For example, the frame module 1604 may include, but is not limited to, posts 1606 with anchor plates 1608, crossmembers 1610, and/or braces 1612. It should be understood that the embodiments directed to the frame module 200 and the posts 202 with anchor plates 204, the crossmembers 206, and the braces 210 are similarly applicable to the configuration of the frame module 1604 including posts 1606 with anchor plates 1608, crossmembers 1610, and braces 1612, without departing from the scope of the present disclosure. For example, the materials from which the components of the frame module 1604 are manufactured may be similar to those described with respect to the frame module 200. By way of another example, the components of the frame module 1604 may be assembled with coupler elements and/or via affixing processes, as described with respect to the frame module 200. By way of another example, the components of the frame module 1604 (and thus the pods 1602 and the HAC system 1600) may be adjustable in one or more dimensions (e.g., in response to customer specifications), similar to as described with respect to the frame module 200 (and thus the pods 100 and the HAC system 900).

In embodiments, the HAC system 1600 includes one or more hanger arm assemblies 1614. For example, a hanger arm assembly 1614 includes a bar 1616 and a plurality of arms 1618. In some configurations, the hanger arm assembly 1614 may be considered a module of (or be considered a component of a module of) the HAC system 1600.

It should be understood that the embodiments directed to the hanger arm assemblies 710 are similarly applicable to the configuration of the hanger arm assemblies 1614, without departing from the scope of the present disclosure. For example, the materials from which the components of the hanger arm assembly 1614 are manufactured may be similar to those described with respect to the hanger arm assemblies 310, 710, 1210. By way of another example, the components of the hanger arm assembly 1614 may be assembled with coupler elements and/or via affixing processes, as described with respect to the hanger arm assemblies 310, 710, 1210. By way of another example, the components of the hanger arm assembly 1614 (and thus the pods 1602 and the HAC system 1600) may be adjustable in one or more dimensions (e.g., in response to customer specifications), similar to as described with respect to the tray module 700 and the hanger arm assembly 710 (and thus the pods 100 and the HAC system 900).

In some configurations, the hanger arm assemblies 1614 may be installed along one or more sides of the HAC system 1600, similar to the power module 300 and/or the tray module 700 of the pods 100 (and the HAC system 900). Alternatively, or in addition, the hanger arm assemblies 1614 may be installed on at least one end of the HAC system 1600, similar to the end tray module 1200 of the HAC system 900.

In embodiments, the HAC system 1600 includes windows 1620 and/or dividers that attach to and span a space within the frame module 1604. For example, the windows 1620 may span a space defined by one or more crossmembers 1610 and/or braces 1612. It should be understood that the embodiments directed to the windows 806 and/or the dividers 810 are similarly applicable to the configuration of the windows 1620 and/or dividers of the HAC system 1600, without departing from the scope of the present disclosure. For example, the materials from which the components of the windows 1620 and/or dividers of the HAC system 1600 are manufactured may be similar to those described with respect to the windows 806 and/or dividers 810 of the panel module 800. By way of another example, the components of the windows 1620 and/or dividers of the HAC system 1600 may be assembled with coupler elements and/or via affixing processes, as described with respect to the windows 806 and/or dividers 810 of the panel module 800. By way of another example, the components of the windows 1620 and/or dividers of the HAC system 1600 (and thus the pods 1602 and the HAC system 1600) may be adjustable in one or more dimensions (e.g., in response to customer specifications), similar to as described with respect to the windows 806 and/or dividers 810 of the panel module 800 (and thus the pods 100 and the HAC system 900).

In embodiments, the windows 1620 may include a pane 808 fabricated from a same or different material as the window 1620. However, it is also contemplated that windows 1620 may be fabricated from a single piece of material, such that the pane 1622 may not be included, without departing from the scope of the present disclosure.

In some configurations, the windows 1620 may be installed along one or more sides of the HAC system 1600, similar to the panel module 800 of the pod 100 (and of the HAC system 900). Alternatively, or in addition, the windows 1620 may be installed on at least one end of the HAC system 1600, similar to the windows 1316 of the door module 1300 of the HAC system 900.

In embodiments, the HAC system 1600 includes one or more ceiling panels 1624. For example, the ceiling panels 1624 may be attached to the frame module 1604, and span a space defined by one or more crossmembers 1610 and/or braces 1612 of the frame module 1604. The one or more ceiling panels 1624 may be coupled to the frame module 1604 via coupler elements including, but not limited to, interlocking assemblies, fasteners, adhesives, or the like. Alternatively, or in addition, one or more of the ceiling panels 1624 may be affixed to the frame module 1604 via joining processes (e.g., welding, or the like).

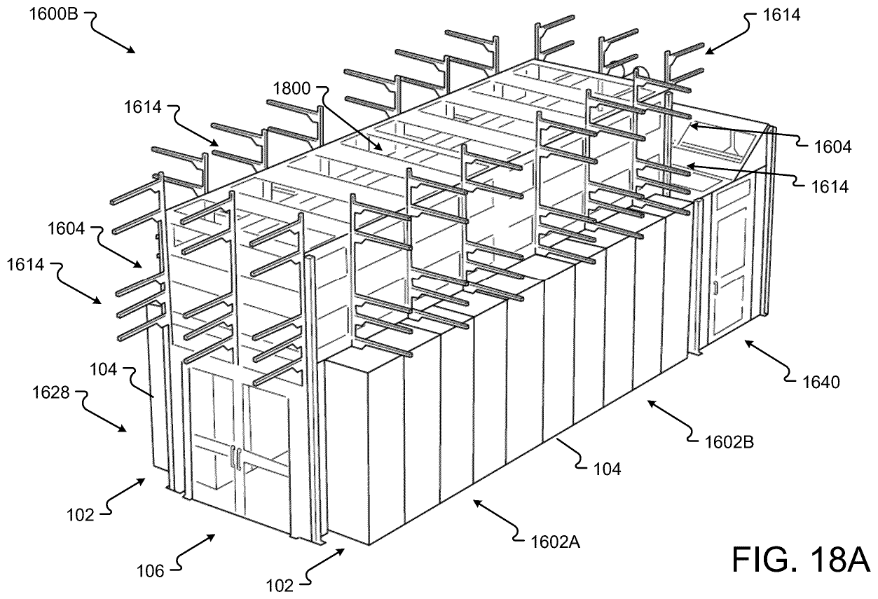

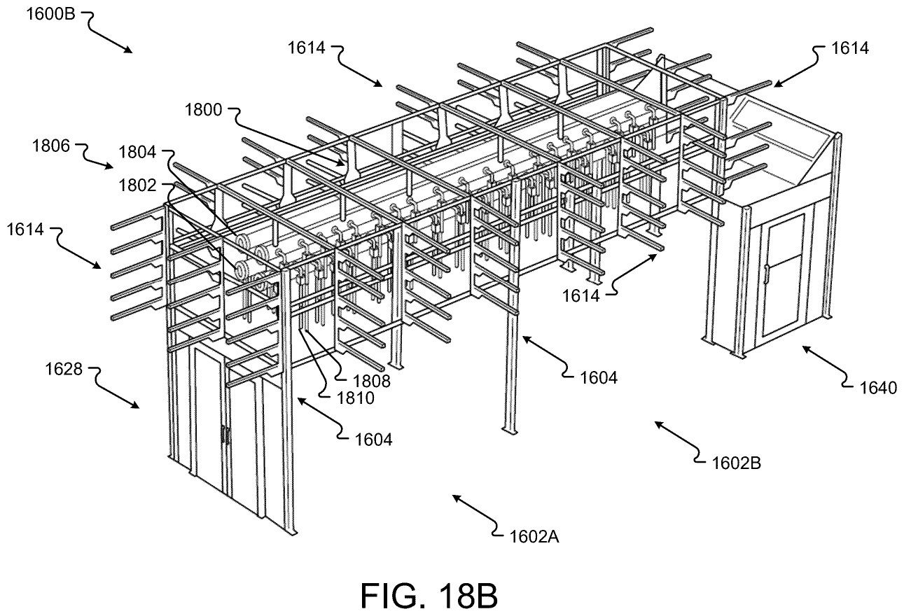

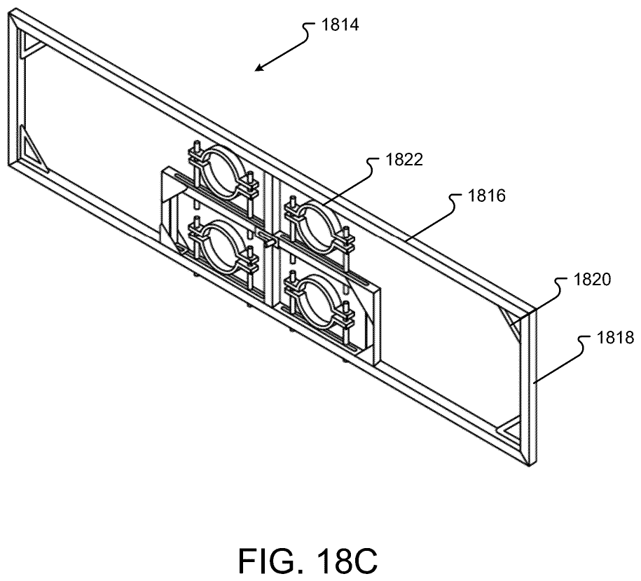

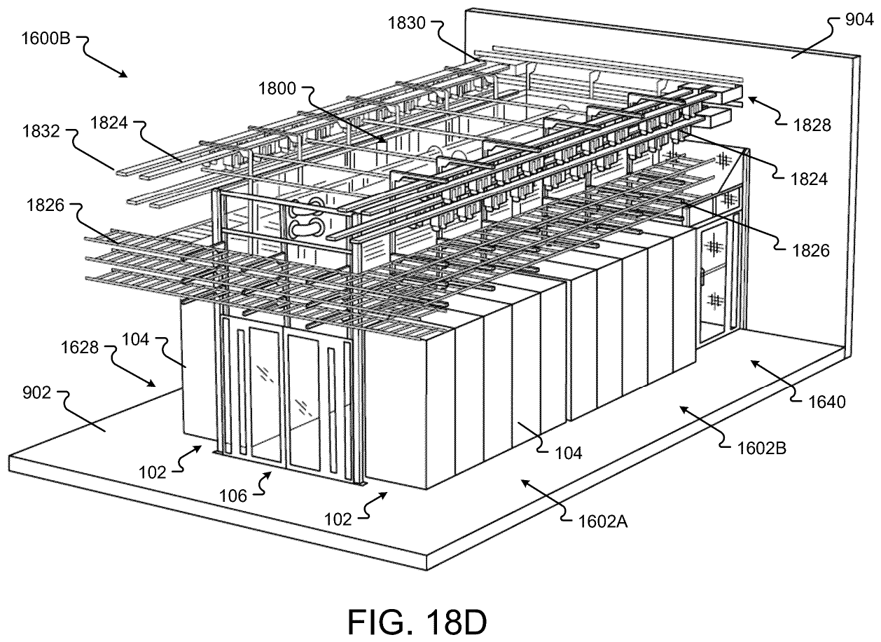

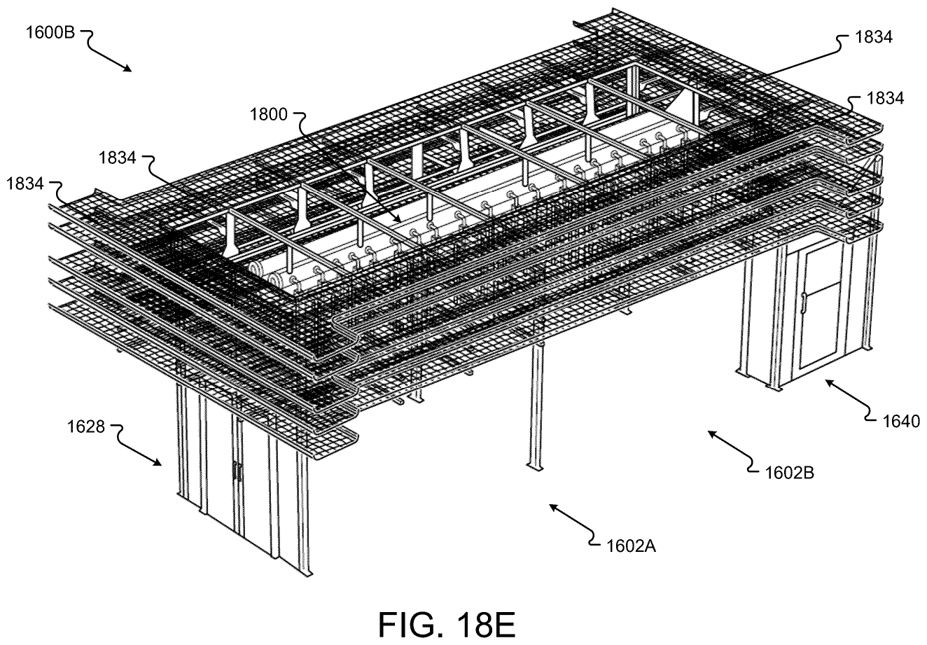

In some configurations, the one or more ceiling panels 1624 may be installed as separate sections that are spaced or abut together, may be separately fabricated and installed in pre-assembled lengths, or may be fabricated and installed as a single continuous length. It is noted that abutting separate windows or sections of windows may serve to better enclose the aisle 106 between adjacent rows 102 of server racks 104 (e.g., as generally illustrated in FIGS. 18A-18E), as compared to spaced one or more ceiling panels 1624.

In embodiments, the one or more ceiling panels 1624 may include a pane 1626 fabricated from an opaque, translucent, or transparent material. For example, the material may be a plastic, a glass, or a metal. By way of another example, the material may be of a thickness to be flexible (e.g., similar to a vinyl panel or other lightweight fabric material) or may be of a thickness to be at least semi-rigid, without departing from the scope of the present disclosure. However, it is also contemplated that one or more ceiling panels 1624 may be fabricated from a single piece of material, such that the pane 1626 may not be included, without departing from the scope of the present disclosure.

In embodiments, the HAC system 1600 includes one or more door modules 1628. In embodiments, the door module 1628 may be installable on, and positionable at one or more locations on, the HAC system 1600. For example, the HAC system 1600 may include at least one door module 1628. For instance, where there are two rows 102 of server racks 104 that define an aisle 106 therebetween (e.g., as illustrated in FIGS. 18A-18E), the HAC system 1600 includes at least one (and optionally two) door modules 1628 located at a particular end of the aisle 106. However, it should be understood that this arrangement is not intended to be limiting on the present disclosure.

In embodiments, the door module 1628, along with the windows 1620 and the ceiling panels 1624, may at least partially enclose the aisle 106 defined between the rows 102 of server racks 104 (and above, within the modules of the pods 1602/the HAC system 1600 including the pods 1602). In some configurations, complete or nearly complete enclosure may be beneficial to be able to regulate the volume of the aisle 106 using air-cooling technologies (e.g., close room air conditioners, or the like) in addition to fluid cooling provided to the server racks 104, creating a hybrid cooling arrangement where fluid cooling and/or air cooling may be employed within the pod 1602 (and the HAC system 1600) as desired.

In embodiments, the door module 1628 includes a door assembly 1630 that is installable on the frame module 1604. For example, the door assembly 1630 may include a frame 1632 that is coupled to the frame module 1604 of a particular pod 1602 (e.g. pod 1602A). In some configurations, the door assembly 1302 includes a fixed portion 1634 within the frame 1632, and one or more doors 1636 installed within the frame 1632 that actuate relative to the fixed portion 1634. For example, the doors 1636 may slide relative to the fixed portion 1634 between an open position and a closed position. By way of another example, the doors 1636 may pivot about an axis through hinges relative to the fixed portion 1634 between an open position and a closed position. In general, it should be understood that doors 1636 may actuate relative to the frame 1632 in any of a swinging, a sliding, a pivoting, or other movement for opening and closing to allow or deny access to the aisle 106 between the adjacent rows 102 of server racks 104.

In some configurations, the fixed portion 1634 and the one or more doors 1636 may be installed as separate sections that are spaced or abut together, may be separately fabricated and installed in pre-assembled lengths, or may be fabricated and installed as a single continuous length. It is noted that abutting the fixed portion 1634 and the one or more doors 1636, or more generally including seals between the frame 1632 and the frame module 1604 and/or the fixed portion 1634 and the one or more doors 1636, may serve to better enclose the aisle 106 between adjacent rows 102 of server racks 104, as compared to components within the door assembly 1630 being spaced apart. It is noted that the one or more doors 1636 may fully fill the frame 1632 between the frame module 1604, such that the fixed portion 1634 may not be included within the doors 1636, without departing from the scope of the present disclosure.

In embodiments, the doors 1636 and/or the optional fixed portion 1634 of the frame 1632 may include a pane 1638. It should be understood that the embodiments directed to the door module 1300 are similarly applicable to the configuration of the door module 1628, without departing from the scope of the present disclosure. For example, the materials from which the components of the door module 1628 are manufactured may be similar to those described with respect to the door module 1300. By way of another example, the components of the door module 1628 may be assembled with coupler elements and/or via affixing processes, as described with respect to the door module 1300. By way of another example, the components of the door module 1628 (and thus the pods 1602 and the HAC system 1600) may be adjustable in one or more dimensions (e.g., in response to customer specifications), similar to as described with respect to the door module 1300 (and thus the pods 100 and the HAC system 900).

In embodiments, the HAC system 1600 includes the door module 1628 that is installable at a first end, and a transition corridor module 1640 that is installable at a second end. For example, where the wall surface 904 is between the HAC system 1600 and a mechanical corridor, the transition corridor module 1640 provides a connection between the HAC system 1600 and the mechanical corridor through an opening within the wall surface 904.

In embodiments, the transition corridor module 1640 includes a frame 1642 that is coupled to the frame module 1604 of a particular pod 1602 (e.g. pod 1602A). In some configurations, the frame 1642 includes one or more posts 1644 with anchor plates 1646. However, it is contemplated that the posts 1644 with anchor plates 1646 may be components of the frame module 1604, without departing from the scope of the present disclosure.

In some configurations, the door assembly 1302 includes a fixed portion 1648 within the frame 1642, and one or more doors 1650 installed within the frame 1642 that actuate relative to the fixed portion 1648. For example, the doors 1650 may slide relative to the fixed portion 1648 between an open position and a closed position. By way of another example, the doors 1650 may pivot about an axis through hinges relative to the fixed portion 1648 between an open position and a closed position. In general, it should be understood that doors 1650 may actuate relative to the frame 1642 in any of a swinging, a sliding, a pivoting, or other movement for opening and closing to allow or deny access to the aisle 106 between the adjacent rows 102 of server racks 104.

In some configurations, the fixed portion 1648 and the one or more doors 1650 may be installed as separate sections that are spaced or abut together, may be separately fabricated and installed in pre-assembled lengths, or may be fabricated and installed as a single continuous length. It is noted that abutting the fixed portion 1648 and the one or more doors 1650, or more generally including seals between the frame 1642 and the fixed portion 1648 and the one or more doors 1650, may serve to better enclose the aisle 106 between adjacent rows 102 of server racks 104, as compared to components within the door assembly 1630 being spaced apart. It is noted that the one or more doors 1650 may fully fill the frame 1642, such that the fixed portion 1648 may not be included within the transition corridor module 1640, without departing from the scope of the present disclosure.

In some configurations, the one or more doors 1650 are offset from the aisle 106. Here, the transition corridor module 1640 may be positioned proximate to a wall surface 904 (e.g., as illustrated in FIG. 18D), where the wall surface 904 optionally includes an opening that provides access into the transition corridor module 1640 from a mechanical corridor. However, it is contemplated that the one or more doors 1650 may be aligned with the aisle 106 (e.g., similar to the doors 1636 of the door assembly 1630), without departing from the scope of the present disclosure. Here, in some non-limiting examples the HAC system 1600 may not be proximate to a wall surface 904 and/or the doors 1650 may be within the opening of the wall surface 904.

In embodiments, the doors 1650 and/or the optional fixed portion 1648 of the frame 1642 may include a pane 1654 fabricated from a same or different material as the doors 1650 and/or the optional fixed portion 1648. However, it is also contemplated that the doors 1650 and/or the optional fixed portion 1648 may be fabricated from a single piece of material, such that the pane 1654 may not be included, without departing from the scope of the present disclosure.

It should be understood that the embodiments directed to the door modules 1300, 1628 are similarly applicable to the configuration of the transition corridor module 1640, without departing from the scope of the present disclosure. For example, the materials from which the components of the transition corridor module 1640 are manufactured may be similar to those described with respect to the door modules 1300. By way of another example, the components of the transition corridor module 1640 may be assembled with coupler elements and/or via affixing processes, as described with respect to the door modules 1300. By way of another example, the components of the transition corridor module 1640 (and thus the pods 1602 and the HAC system 1600) may be adjustable in one or more dimensions (e.g., in response to customer specifications), similar to as described with respect to the door modules 1300 (and thus the pods 100 and the HAC system 900)

In embodiments, the transition corridor module 1640 includes one or more ceiling panels 1656. For example, the ceiling panels 1656 may span a space defined by the frame 1642. In embodiments, the one or more ceiling panels 1656 may include a pane 1658. However, it is also contemplated that one or more ceiling panels 1656 may be fabricated from a single piece of material, such that the pane 1658 may not be included, without departing from the scope of the present disclosure. It should be understood that the embodiments directed to the ceiling panels 1624 with optional panes 1626 are similarly applicable to the configuration of the ceiling panels 1656 with optional panes 1658, without departing from the scope of the present disclosure.

In embodiments, the HAC system 1600 includes a truss plate 1660 with a frame 1662. For example, the truss plate 1660 may be attached to the frame module 1604, and span a space defined by one or more crossmembers 1610 and/or braces 1612 of the frame module 1604. The truss plate 1660 may be coupled to the frame module 1604 via coupler elements including, but not limited to, interlocking assemblies, fasteners, adhesives, or the like. Alternatively, or in addition, the truss plate 1660 may be affixed to the frame module 1604 via joining processes (e.g., welding, or the like.

In embodiments, the truss plate 1660 includes one or more windows 1664. In some configurations, the one or more windows 1664 may be installed as separate sections that are spaced or abut together, may be separately fabricated and installed in pre-assembled lengths, or may be fabricated and installed as a single continuous length. It is noted that abutting separate windows or sections of windows may serve to better enclose the aisle 106 between adjacent rows 102 of server racks 104 (e.g., as generally illustrated in FIGS. 18A-18E), as compared to spaced one or more windows 1664.

In embodiments, the windows 1664 may include a pane 1666 fabricated from a same or different material as the windows 1664. For example, the pane 1666 may be fabricated from an opaque, translucent, or transparent material. For example, the material may be a plastic, a glass, or a metal. By way of another example, the material may be of a thickness to be flexible (e.g., similar to a vinyl panel or other lightweight fabric material) or may be of a thickness to be at least semi-rigid, without departing from the scope of the present disclosure. However, it is also contemplated that one or more windows 1664 may be fabricated from a single piece of material, such that the pane 1666 may not be included, without departing from the scope of the present disclosure.

In embodiments, the HAC system 1600 includes a fluid conduit plate 1668 with a frame 1670. For example, the fluid conduit plate 1668 may be attached to the frame module 1604, and span a space defined by one or more crossmembers 1610 and/or braces 1612 of the frame module 1604. The fluid conduit plate 1668 may be coupled to the frame module 1604 via coupler elements including, but not limited to, interlocking assemblies, fasteners, adhesives, or the like. Alternatively, or in addition, the fluid conduit plate 1668 may be affixed to the frame module 1604 via joining processes (e.g., welding, or the like).

In embodiments, the fluid conduit plate 1668 includes one or more windows 1672. In some configurations, the one or more windows 1672 may be installed as separate sections that are spaced or abut together, may be separately fabricated and installed in pre-assembled lengths, or may be fabricated and installed as a single continuous length. It is noted that abutting separate windows or sections of windows may serve to better enclose the aisle 106 between adjacent rows 102 of server racks 104 (e.g., as generally illustrated in FIGS. 18A-18E), as compared to spaced one or more windows 1672.

In embodiments, the windows 1672 may include a pane 1674 fabricated from a same or different material as the windows 1672. For example, the pane 1666 may be fabricated from an opaque, translucent, or transparent material. For example, the material may be a plastic, a glass, or a metal. By way of another example, the material may be of a thickness to be flexible (e.g., similar to a vinyl panel or other lightweight fabric material) or may be of a thickness to be at least semi-rigid, without departing from the scope of the present disclosure. However, it is also contemplated that one or more windows 1672 may be fabricated from a single piece of material, such that the pane 1674 may not be included, without departing from the scope of the present disclosure.

In embodiments, the frame 1670 includes one or more apertures 1676. For example, where the HAC system 1600 is configured for fluid-cooling, the one or more apertures 1676 may be dimensioned to receive fluid pipes for the fluid-cooling system.

Although FIGS. 16A-16J generally illustrate one arrangement of the HAC system 1600 with the truss plate 1660 located proximate to the door assembly 1630 and the fluid conduit plate 1668 located proximate to the transition corridor module 1640, it should be understood that this is not limiting to the present disclosure. For example, the truss plate 1660 and the fluid conduit plate 1668 may be interchangeable, depending on whether fluid-cooling pipes are configured to pass through the front end or the rear end of the HAC system 1600. By way of another example, the HAC system 1600 may include two fluid conduit plates 1668, such as when fluid-cooling pipes are configured to pass through the front end and the rear end of the HAC system 1600. By way of another example, the HAC system 1600 may include two trusses 1660, such as when the HAC system 1600 is only air-cooled as does not require the apertures 1676 for fluid-cooling pipes.

It is noted that the hanger arm assemblies 1614 including the bars 1616 and/or the arms 1618, the windows 1620, the ceiling panels 1624, the door module 1628, and/or the transition corridor module 1640 may be considered components of the frame module 1604, for purposes of the present disclosure. In some instances, integrating the hanger arm assemblies 1614 including the bars 1616 and/or the arms 1618, the windows 1620, the ceiling panels 1624, the door module 1628, and/or the transition corridor module 1640 within the frame module 1604 may simplify the manufacturing and assembly of the HAC system 1600, by integrating aspects of the modules 300, 700, 800 as illustrated in the pods 100 and the HAC system 900.

As illustrated in FIG. 16E, in embodiments the arms 1618 evenly or unevenly spaced (e.g., vertically). The arms 1618 may be configured to support one or more of a power conduit 1824, a shelf 1826, and/or a cable tray 1834, or other component installed on an exterior of the frame module 1604. It should be understood that the embodiments directed to the power conduit 320, the cable tray 720, and/or the shelf 724 are similarly applicable to the configuration of the power conduit 1824, the shelf 1826, and/or the cable tray 1834, without departing from the scope of the present disclosure. For example, the materials from which the components of the hanger arm assembly 1614 are manufactured may be similar to those described with respect to the power conduit 320, the cable tray 720, and/or the shelf 724. By way of another example, the components of the hanger arm assembly 1614 may be assembled with coupler elements and/or via affixing processes, as described with respect to the power conduit 320, the cable tray 720, and/or the shelf 724. By way of another example, the components of the power conduit 1824, the shelf 1826, and/or the cable tray 1834 (and thus the pods 1602 and the HAC system 1600) may be adjustable in one or more dimensions (e.g., in response to customer specifications), similar to as described with respect to the power module 300 including the power conduit 320, and the tray module 700 including the cable trays 720 and shelves 724 (and thus the pods 100 and the HAC system 900).

Although embodiments of the present disclosure are directed to the power conduits 1824 for power cable management and cable trays 1834 for networking or data cable management, it should be understood that this is not limiting on the present disclosure. For example, the power conduits 1824 may be conduits for routing networking or data cables, and/or the cable trays 1834 may be conduits for routing power cables, without departing from the scope of the present disclosure.

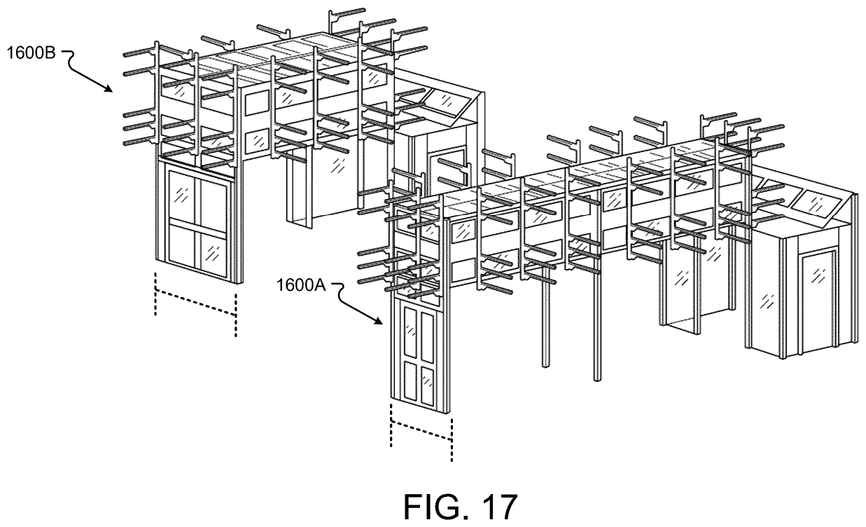

In embodiments, HAC systems 1600A employing only air-cooling and HAC system 1600B employing air-cooling and fluid-cooling may be the same or different in dimensions. For example, as illustrated in FIG. 17, although the same HAC system 1600 may be used for air-cooling and/or fluid-cooling, it is contemplated that there are benefits (e.g., lower weight, material cost, footprint of HAC system 1600, and the like) to reducing at least the width of an HAC system 1600A employing only air-cooling, as the air-cooled HAC system 1600A would not require the additional width needed to install the fluid-cooling components of the fluid-cooled HAC system 1600B.

FIGS. 18A-18E in general illustrate the HAC system 1600B configured for fluid-cooling, in accordance with one or more embodiments of the present disclosure.

In embodiments, the HAC system 1600B with pods 1602A, 1602B configured for fluid-cooling may include (or be installed proximate to) one or more rows 102 of server racks 104. For example, the HAC system 1600B with pods 1602A, 1602B may include (or be installed proximate to) two rows 102 of server racks 104 that define a gap or space for exhaust therebetween. It is noted that the HAC system 1600B with pods 1602A, 1602B and the one or more rows 102 of server racks 104 may be arranged in an aisle configuration, such that the gap or space is an aisle 106, for purposes of the present disclosure.

As generally illustrated in FIGS. 16A-18E, in some configurations the transition corridor module 1640 is wider than the pods 1602A, 1602B. It is noted that this may be to accommodate an amount that the server racks 104 extend away from the sidewalls of the HAC system 1600B. For example, this dimensioning of the transition corridor module 1640 may provide increased control over the thermal conditions within the HAC system 1600B. By way of another example, this dimensioning of the transition corridor module 1640 may provide increased aesthetics to the HAC system 1600B by making the offset door 1650 of the transition corridor module 1640 substantially flush with the outward faces of the server racks 104.

In embodiments as illustrated in FIGS. 18B-18D, the HAC system 1600B includes a fluid cooling module 1800. In general, any embodiments directed to the fluid cooling module 400 should be understood as being directed to the fluid cooling module 1800, and vice versa, without departing from the scope of the present disclosure. For example, the HAC system 1600B may include one fluid cooling module 1800 that supplies adjacent rows 102 of server racks 104. For instance, where there are two rows 102 of server racks 104, the pod 100 includes one fluid cooling module 1800. However, it should be understood that this arrangement is not intended to be limiting on the present disclosure.

In embodiments, the fluid cooling module 1800 may include a supply pipe 1802 and a return pipe 1804 in one or more pipe sets 1806 for a fluid (e.g., a coolant such as a water, a glycol, a water-glycol mixture, and the like, or more generally a liquid or a gas). For example, the supply pipe 1802 may provide fluid at a cooler temperature than the fluid received in the return pipe 1804. Optionally, the return pipe 1804 may be exterior to the HAC system 1600B, such that only a supply pipe 1802 is provided within the HAC system 1600B. Alternatively, the supply pipe 1802 may be exterior to the HAC system 1600B, such that only the return pipe 1804 is provided within the HAC system 1600B.

In non-limiting examples illustrated in FIGS. 18B-18D, the fluid cooling module 1800 includes a pipe set 1806 including a supply pipe 1802 and a return pipe 1804 for each of the rows 102 of server racks 104. It should be understood that the arrangement illustrated in FIGS. 18B-18D is not intended to be limiting on the present disclosure. For example, any of the embodiments related to the supply pipe 412 (with optional supply port 1102 and/or supply pipe joint 1106) and/or the return pipe 414 (with optional return port 1104 and/or return pipe joint 1108) may similarly be applicable to the configuration of the supply line 1808 and/or the return line 1810, respectively, without departing from the scope of the present disclosure.

In addition, as illustrated in FIGS. 18B-18E, the fluid cooling module 1800 includes a supply line 1808 from the supply pipe 1802 and a return line 1810 to the return pipe 1804 for each of the server racks 104 within a particular row 102. It should be understood that the arrangement illustrated in FIGS. 18B-18D is not intended to be limiting on the present disclosure. For example, any of the embodiments related to the supply line 418 and/or the return line 420 may similarly be applicable to the configuration of the supply line 1808 and/or the return line 1810, respectively, without departing from the scope of the present disclosure. For instance, like with HAC system 900 and the end fluid module 1100, the fluid cooling module 1800 may include pipe joints for the supply pipe 1802, which couples multiple sections of the supply pipe 1802 together to be fed by and circulate to supply ports within a wall surface 904. In addition, like with HAC system 900 and the end fluid module 1100, the fluid cooling module 1800 may include pipe joints for the return pipe 1804, which couples multiple sections of the return pipe 1804 together to be fed by and circulate to return ports within a wall surface 904.

In some configurations, fluid flow through one or more of the supply pipe 1802, the supply line 1808, the return pipe 1804, and/or the return line 1810 is controlled by a valve 1812. The valve 1812 may be manually controlled by a technician. Alternatively, or in addition, the valve 1812 may be solenoid valves (e.g., solenoid-driven gate valves, solenoid-driven ball valves, or the like) that are electronically controlled either by a technician via a control system. It is also noted that the valve 1812 may be a solenoid valve that is automatically controlled by a control system in response to acquired sensor data monitoring operational parameters within the HAC system 1600B.

In embodiments, like with the integration of hanger arm assemblies 1614 into the frame modules 1604 into the pods 1602A, 1602B, the fluid cooling module 1800 may similarly be integrated into the frame module 1604. As illustrated in FIG. 18C, the fluid cooling module 1800 includes one or more frames 1814 that are installable on, and positionable at one or more locations on, the frame module 1604. For example, each of the pods 1602A, 1602B may includes one or more frames 1814 for the fluid cooling module 1800. Being integrated into the frame modules 1604 allows for the enclosure of the fluid cooling module 1800 within a cavity defined by one or more of the windows 1620, the ceiling panels 1624, the truss plate 1660, and/or the fluid conduit plate 1668 of the frame module 1604.

In embodiments, the frame 1814 may be installable on one or more posts 1606, crossmembers 1610, and/or one or more braces 1612 of the frame module 1604. For example, the frame 1814 may be coupled to one or more posts 1606, crossmembers 1610, and/or one or more braces 1612 via coupler elements including, but not limited to, interlocking assemblies, fasteners, adhesives, or the like. Alternatively, or in addition, the frame 1814 may be affixed to respective one or more posts 1606, crossmembers 1610, and/or one or more braces 1612 via joining processes (e.g., welding, or the like).

In embodiments, the frame 1814 includes a plurality of crossmembers 1816 in a horizontal or substantially horizontal orientation. In embodiments, the frame 1814 includes a plurality of posts 1818 in a vertical or substantially vertical orientation. Optionally, the frame 1814 includes a plurality of braces 1820 set at an oblique angle to the crossmembers 1816 and/or the posts 1818. For example, the crossmembers 1816, the posts 1818, and/or the braces 1820 may be coupled together to form the frame 1814 via coupler elements including, but not limited to, interlocking assemblies, fasteners, adhesives, or the like. Alternatively, or in addition, one or more of the crossmembers 1816, the posts 1818, and/or the braces 1820 may be affixed together via joining processes (e.g., welding, or the like) to form the frame 1814.

In embodiments, the fluid cooling module 1800 includes one or more hangers 1822 for the supply pipes 1802 and/or the return pipes 1804. For example, the hangers 1822 may be attached to the frame 1814 via coupler elements including, but not limited to, interlocking assemblies, fasteners, adhesives, or the like. Alternatively, or in addition, one or more of the hangers 1822 may be affixed to the frame 1814 via joining processes (e.g., welding, or the like). It is noted that the hangers 1822 may be evenly or unevenly distributed through the HAC system 1600B to support the supply pipes 1802 and/or the return pipes 1804.

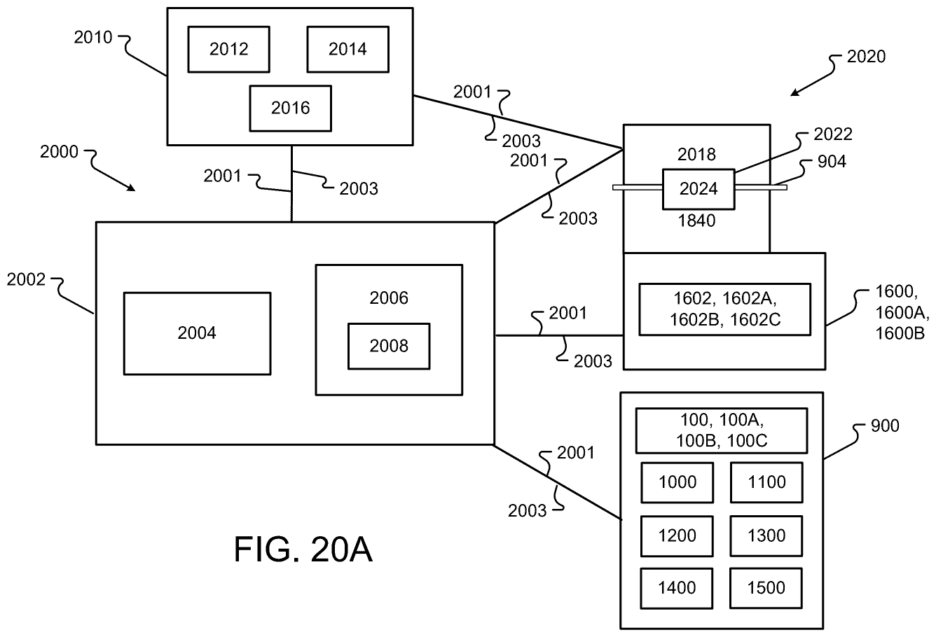

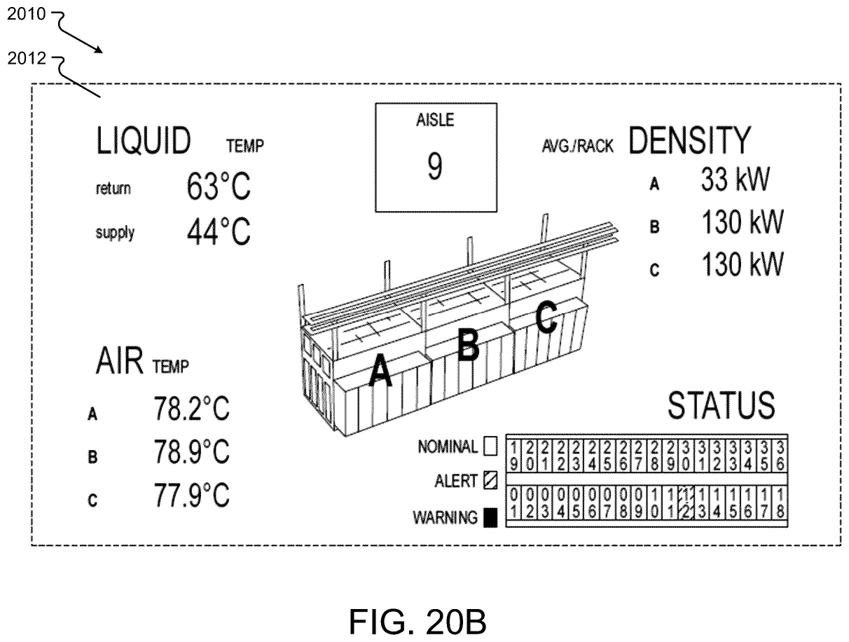

In embodiments, the HAC system 1600B is installed proximate to a floor surface 902 and/or a wall surface 904. Where the HAC system 1600B is proximate to the wall surface 904, the wall surface 904 may include a return air opening 2022 that leads from the mechanical corridor 2018 to the transition corridor module 1640 or a second door module 1628. In some configurations, a security screen 2024 is installed in the opening 2022 within the wall surface 904 that optionally prevents access through the return air opening 2022 from the mechanical corridor 2018. Where the HAC system 1600B includes the fluid cooling modules 1800, it is noted that the security screen 2024 may include apertures for support ports and/or return ports to pass through into the HAC system 1600B to couple to the fluid module 1800. It is noted that the mechanical corridor 2018, the data center 2020, the opening 2022 within the wall surface 904, and the security screen 2024 are illustrated in FIG. 20A.

In embodiments as illustrated in FIG. 18D, the HAC system 1600B may include one or more power conduits 1824 and/or one or more shelves 1826. For example, the one or more power conduits 1824 and/or the one or more shelves 1826 may be installed on the hanger arm assemblies 1614. It is noted that any embodiments directed to the power conduits 320 may be directed to the power conduits 1824, and vice versa, without departing from the scope of the present disclosure. Similarly, it is noted that any embodiments directed to the shelves 724 may be directed to the shelves 1826, and vice versa, without departing from the scope of the present disclosure.

It should be understood that the arrangement illustrated in FIG. 18D is not intended to be limiting for the present disclosure. For example, like with HAC system 900 and the power end module 1000, and where the HAC system 1600B is proximate to the wall surface 904, the HAC system 1600B may include a power end module 1828 with one or more power conduit joints 1830 and/or end stops 1832 in communication with the power conduits 1824. It is noted that any embodiments directed to the power end module 1000 may be directed to the power module 1828, and vice versa, without departing from the scope of the present disclosure.

In embodiments, as illustrated in FIG. 18E, the HAC system 1600B may include one or more cable trays 1834. For example, the one or more cable trays 1834 may be installed on the hanger arm assemblies 1614. It is noted that any embodiments directed to the cable trays 720 may be directed to the cable trays 1834, and vice versa, without departing from the scope of the present disclosure.

Although embodiments are directed to the HAC system 1600B including one or more of the power conduits 1824, the shelves 1826, and/or the cable trays 1834, it should be understood that the HAC system 1600A configured for air-cooling may include one or more of the power conduits 1824, the shelves 1826, and/or the cable trays 1834, without departing from the scope of the present disclosure. In general, any configuration of the HAC system 1600 may include one or more of the power conduits 1824, the shelves 1826, and/or the cable trays 1834.

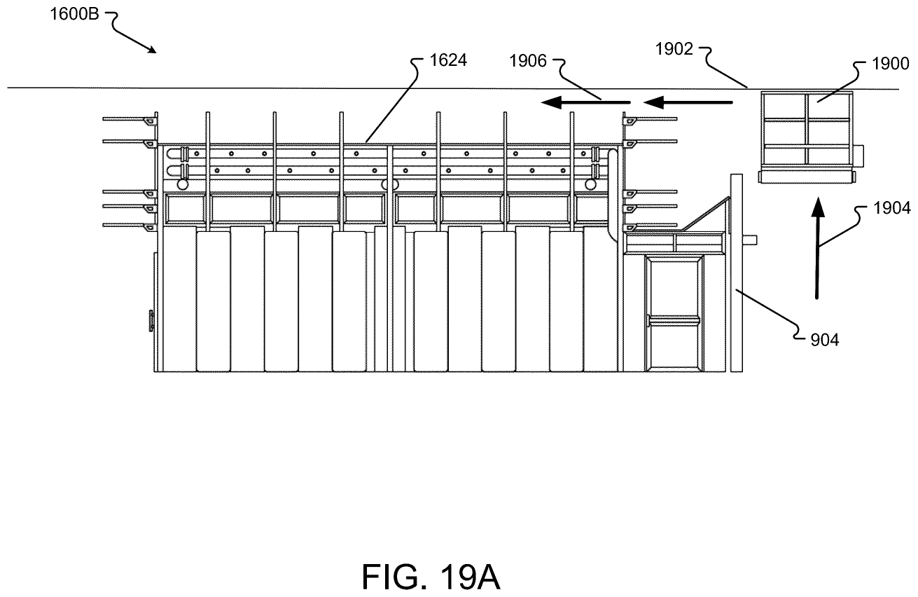

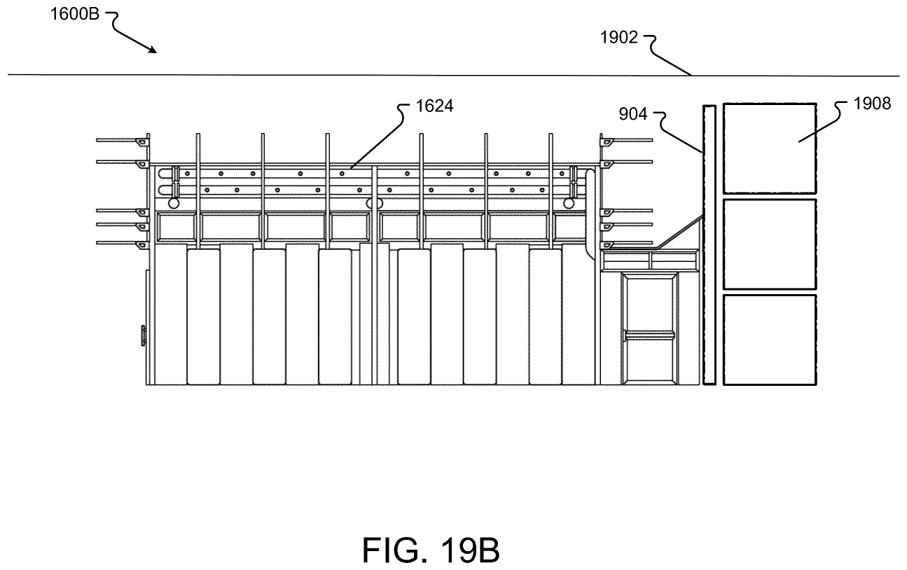

Referring now to FIG. 19A, the HAC system 1600B may be positioned proximate to a cooling unit 1900 mounted on a ceiling surface 1902 (e.g., within a mechanical corridor). For example, the HAC system 1600B may be located such that warm air 1904 is drawn into the cooling unit 1900 and cool air 1906 passes over/through the wall surface 904 to the HAC system 1600B. For instance, the cool air may pass between the ceiling surface 1902 and ceiling panels 1624 of the HAC system 1600B.

Referring now to FIG. 19B, the HAC system 1600B may be positioned proximate to cooling units 1908 that are stacked proximate to the HAC system 1600B and the wall surface 904. For example, the HAC system 1600B may be located such that warm air 1904 is drawn into the cooling units 1908 and cool air 1906 passes over/through the wall surface 904 to the HAC system 1600B. For instance, the cool air may pass between the ceiling surface 1902 and ceiling panels 1624 of the HAC system 1600B.

Although embodiments are directed to the HAC system 1600B being proximate to ceiling-mounted cooling units 1900 or stacked cooling units 1908, it should be understood that the HAC system 1600A configured for air-cooling only may be proximate to ceiling-mounted cooling units 1900 or stacked cooling units 1908, without departing from the scope of the present disclosure. In general, any configuration of the HAC system 1600 may be proximate to ceiling-mounted cooling units 1900 or stacked cooling units 1908.

FIGS. 20A and 20B generally illustrate a control system 2000, in accordance with one or more embodiments of the present disclosure.

For example, the control system 2000 may include (or be separate from but in communication with) the HAC system 900 with the one or more pods 100A, 100B, 100C. It should be understood that embodiments directed to the assemblies, subassemblies, and/or components of the pod 100 from FIGS. 1A-15 and the HAC system 900 in FIGS. 9A-15 may be applicable to the pods 100A, 100B, 100C and the HAC system 900 in FIGS. 20A and 20B, and vice versa, without departing from the scope of the present disclosure.

By way of another example, the control system 2000 may include (or be separate from but in communication with) the HAC systems 1600, 1600A, 1600B with the one or more pods 1602, 1662A, 1602B, 1602C. It should be understood that embodiments directed to the assemblies, subassemblies, and/or components of the pods 1602, 1602A, 1602B, 1602C and the HAC system 1600, 1600A, 1600B in FIGS. 16A-19B may be applicable to the pods 1602, 1602A, 1602B, 1602C and the HAC system 1600, 1600A, 1600B in FIGS. 20A and 20B, and vice versa, without departing from the scope of the present disclosure.

In embodiments, the control system 2000 includes one or more control units 2002 (e.g., a controller, server, or the like) in communication with components of the HAC system 900 and/or the HAC system 1600, 1600A, 1600B. For example, the control units 2002 may acquire data 2001 from the HAC system 900 and/or the HAC system 1600, 1600A, 1600B. For instance, the data 2001 may be data regarding temperature, fluid flow, operational status or state of components of the pods 100A, 100B, 100C and/or the HAC system 900. In addition, the data 2001 may be data regarding temperature, fluid flow, operational status or state of components of the pods 1602, 1602A, 1602B, 1602C and/or the HAC system 1600, 1600A, 1600B. By way of another example, the control units 2002 may provide control instructions 503 to components of the HAC system 900 and/or the HAC system 1600, 1600A, 1600B.

Although embodiments of the present disclosure illustrate the one or more control units 2002 as separate components in communication with the HAC system 900 and/or the HAC system 1600, 1600A, 1600B, it should be understood that the one or more control units 2002 may be a component of the HAC system 900 and/or the HAC system 1600, 1600A, 1600B without departing from the scope of the present disclosure.

In general, the one or more control units 2002 may include one or more processors 2004 and memory 2006 (e.g., a memory medium, memory device, non-transitory computer readable medium, or the like). The one or more processors 2004 may be configured to execute program instructions 2008 maintained on or stored in the memory 2006. The one or more processors 2004 of the one or more control units 2002 may execute any of the various method or process steps necessary to operate the HAC system 900 and/or the HAC system 1600, 1600A, 1600B, and/or the subassemblies and/or components of the HAC system 900 and/or the HAC system 1600, 1600A, 1600B. In this regard, at least a portion of the disclosure may be understood as being directed to a computer-implemented method, as at least a portion of the disclosure may be understood as being directed to a computer-implemented invention.

In embodiments, the control system 2000 may include a user interface 2010 coupled (e.g., physically coupled, electrically coupled, communicatively coupled through wired or wireless connections (e.g., Bluetooth®, Wi-Fi, etc.), or the like) to the one or more control units 2002. For example, the user interface 2010 may be a separate device coupled to the one or more control units 2002. By way of another example, the user interface 2010 and the one or more control units 2002 may be located within a common or shared housing.

In embodiments, the user interface 2010 may include one or more displays 2012 and/or one or more user input devices 2014. Where communication is wired, the user interface 2010 may include one or more port connectors 2016 (e.g., for the transmitting and/or receiving of power and/or data, and the like). Similarly, it is contemplated that the one or more control units 2002, components of the HAC system 900 and/or the HAC system 1600, 1600A, 1600B, and/or components installed within a mechanical corridor 2018 of a data center 2020 proximate to the HAC system 900 and/or the HAC system 1600, 1600A, 1600B may include port connectors to allow for wired communication between the various components within the control system 2000.

Alternatively, or in addition, to the mechanical corridor 2018, it should be understood that the data center 2020 may include one or more of the rows 102 of server racks 104 that define the aisle 106; the HAC system 900 with pods 100, 100A, 100B, 100C; the HAC system 1600, 1600A, 1600B with pods 1602, 1602A, 1602B, 1602C; the control units 2002; the user interfaces 2010; the floor surface 902; the wall surface 904; the ceiling surface 1902; the ceiling-mounted cooling units 1900; the stacked cooling units 1908; and/or other components as described throughout the present disclosure.

In embodiments, the user interface 2010 provides a readout and ability to control operating points of the HAC system 900 and/or the HAC system 1600, 1600A, 1600B. The information may be presented at a location for each respective pod 100A, 100B, 100C of the HAC system 900 and/or each respective pods 1602, 1602A, 1602B of the HAC system 1600, 1600A, 1600B, and/or may be routed to a single location (e.g., located proximate to an end of the aisle 106 between rows 102 of server racks 104) for the HAC system 900 and/or the HAC system 1600, 1600A, 1600B, such as the user interface 1504 exemplarily illustrated in FIG. 15.

FIG. 20B is one example of a user interface 2010 including information related to data 2001 received from the HAC system 900 and/or the HAC system 1600, 1600A, 1600B (e.g., via the control unit 502). The user interface 2010 may provide information via the display 2012. For example, the information may include, but is not limited to, number for the aisle 106, temperature of the supply fluid and the return fluid for the aisle 106, average power density for each pod (and/or for a particular server rack 104, for a row 102 of server rack 104, and/or for the entire HAC system 900, 1600, 1600A, 1600B). By way of another example, the information may include, but is not limited to, temperature within the aisle 106 defined by the rows 102 in each pod (and/or for a particular server rack 104, and/or for the entire HAC system 900, 1600, 1600A, 1600B). By way of another example, the information may include, but is not limited to, status of particular server racks 104 (and/or for the server racks 104 in a particular row 102, and/or for the server racks 104 in a full pod, and/or for the server racks 104 in the full HAC system 900, 1600, 1600A, 1600B).

In general, the user interface 2010 may provide any information that may be desirable to an installer, a technician, a user or other individual who may have access to the server racks 104 within the data center during assembly and installation, diagnostic testing, and/or standing operation. It is noted that the information may be readily visible depending on the size of the user interface 2010, including across an entire data hall in which the aisle of server racks 104 is installed (e.g., as the user interface 1504 from the accessory module 1500 of FIG. 15) and/or from a remote location (e.g., a security room or monitoring room, laboratory, workspace or floor area, or the like). It is additionally noted the user interface 2010 may be installed directly onto the HAC system 900 and/or the HAC system 1600, 1600A, 1600B, or may be installed on one or more articulating arms coupled to the HAC system 900 and/or the HAC system 1600, 1600A, 1600B.

In some configurations, the control unit 2002 and/or the user interface 2010 are components of a smartphone, tablet, or computer or other electronic device that is wired or wirelessly coupled to one or more components of the HAC system 900 and/or the HAC system 1600, 1600A, 1600B. It is noted that the electronic device may be in direct or indirect communication with the one or more components of the HAC system 900 and/or the HAC system 1600, 1600A, 1600B, including optionally through one or more intervening servers.

The control system 2000 may include (or be in communication with) components within a mechanical corridor 2018. For example, the HAC system 900 and/or the HAC system 1600, 1600A, 1600B may be installed proximate to a wall surface 904 and the mechanical corridor 2018, where the wall surface 904 optionally includes an opening that provides access to the HAC system 900 and/or the HAC system 1600, 1600A, 1600B from the mechanical corridor 2018. It is noted that the mechanical corridor 2018 may include fluid-cooling and/or air-cooling components that supply the HAC system 900 and/or the HAC system 1600, 1600A, 1600B.

The control system 2000 may include one or more sensors coupled (e.g., physically coupled, electrically coupled, communicatively coupled, or the like) to or integrated in the one or more control units 2002, the HAC system 900 and/or the HAC system 1600, 1600A, 1600B, and/or the subassemblies and/or components of the HAC system 900 and/or the HAC system 1600, 1600A, 1600B. The one or more sensors may be operable to determine various operational, physical, and/or environmental parameters of the HAC system 900 and/or the HAC system 1600, 1600A, 1600B, the subassemblies and/or components of the HAC system 900 and/or the HAC system 1600, 1600A, 1600B, and/or the control system 2000; the environment surrounding the HAC system 900 and/or the HAC system 1600, 1600A, 1600B, the subassemblies and/or components of the HAC system 900 and/or the HAC system 1600, 1600A, 1600B, and/or the control system 2000; and the like. For instance, the sensors may be operable to determine the power consumption of the HAC system 900 and/or the HAC system 1600, 1600A, 1600B, the subassemblies and/or components of the HAC system 900 and/or the HAC system 1600, 1600A, 1600B, and/or the control system 2000.

In one non-limiting example, the HAC system 900 and/or the HAC system 1600, 1600A, 1600B includes sensors for leak detection for a section of pod, for each pod as a whole, and/or for the HAC system 900 and/or the HAC system 1600, 1600A, 1600B as a whole. It is noted that this data 2001 may be provided on the user interface 2010, to allow for the pinpointing of a leak to a particular location depending on the pre-determined breakdown of size of the HAC system 900 and/or the HAC system 1600, 1600A, 1600B.

The control system 2000 may include one or more transmitters and/or receivers coupled (e.g., physically coupled, electrically coupled, communicatively coupled, or the like) to or integrated in the one or more control units 2002, the HAC system 900 and/or the HAC system 1600, 1600A, 1600B, and/or the subassemblies and/or components of the HAC system 900 and/or the HAC system 1600, 1600A, 1600B. The one or more transmitters and/or receivers may be configured to transmit data 2001 and/or receive data 2001 for the HAC system 900 and/or the HAC system 1600, 1600A, 1600B and/or the subassemblies and/or components of the HAC system 900 and/or the HAC system 1600, 1600A, 1600B (e.g., from sensors installed within the HAC system 900 and/or the HAC system 1600, 1600A, 1600B and/or the subassemblies and/or components of the HAC system 900 and/or the HAC system 1600, 1600A, 1600B) or from external third-party control units (e.g., controllers, servers, or the like) either via wired connections or wireless connections, which may be configured as transmitting (Tx) units, receiving (Rx) units, or combination Tx/Rx units.

The control system 2000 may be configured to monitor the HAC system 900 and/or the HAC system 1600, 1600A, 1600B, and/or the subassemblies and/or components of the HAC system 900 and/or the HAC system 1600, 1600A, 1600B, via received and/or transmitted data. The control system 2000 may be configured to generate control signals to adjust one or more components of the HAC system 900 and/or the HAC system 1600, 1600A, 1600B, and/or the subassemblies and/or components of the HAC system 900 and/or the HAC system 1600, 1600A, 1600B, via a feedback loop or a feed forward loop based on the received and/or transmitted data, either automatically (or substantially automatically) or following an input from a user. The control system 2000 may be configured to receive and/or transmit data in a standardized format and/or a non-standardized format. Where the data is in a non-standardized format, the data may be converted to a standardized format upon receipt and/or prior to transmission to sensors, third-party control units, or the like.

In some configurations, automation (e.g., in the form of automatic or semi-automatic control) and/or artificial intelligence may be provided to (or within) the control system 2000. The control system 2000 can incorporate predictive analytics to control fluid flow (e.g., coolant, including but not limited to, liquid coolant) and/or air flow through the HAC system 900 and/or the HAC system 1600, 1600A, 1600B. Alternatively, or in addition to automatic or semi-automatic control of the various components within the HAC system 900 and/or the HAC system 1600, 1600A, 1600B by the control unit 2002, it is contemplated that one or more of the operation or adjustment of components of the HAC system 900 and/or the HAC system 1600, 1600A, 1600B may be performed manually by an operator, either in addition to or instead of automatically or semi-automatically by the control unit 2002, without departing from the scope of the present disclosure.

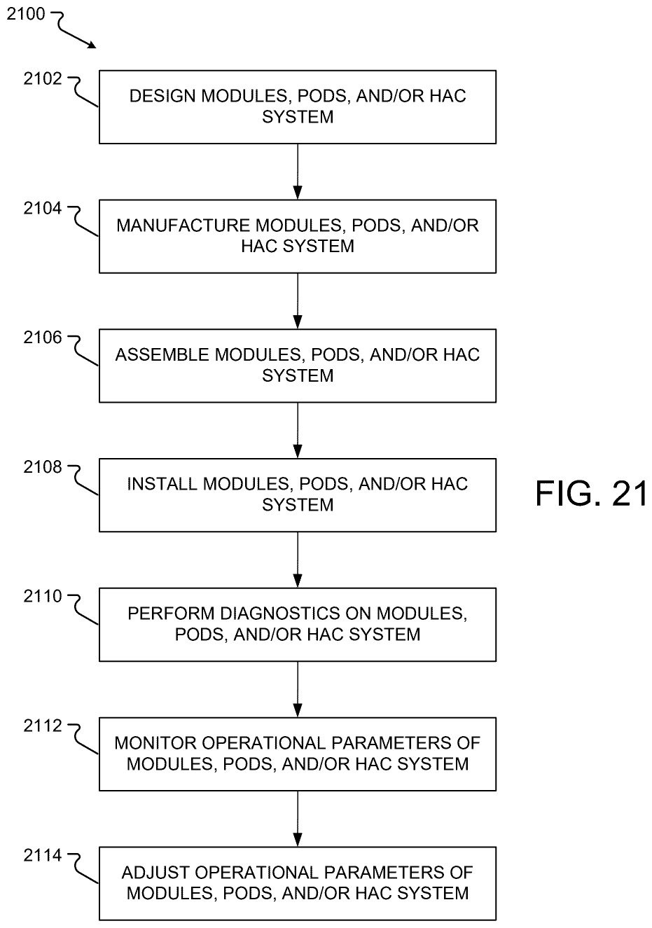

FIG. 21 is a flow diagram of a method or process 2100 illustrating the design, manufacturing, assembly, installation, and operation of the HAC system 900 of FIG. 9A including one or more pods 100 of FIG. 1A (e.g., 100A, 100B, 100C), in accordance with one or more embodiments of the present disclosure. FIG. 21 also is a flow diagram of a method or process 2100 illustrating the design, manufacturing, assembly installation, and operation of the HAC system 1600, 1600A, 1600B including one or more pods 1602 of FIG. 16A (e.g., 1802A, 1802B), in accordance with one or more embodiments of the present disclosure.

While a general order for the actions of the method or process 2100 is shown in FIG. 21, the method or process 2100 can include more or fewer actions or can arrange the order of the actions differently (including simultaneously, substantially simultaneously, or sequentially) than those shown in FIG. 21. It is noted that the method or process 2100 shall be explained with reference to the components, devices, subassemblies, environments, etc. described in conjunction with FIGS. 1A-20B. For example, it is noted that the embodiments as illustrated in FIGS. 1A-20B should be understood as reading on the embodiments described with respect to FIG. 21, and vice versa, without departing from the scope of the present disclosure.

In embodiments, modules, pods, and/or an HAC system are designed 2102. Referring to FIGS. 1A-15, the pod 100 includes one or more modules 200, 300, 400 (with optional components 500, 600), 700, and/or 800, with components attached thereto as described throughout the present disclosure. The HAC system 900 includes one or more pods 100 (e.g., pods 100A, 100B, 100C). The HAC system 900 may include one or more full system modules 1000, 1100, 1200, 1300, 1400, 1500 and/or shared components (e.g., control system 1600 components including, but not limited to, control units 2002, user interfaces 2010, and the like). Referring to FIGS. 16A-19B, the HAC system 1600, 1600A, 1600B has one or more pods 1602 (e.g., pods 1602A, 1602B, 1802C) includes one or more modules 1604, 1614, 1628, 1640, 1800, 1828, with components attached thereto as described throughout the present disclosure.

It should be understood that the designing of the HAC system 900, 1600, 1600A, 1600B may be completed based on customer specifications. In one non-limiting example, when placing an order for the HAC system 900, 1600, 1600A, 1600B, the customer may choose from options for the HAC system 900, 1600, 1600A, 1600B such as (1) fluid-cooled (e.g., liquid-cooled) with a mechanical corridor transition, (2) fluid-cooled (e.g., liquid-cooled) with a ceiling plenum transition, (3) air-cooled with a mechanical corridor transition, or (4) air-cooled with a ceiling plenum transition.

The customer may accept pre-determined widths, length and number of pods, location or type of doors, pipe size (where the fluid cooling modules 400, 1100, 1800 are needed), number/size/capacity of cable management modules 700, 1200, and/or the inclusion of any default accessories when making the above choice. Alternatively, the customer may modify one or more of width of pod 100/HAC system 900 and/or width of pod 1602/HAC system 1600, length of pod 100/HAC system 900 and/or length of pod 1602/HAC system 1600 (including by adding or removing a number of pods 100, 1602), door type or door location of the HAC system 900 and/or HAC system 1600, inclusion of a transition corridor module 1640, pipe size (where the fluid cooling modules 400, 1100, 1800 are required), number/size/capacity of cable management modules 700, 1200, and/or the inclusion of any additional or alternative accessories when making the above choice.

In embodiments, the modules, the pods, and/or the HAC system are manufactured 2104. The manufacturing may occur at a factory or other manufacturing facility. For example, manufacturing the HAC system 900 and/or the pods 100, and/or the HAC system 1600 and/or the pods 1602, including optionally components of the control system 1600, may allow for customization of the HAC system 900 and/or the pods 100, and/or the HAC system 1600 and/or the pods 1602, to specifications set by a customer during the ordering process.

In embodiments, the modules, the pods, and/or the HAC system are assembled 2106. The assembly may occur at the factory or other manufacturing facility, prior to transportation to a project site. For example, the pods 100 (e.g., including the modules 200, 300, 400 (with optional components 500, 600), 700, and/or 800) and/or modules 1000, 1100, 1200, 1300, 1400, 1500 of the HAC system 900 may be partially-or fully-assembled at a factory prior to transportation to a project site. By way of another example, the pods 1602 (e.g., including the modules 1604, 1614, 1628, 1640, 1800, 1828) of the HAC system 1600 may be partially-or fully-assembled at a factory prior to transportation to a project site.

In embodiments, the modules, the pods, and/or the HAC system are installed 2108. The installation may occur at a project site, after transportation from the factory or other manufacturing facility. It is noted that manufacturing and/or assembling the HAC system 900 and/or the pods 100, including optionally components of the control system 1600, at the factory or other manufacturing facility to be installed in a modular configuration may reduce the possibility of error during installation of the HAC system and/or the pods 100 at a project site.

In embodiments, diagnostics are performed 2110 on the modules, the pods, and/or the HAC system. For example, diagnostics may be performed during manufacturing, during assembly, during installation, and/or after installation on the pods 100 (e.g., including the modules 200, 300, 400 (with optional components 500, 600), 700, and/or 800) and/or modules 1000, 1100, 1200, 1300, 1400, 1500 of the HAC system 900. By way of another example, diagnostics may be performed during manufacturing, during assembly, during installation, and/or after installation on the pods 1602 (e.g., including the modules 1604, 1614, 1628, 1640, 1800, 1828) of the HAC system 1600.

In embodiments, operational parameters of the modules, the pods, and/or the HAC system are monitored 2112. For example, the monitoring and optional adjustment of operational parameters may be performed during manufacturing, during assembly, during installation, and/or after installation on the pods 100 (e.g., including the modules 200, 300, 400 (with optional components 500, 600), 700, and/or 800) and/or modules 1000, 1100, 1200, 1300, 1400, 1500 of the HAC system 900. By way of another example, the monitoring and optional adjustment of operational parameters may be performed during manufacturing, during assembly, during installation, and/or after installation on the pods 1602 (e.g., including the modules 1604, 1614, 1628, 1640, 1800, 1828) of the HAC system 1600.

In embodiments, operational parameters of the modules, the pods, and/or the HAC system are adjusted 2114. For example, where operational parameters are not meeting or exceeding pre-determined values (e.g., based on thresholds, values, or other objective or subject metrics), adjustment of operational parameters may be performed during manufacturing, during assembly, during installation, and/or after installation on the pods 100 (e.g., including the modules 200, 300, 400 (with optional components 500, 600), 700, and/or 800) and/or modules 1000, 1100, 1200, 1300, 1400, 1500 of the HAC system 900. By way of another example, where operational parameters are not meeting or exceeding pre-determined values (e.g., based on thresholds, values, or other objective or subject metrics), adjustment of operational parameters may be performed during manufacturing, during assembly, during installation, and/or after installation on the pods 1602 (e.g., including the modules 1604, 1614, 1628, 1640, 1800, 1828) of the HAC system 1600.

It is noted that diagnostics may be performed 2110, operational parameters may be monitored 2112, and/or operational parameters may be adjusted 2114 of the rows 102 of server racks 104 in addition to or instead of the monitoring of the HAC systems 900, 1600, without departing from the scope of the present disclosure.

It should be understood that one or more actors may perform the operations 2102, 2104, 2106, 2108, 2110, 2110, 2112, 2114 of the method or process 2100. In addition, it should be understood that the timing of the operations 2102, 2104, 2106, 2108, 2110, 2110, 2112, 2114 of the method or process 2100 may be spaced or separate, including depending on the number of actors. As such, the method or process 2100 is provided only for illustration as a single method or process, but that it should be understood the method or process 2100 may actually comprise multiple methods or processes without departing from the scope of the present disclosure.

Advantages of the present disclosure include a modularized HAC system, and methods related to the manufacturing, assembly, installation, and operation of the same. The modularized HAC system includes one or more pods, where each pod includes a series of modules that are installed proximate to one or more rows of server racks (e.g., including, optionally, two rows of server racks defining an aisle therebetween, into which exhaust is directed). The modularized HAC system includes shared modules or components installable within and/or at an end of the one or more pods. Together, the HAC system may be installed at a project site in aisles, where each aisle includes one or more pods (and shared components) that make up the HAC system with the one or more rows of server racks.

Advantages of the present disclosure also include collecting information about the operational parameters of the HAC system, the pods within the HAC system, the modules within the pods, the shared components or modules of the HAC system, and/or the components for the modules. The information may be provided at each respective pod, or at a single location on the HAC system, and/or at a separate location from the HAC system, including via a user interface.

Advantages of the present disclosure also include modules of the pods (and/or full pods) and/or the shared components or modules of the HAC system being designed, manufactured, and assembled as a factory or other manufacturing facility. The assembled modules, shared components or modules, and/or pods of modules may then be provided to a project site, streamlining the assembly process prior to installation and reducing the possibility of installation error while increasing quality control and consistency of assembly and installation across different products.

Although embodiments of the present disclosure are directed to implementation of the systems and method described herein in data centers, it should be understood such is merely illustrative as is not intended on being limited to the present disclosure. In general, the present disclosure may be understood as being directed to any application that may monitor fluid (e.g., coolant) temperature and power consumption to increase efficiency, including with systems that are manufactured and/or installed in sections (e.g., modules, pods, or the like).

While various embodiments of the present disclosure have been described in detail, it is apparent that modifications and alterations of those embodiments will occur to those skilled in the art. However, it is to be understood that such modifications and alterations are within the scope and spirit of the present disclosure, as set forth in the following claims. Further, the invention(s) described herein is capable of other embodiments and of being practiced or of being carried out in various ways. It is to be understood that the phraseology and terminology used herein is for the purpose of description and should not be regarded as limiting.

What is claimed is:

1. A pod for a modularized hot aisle containment (HAC) system, the pod comprising:
a frame module including a plurality of posts, wherein spacing between adjacent posts of the plurality of posts is dimensioned to receive adjacent rows of server racks and at least partially surround an aisle defined between the adjacent rows of server racks when the adjacent rows of server racks are installed with the pod;
a power module couplable to the frame module, the power module configured to route power cables to the adjacent rows of server racks when the adjacent rows of server racks are installed with the pod;
a tray module couplable to the frame module, the tray module configured to route networking or data cables to the adjacent rows of server racks when the adjacent rows of server racks are installed with the pod; and
a panel module couplable to the frame module, wherein the panel module is configured to at least partially enclose the defined aisle between adjacent rows of server racks to at least one of contain and direct hot air exhausted from the adjacent rows of server racks through the defined aisle when the adjacent rows of server racks are installed with the pod,
wherein the frame module, the power module, the tray module, and the panel module are assembled to form the pod at a first location, and are deliverable pre-assembled for installation with the adjacent rows of server racks to a second location.

2. The pod of claim 1, wherein at least some posts of the plurality of posts are couplable to a floor surface during installation via anchor plates, and
wherein the frame module comprises at least one crossmember coupled to adjacent posts of the plurality of posts.

3. The pod of claim 1, wherein the power module comprises:
a frame couplable to adjacent posts of the plurality of posts;
at least one hanger arm assembly coupled to the frame, the at least one hanger arm assembly including a plurality of arms that are adjustable within the hanger arm assembly and relative to the frame; and
at least one power conduit coupled to one or more arms of the plurality of arms, wherein the at least one power conduit is configured to route power cables to the adjacent rows of server racks when the adjacent rows of server racks are installed with the pod.

4. The pod of claim 1, wherein the tray module comprises:
a frame couplable to adjacent posts of the plurality of posts;
at least one hanger arm assembly coupled to the frame, the at least one hanger arm assembly including a plurality of arms that are adjustable within the hanger arm assembly and relative to the frame; and
at least one cable tray coupled to one or more arms of the plurality of arms, wherein the at least one cable tray is configured to route networking or data cables to the adjacent rows of server racks.

5. The pod of claim 4, wherein the tray module comprises:
at least one shelf coupled to one or more arms of the plurality of arms.

6. The pod of claim 1, wherein the panel module comprises:
a frame couplable to adjacent posts of the plurality of posts; and
at least one window that extends from the frame, wherein the at least one window is configured to at least partially enclose the defined aisle between adjacent rows of server racks to at least one of contain and direct the hot air exhausted from the adjacent rows of server racks through the defined aisle when the adjacent rows of server racks are installed with the pod.

7. The pod of claim 6, wherein the panel module further comprises:
at least one divider that extends from the frame in a direction opposite a direction of extension of the at least one window, wherein the at least one divider is configured to at least partially enclose the defined aisle between adjacent rows of server racks to at least one of contain and direct the hot air exhausted from the adjacent rows of server racks through the defined aisle when the adjacent rows of server racks are installed with the pod.

8. The pod of claim 1, further comprising:
at least one ceiling panel, wherein the at least one ceiling panel is configured to at least partially enclose the defined aisle between adjacent rows of server racks to at least one of contain and direct the hot air exhausted from the adjacent rows of server racks through the defined aisle when the adjacent rows of server racks are installed with the pod.

9. The pod of claim 8, wherein the at least one ceiling panel is installed on a fluid cooling module of the pod.

10. The pod of claim 1, further comprising:
at least one catwalk panel, wherein the at least one catwalk panel is configured to support a pre-determined amount of weight.

11. The pod of claim 10, wherein the at least one catwalk panel is installed on a fluid cooling module of the pod.

12. The pod of claim 1, further comprising:
a fluid cooling module, the fluid cooling module configured to provide fluid to the adjacent rows of server racks for fluid cooling when the adjacent rows of server racks are installed with the pod.

13. The pod of claim 12, wherein the fluid cooling module is a liquid cooling module that supplies a liquid coolant at a first lower temperature to, and receives liquid coolant at a second higher temperature from, the adjacent rows of server racks when the adjacent rows of server racks are installed with the pod.

14. The pod of claim 13, wherein the fluid cooling module comprises:
a frame couplable to adjacent posts of the plurality of posts;
at least one supply pipe insertable in the frame and for a fluid at a first lower temperature;
at least one supply line fluidically coupled with the supply pipe and the adjacent rows of server racks when the adjacent rows of server racks are installed with the pod;
at least one return pipe insertable in the frame and for a fluid at a second higher temperature; and
at least one return line fluidically coupled with the return pipe and the adjacent rows of server racks when the adjacent rows of server racks are installed with the pod.

15. The pod of claim 14, wherein the at least one supply pipe includes two supply pipes that are fluidically coupled via a supply pipe joint to circulate supply fluid between supply ports located at one end of the pod, and wherein the at least one return pipe includes two return pipes that are fluidically coupled via a return pipe joint to circulate return fluid between return ports located at one end of the pod.

16. The pod of claim 1, wherein the frame module is configured to receive a door module, wherein the door module is configured to at least partially enclose the defined aisle between adjacent rows of server racks to at least one of contain and direct hot air exhausted from the adjacent rows of server racks through the defined aisle when the adjacent rows of server racks are installed with the HAC system.

17. A modularized hot aisle containment (HAC) system, the HAC system comprising:
at least one pod, comprising:
a frame module including a plurality of posts, wherein spacing between adjacent posts of the plurality of posts is dimensioned to receive adjacent rows of server racks and at least partially surround an aisle defined between the adjacent rows of server racks when the adjacent rows of server racks are installed with the HAC system;
a power module couplable to the frame module, the power module configured to route power cables to the adjacent rows of server racks when the adjacent rows of server racks are installed with the HAC system;
a tray module couplable to the frame module, the tray module configured to route networking or data cables to the adjacent rows of server racks when the adjacent rows of server racks are installed with the HAC system; and
a panel module couplable to the frame module, wherein the panel module is configured to at least partially enclose the defined aisle between adjacent rows of server racks to at least one of contain and direct hot air exhausted from the adjacent rows of server racks through the defined aisle when the adjacent rows of server racks are installed with the pod,
wherein the frame module, the power module, the tray module, and the panel module are assembled to form the at least one pod at a first location, and are deliverable pre-assembled as the at least one pod for installation with the adjacent rows of server racks to a second location; and
a door module couplable to the frame module of a particular pod of the at least one pod, wherein the door module is configured to at least partially enclose the defined aisle between adjacent rows of server racks to at least one of contain and direct hot air exhausted from the adjacent rows of server racks through the defined aisle when the adjacent rows of server racks are installed with the HAC system.

18. The HAC system of claim 17, the at least one pod further comprising:
a fluid cooling module, the fluid cooling module configured to provide fluid to the adjacent rows of server racks for fluid cooling when the adjacent rows of server racks are installed with the HAC system.

19. A method, comprising:
designing one or more modules for at least one pod of a modularized hot aisle containment (HAC) system, the one or more modules comprising:
a frame module including a plurality of posts, wherein spacing between adjacent posts of the plurality of posts is dimensioned to receive adjacent rows of server racks and at least partially surround an aisle defined between the adjacent rows of server racks when the adjacent rows of server racks are installed with the HAC system;
a power module couplable to the frame module, the power module configured to route power cables to the adjacent rows of server racks when the adjacent rows of server racks are installed with the HAC system;
a tray module couplable to the frame module, the tray module configured to route networking or data cables to the adjacent rows of server racks when the adjacent rows of server racks are installed with the HAC system; and
a panel module couplable to the frame module, wherein the panel module is configured to at least partially enclose the defined aisle between adjacent rows of server racks to at least one of contain and direct hot air exhausted from the adjacent rows of server racks through the defined aisle when the adjacent rows of server racks are installed with the HAC system;
manufacturing the one or more modules for at least one pod of the system; and
assembling the at least one pod of the HAC system, wherein the frame module, the power module, the tray module, and the panel module are assembled to form the at least one pod at a first location, and the at least one pod is deliverable pre-assembled for installation with the adjacent rows of server racks to a second location.

20. The method of claim 19, wherein designing one or more modules for at least one pod of a modularized hot aisle containment system further includes designing:
a fluid cooling module, the fluid cooling module configured to provide fluid to the adjacent rows of server racks for fluid cooling when the adjacent rows of server racks are installed with the HAC system.
